(19) United States
(12) Patent Application Publication
(10) Pub. No.: US 2024/0402994 A1
(43) Pub. Date: Dec. 5, 2024

(54) ELECTRONIC DEVICE AND DISPLAY SYSTEM

(71) Applicant: Semiconductor Energy Laboratory Co., Ltd., Atsugi-shi, Kanagawa-ken (JP)

(72) Inventors: Kiyoshi KATO, Atsugi (JP); Tatsuya ONUKI, Atsugi (JP); Atsushi MIYAGUCHI, Hadano (JP); Yoshiaki OIKAWA, Atsugi (JP); Shunpei YAMAZAKI, Setagaya (JP)

(21) Appl. No.: 18/683,540

(22) PCT Filed: Sep. 8, 2022
(86) PCT No.: PCT/IB2022/058439

§ 371 Date: Feb. 14, 2024

(30) Foreign Application Priority Data
Sep. 22, 2021 (JP) 2021-153758

(51) Int. Cl. G06F 7/523; G06F 7/50; G11C 11/405; H10B 12/00

(52) U.S. Cl. CPC G06F 7/523; G06F 7/50; G11C 11/405; H10B 12/00

(57) ABSTRACT

An electronic device with a novel structure is provided. In an electronic device including a semiconductor device, the semiconductor device includes a CPU, an accelerator, and a memory device. The CPU includes a scan flip-flop circuit and a backup circuit electrically connected to the scan flip-flop circuit. The backup circuit includes a first transistor. The accelerator includes an arithmetic circuit and a data retention circuit electrically connected to the arithmetic circuit. The data retention circuit includes a second transistor. The memory device includes a memory cell including a third transistor. The first transistor to the third transistor each include a semiconductor layer containing a metal oxide in a channel formation region.

### TECHNICAL FIELD

In this specification, an electronic device, a display system including the electronic device, a semiconductor device included in the electronic device, and the like are described.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic apparatus, a lighting device, an input device, an input/output device, a driving method thereof, and a manufacturing method thereof.

### BACKGROUND ART

The wearable electronic device that performs mobile communication or the like is widely used. For example, an arm-worn electronic device may include a variety of sensors, a CPU for controlling the sensors, a memory for storing data, and the like in addition to a display (e.g., see Patent Document 1).

In such an electronic device, techniques for improving the performance of the semiconductor devices have been actively developed to process a large volume of data at high speed. As a technique for achieving high performance, what is called an SoC (System on Chip) is given in which an accelerator such as a GPU (Graphics Processing Unit) and a CPU are tightly coupled.

### REFERENCE

### Patent Document

[Patent Document 1] PCT International Publication No. 2016/036472

### SUMMARY OF THE INVENTION

### Problems to be Solved by the Invention

In an electronic device including a semiconductor device having higher performance by adopting an SoC, heat generation and an increase in power consumption become problems. The number of times of data transfer in a CPU is dominant factor in increasing power consumption of the semiconductor device. Thus, it is important to inhibit an increase in the number of times of data transfer to suppress power consumption or heat generation of the semiconductor device. Alternatively, in order to reduce power consumption or heat generation of the semiconductor device, it is important to reduce the number of times of data transfer between the CPU and a memory. However, performance improvement of the semiconductor device and reduction in power consumption or heat generation of the semiconductor device have a trade-off relationship. That is, it has been difficult to achieve both performance improvement of the semiconductor device and reduction in power consumption or heat generation of the semiconductor device.

An object of one embodiment of the present invention is to provide a novel electronic device, a novel display system, and the like. Another object of one embodiment of the present invention is to provide an electronic device, a display system, and the like with a novel structure which include a semiconductor device having higher performance by adopting an SoC and in which heat generation and an increase in power consumption can be inhibited. Another object of one embodiment of the present invention is to provide an electronic device and the like and a display system with a novel structure in which the number of times of data transfer in a CPU can be reduced. Another object of one embodiment of the present invention is to provide an electronic device, a display system, and the like with a novel structure in which both performance improvement of a semiconductor device and reduction in power consumption or heat generation of the semiconductor device can be achieved. Another object of one embodiment of the present invention is to provide an electronic device, a display system, and the like with a novel structure that are highly convenient.

The description of a plurality of objects does not preclude the existence of each object. One embodiment of the present invention does not necessarily achieve all the objects described as examples. Furthermore, objects other than those listed are apparent from description of this specification, and such objects can be objects of one embodiment of the present invention.

### Means for Solving the Problems

One embodiment of the present invention is an electronic device including a semiconductor device. The semiconductor device includes a CPU, an accelerator, and a memory device. The CPU includes a scan flip-flop circuit and a backup circuit electrically connected to the scan flip-flop circuit. The backup circuit includes a first transistor. The accelerator includes an arithmetic circuit and a data retention circuit electrically connected to the arithmetic circuit. The data retention circuit includes a second transistor. The memory device includes a memory cell including a third transistor. The first transistor to the third transistor each include a semiconductor layer containing a metal oxide in a channel formation region.

One embodiment of the present invention is an electronic device including a semiconductor device. The semiconductor device includes a CPU, an accelerator, and a memory device. The CPU includes a scan flip-flop circuit and a backup circuit electrically connected to the scan flip-flop circuit. The backup circuit includes a first transistor. A layer where the backup circuit is provided is stacked with a layer where the scan flip-flop circuit is provided. The accelerator includes an arithmetic circuit and a data retention circuit electrically connected to the arithmetic circuit. The data retention circuit includes a second transistor. A layer where the data retention circuit is provided is stacked with a layer where the arithmetic circuit is provided. The memory device includes a memory cell including a third transistor. The first transistor to the third transistor each include a semiconductor layer containing a metal oxide in a channel formation region.

In the electronic device of one embodiment of the present invention, it is preferable that the backup circuit have a function of retaining, when the CPU does not operate, data retained in the scan flip-flop circuit in a state where supply of power supply voltage is stopped.

In the electronic device of one embodiment of the present invention, it is preferable that the data retention circuit have a function of retaining, when the accelerator does not operate, data retained in the data retention circuit in a state where supply of power supply voltage is stopped.

In the electronic device of one embodiment of the present invention, it is preferable that the scan flip-flop circuit and the arithmetic circuit each include a transistor including a semiconductor layer containing silicon in a channel formation region.

In the electronic device of one embodiment of the present invention, it is preferable that the memory device include a peripheral circuit controlling the memory cell, and a layer where the peripheral circuit is provided be stacked with a layer where the memory cell is provided.

In the semiconductor device of one embodiment of the present invention, the arithmetic circuit is preferably a circuit that performs a product-sum operation.

In the semiconductor device of one embodiment of the present invention, the metal oxide preferably contains In, Ga, and Zn.

One embodiment of the present invention is a display system including a first electronic device and a second electronic device. The first electronic device includes a first display portion, a first wireless communication means, and a first sensor. The second electronic device includes a second display portion, a second wireless communication means, and a second sensor. When the first wireless communication means and the second wireless communication means are linked to each other, the first electronic device and the second electronic device are connected to each other. The display system has a function of displaying any one or more of augmented reality, virtual reality, substitutional reality, and mixed reality on the second display portion based on any one or more pieces of information input to the first sensor and the second sensor, and a function of operating an image on the second display portion based on the information input to the first sensor.

In the display system of one embodiment of the present invention, the above-described first electronic device is preferably an electronic device of one embodiment of the present invention.

Note that other embodiments of the present invention will be shown in the description of the following embodiments and the drawings.

### Effect of the Invention

One embodiment of the present invention can provide a novel electronic device, a novel display system, and the like. Another embodiment of the present invention can provide an electronic device, a display system, and the like with a novel structure which includes a semiconductor device having higher performance by adopting an SoC and in which heat generation and an increase in power consumption can be inhibited. Another embodiment of the present invention can provide an electronic device, a display system, and the like with a novel structure in which the number of times of data transfer in a CPU can be reduced. Another embodiment of the present invention can provide an electronic device, a display system, and the like with a novel structure in which both performance improvement of a semiconductor device and reduction in power consumption or heat generation of the semiconductor device can be achieved. Another embodiment of the present invention can provide an electronic device, a display system, and the like with a novel structure that are highly convenient.

The description of a plurality of effects does not preclude the existence of other effects. In addition, one embodiment of the present invention does not necessarily achieve all the effects described as examples. In one embodiment of the present invention, other objects, effects, and novel features are apparent from the description of this specification and the drawings.

### BRIEF DESCRIPTION OF THE DRAWINGS

FIG. 1A and FIG. 1B are diagrams illustrating a structure example of an electronic device.

FIG. 2A and FIG. 2B are diagrams illustrating a structure example of an electronic device.

FIG. 3 is a diagram illustrating a configuration example of an electronic device.

FIG. 4A and FIG. 4B are diagrams illustrating configuration examples of an electronic device.

FIG. 5 is a diagram illustrating a configuration example of an electronic device.

FIG. 6A and FIG. 6B are diagrams illustrating a configuration example of an electronic device.

FIG. 7A and FIG. 7B are diagrams illustrating a configuration example of an electronic device.

FIG. 8A and FIG. 8B are diagrams illustrating a structure example of an electronic device.

FIG. 9A and FIG. 9B are diagrams illustrating configuration examples of an electronic device.

FIG. 10A and FIG. 10B are diagrams illustrating configuration examples of electronic devices.

FIG. 11A to FIG. 11F are diagrams illustrating configuration examples of an electronic device.

FIG. 12 is a diagram illustrating a structure example of an electronic device.

FIG. 13A and FIG. 13B are diagrams illustrating structure examples of an electronic device.

FIG. 14A to FIG. 14C are diagrams illustrating structure examples of electronic devices.

FIG. 15A and FIG. 15B are diagrams illustrating structure examples of electronic devices.

FIG. 16 is a diagram illustrating a structure example of an electronic device.

FIG. 17A to FIG. 17C are diagrams illustrating structure examples of electronic devices.

FIG. 18 is a diagram illustrating a structure example of an electronic device.

FIG. 19A and FIG. 19B are diagrams illustrating structure examples of electronic devices.

FIG. 20A to FIG. 20B are diagrams illustrating structure examples of a display apparatus and a display system.

FIG. 21A and FIG. 21B are diagrams illustrating structure examples of a display apparatus and a display system.

FIG. 22A to FIG. 22D are diagrams illustrating examples of a display apparatus and images of a display system.

FIG. 23 is a diagram showing an example of an operation method of a display system.

FIG. 24A to FIG. 24D are diagrams illustrating examples of a display apparatus and images of a display system.

FIG. 25 is a diagram showing an example of an operation method of a display system.

FIG. 26A and FIG. 26B are diagrams illustrating a structure example of a display apparatus.

FIG. 27 is a diagram illustrating a configuration example of a display apparatus.

FIG. 28 is a diagram illustrating an operation example of an electronic device.

FIG. 29A and FIG. 29B are schematic diagrams illustrating a structure example of an electronic device.

FIG. 30A and FIG. 30B are schematic diagrams illustrating structure examples of an electronic device.

FIG. 31A and FIG. 31B are schematic diagrams illustrating a structure example of an electronic device.

FIG. 32A and FIG. 32B are diagrams illustrating a configuration example of a display apparatus.

FIG. 33A and FIG. 33B are diagrams illustrating a structure example of a display apparatus.

FIG. 34A and FIG. 34C are diagrams illustrating a structure example of a display apparatus.

FIG. 35A and FIG. 35C are diagrams illustrating structure examples of a display apparatus.

FIG. 36A and FIG. 36B are diagrams illustrating a structure example of a display apparatus.

FIG. 37 is a diagram illustrating a structure example of a display apparatus.

FIG. 38 is a diagram illustrating a structure example of a display apparatus.

FIG. 39 is a diagram illustrating a structure example of a display apparatus.

FIG. 40 is a diagram illustrating a structure example of a display apparatus.

FIG. 41 is a diagram illustrating a structure example of a display apparatus.

FIG. 42 is a diagram illustrating a structure example of a display apparatus.

FIG. 43 is a diagram illustrating a structure example of a display apparatus.

FIG. 44A to FIG. 44E are diagrams illustrating structure examples of electronic devices.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Note that ordinal numbers such as “first”, “second”, and “third” in this specification and the like are used in order to avoid confusion among components. Thus, the ordinal numbers do not limit the number of components. In addition, the ordinal numbers do not limit the order of components. Furthermore, in this specification and the like, for example, a “first” component in one embodiment can be referred to as a “second” component in other embodiments or the SCOPE OF CLAIMS. Moreover, in this specification and the like, for example, a “first” component in one embodiment can be omitted in other embodiments or the SCOPE OF CLAIMS. Moreover, in this specification and the like, for example, a “first” component in one embodiment can be omitted in other embodiments or the SCOPE OF CLAIMS.

In some cases, the same components, components having similar functions, components made of the same material, components formed at the same time, and the like are denoted by the same reference numerals in the drawings and repeated description thereof is omitted.

In this specification, for example, a power supply potential VDD may be abbreviated to a potential VDD, VDD, or the like. The same applies to other components (e.g., a signal, a voltage, a circuit, an element, an electrode, and a wiring).

In the case where a plurality of components are denoted by the same reference numerals, and, particularly when they need to be distinguished from each other, an identification sign such as “_1”, “_2”, “[n]”, or “[m,n]” is sometimes added to the reference numerals. For example, a second wiring GL is referred to as a wiring GL[2].

### Embodiment 1

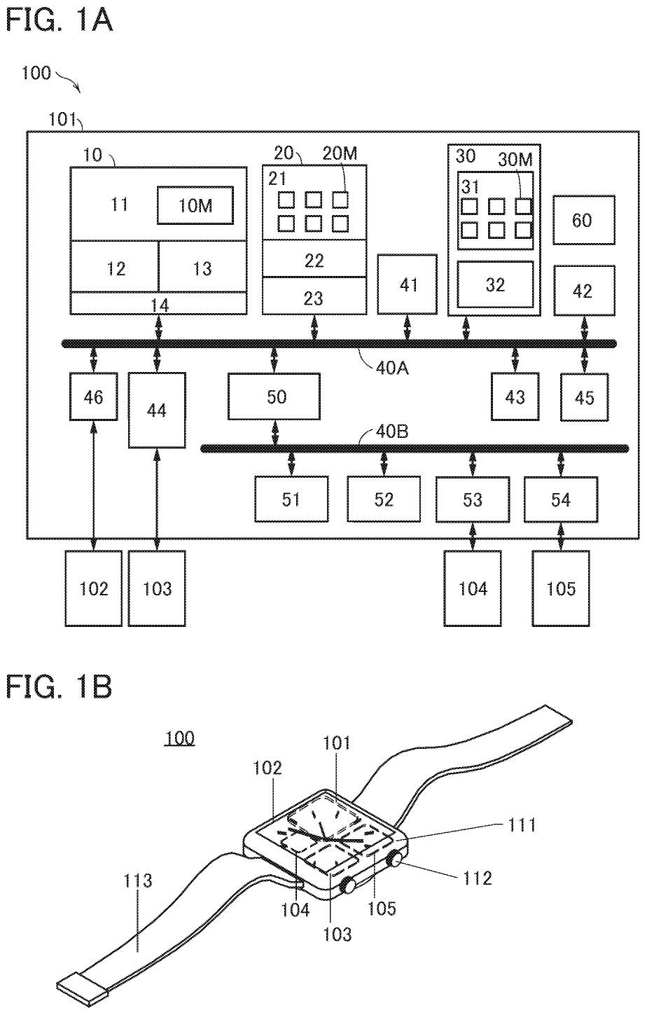

Structure examples of an electronic device according to one embodiment of the present invention are described with reference to FIG. 1A to FIG. 11F.

### <Structure Example of Electronic Device>

FIG. 1A is a block diagram illustrating an electronic device of one embodiment of the present invention. In an electronic device 100 illustrated in FIG. 1A, a display 102, a main memory 103, a battery 104, and a sensor 105 are illustrated in addition to a semiconductor device 101, for example. FIG. 1B is an example of a perspective view of the electronic device 100 corresponding to the block diagram of the electronic device 100 shown in FIG. 1A. The electronic device illustrated in FIG. 1B is a watch-type electronic device, and a structure in which the display 102, the main memory 103, the battery 104, and the sensor 105 are stored besides the semiconductor device 101 in a housing 111 to which an operation portion 112 and a band 113 are attached is illustrated. Note that the electronic device 100 illustrated in FIG. 1B has a function of what is called a smartwatch.

The semiconductor device 101 includes a CPU 10, an accelerator 20, a memory device 30, a DMAC (Direct Memory Access Controller) 41, a power management unit (PMU) 42, a power supply circuit 60, a memory controller 43, a DDR SDRAM (Double Data Rate Synchronous Dynamic Random Access Memory) controller 44, a USB (Universal Serial Bus) interface circuit 45, a display interface circuit 46, a bridge circuit 50, an interrupt control circuit 51, an interface circuit 52, a battery control circuit 53, and an ADC (Analog-to-digital converter)/DAC (Digital-to-analog converter) interface circuit 54. Although not illustrated in FIG. 1A, the semiconductor device 101 may include a module (also referred to as a communication module) having a function of communicating with the outside. The communication module is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. Several tens of kilohertz to several tens of gigahertz are a practical frequency band that is generally used. A structure can be employed in which the high frequency circuit connected to an antenna includes a high frequency circuit portion compatible with a plurality of frequency bands and the high frequency circuit portion includes an amplifier, a mixer, a filter, a DSP, an RF transceiver, or the like. In the case of performing wireless communication, it is possible to use, as a communication protocol or a communication technology, a communications standard defined by the 3GPP (Third Generation Partnership Project) (registered trademark), such as standard compatible with LTE (Long Term Evolution) (registered trademark), LTE-Advanced compatible with the fourth-generation mobile communication system, the fifth-generation mobile communication system (5G), or the sixth-generation mobile communication system (6G), a communications standard defined by IEEE (Institute of Electrical and Electronics Engineers) (registered trademark), such as Wi-Fi (registered trademark) or Bluetooth (registered trademark), or the like.

Note that the semiconductor device 101 may include another circuit, for example, a security circuit or the like. A security circuit is a circuit for improving confidentiality of signals in such a manner that, for example, signals are transmitted and received between the semiconductor device 101 and an external circuit after being encrypted.

The CPU 10 includes a CPU core 11, an L1 cache memory device 12, an L2 cache memory device 13, and a bus interface portion 14, for example. The L1 cache memory device 12 is referred to as an instruction cache in some cases. The L2 cache memory device 13 is referred to as a data cache in some cases.

The CPU core 11 includes a plurality of CPU cores. The CPU cores include a backup circuit 10M electrically connected to a scan flip-flop circuit. The L1 cache memory device 12 has a function of temporarily storing an instruction to be executed by the CPU core 11. The L2 cache memory device 13 has a function of temporarily storing data to be processed by the CPU core 11 or data obtained by the processing. The bus interface portion 14 can have a circuit configuration that can transmit and receive signals such as data, an address, and the like to and from a bus for connecting the CPU 10 and other circuits in the semiconductor device 101.

Note that the scan flip-flop circuit in the CPU 10 is composed of a circuit including a transistor which includes a semiconductor layer containing silicon in a channel formation region (Si transistor), that is, a Si CMOS. Meanwhile, the backup circuit 10M includes a transistor including a semiconductor layer containing a metal oxide in a channel formation region (OS transistor). The backup circuit 10M including the OS transistor can function as an OS memory having a function of retaining electric charge for a long time when the OS transistor is turned off.

A metal oxide has a band gap of 2.5 eV or wider; thus, an OS transistor has an extremely low off-state current. For example, the off-state current per micrometer in channel width at a source-drain voltage of 3.5 V and room temperature (25° C.) can be lower than 1×10⁻²⁰ A, lower than 1×10⁻²² A, or lower than 1×10⁻²⁴ A. That is, the on/off ratio of drain current can be greater than or equal to 20 digits and less than or equal to 150 digits. Therefore, in an OS memory, the amount of electric charge that leaks from a retention node through the OS transistor is extremely small. Accordingly, the OS memory can function as a nonvolatile memory circuit; thus, power gating of the CPU 10 is enabled.

A highly integrated semiconductor device generates heat due to circuit drive in some cases. This heat makes the temperature of a transistor rise to change the characteristics of the transistor, and the field-effect mobility thereof might change or the operation frequency thereof might decrease, for example. Since an OS transistor has higher heat resistance than a Si transistor, a change in field-effect mobility and a decrease in operating frequency due to a temperature change do not easily occur. Even when having a high temperature, an OS transistor is likely to keep a property of the drain current increasing exponentially with respect to the gate-source voltage. Thus, the use of an OS transistor enables a stable operation in a high-temperature environment.

A metal oxide used for an OS transistor is a Zn oxide, a Zn—Sn oxide, a Ga—Sn oxide, an In—Ga oxide, an In—Zn oxide, an In-M-Zn oxide (M is Ti, Ga, Y, Zr, La, Ce, Nd, Sn, or Hf), or the like. The use of a metal oxide containing Ga as M for the OS transistor is particularly preferable because the electrical characteristics such as field-effect mobility of the transistor can be made excellent by adjusting a ratio of elements. In addition, an oxide containing indium and zinc may contain one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like.

In order to improve the reliability and electrical characteristics of the OS transistor, it is preferable that the metal oxide used in the semiconductor layer is a metal oxide having a crystal portion such as CAAC-OS, CAC-OS, or nc-OS. CAAC-OS is an abbreviation for c-axis-aligned crystalline oxide semiconductor. CAC-OS is an abbreviation for Cloud-Aligned Composite oxide semiconductor. In addition, nc-OS is an abbreviation for nanocrystalline oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The CAC-OS has a function of allowing electrons (or holes) serving as carriers to flow and a function of not allowing electrons serving as carriers to flow. The function of allowing electrons to flow and the function of not allowing electrons to flow are separated, whereby both functions can be heightened to the maximum. In other words, when CAC-OS is used for a channel formation region of an OS transistor, a high on-state current and an extremely low off-state current can be both achieved.

Avalanche breakdown or the like is less likely to occur in some cases in an OS transistor than in a general Si transistor because, for example, a metal oxide has a wide band gap and thus electrons are less likely to be excited, and the effective mass of a hole is large. Therefore, for example, it may be possible to inhibit hot-carrier degradation or the like that is caused by avalanche breakdown. Since hot-carrier degradation can be inhibited, an OS transistor can be driven with a high drain voltage.

An OS transistor is an accumulation transistor in which electrons are majority carriers. Therefore, DIBL (Drain-Induced Barrier Lowering), which is one of short-channel effects, affects an OS transistor less than an inversion transistor having a pn junction (typically a Si transistor). In other words, an OS transistor has higher resistance against short channel effects than a Si transistor.

Owing to its high resistance against short channel effects, an OS transistor can have a reduced channel length without deterioration in reliability, which means that the use of an OS transistor can increase the degree of integration in a circuit. Although a reduction in channel length enhances a drain electric field, avalanche breakdown is less likely to occur in an OS transistor than in a Si transistor as described above.

Since an OS transistor has a high resistance against short-channel effects, a gate insulating film can be made thicker than that of a Si transistor. For example, even in a minute OS transistor whose channel length and channel width are less than or equal to 50 nm, a gate insulating film as thick as approximately 10 nm can be provided in some cases. When the gate insulating film is made thick, parasitic capacitance can be reduced and thus the operating speed of a circuit can be improved. In addition, when the gate insulating film is made thick, leakage current through the gate insulating film is reduced, resulting in a reduction in static current consumption.

As described above, the CPU 10 can retain data owing to the backup circuit 10M, which is an OS memory, even when supply of power supply voltage is stopped. Thus, the power gating of the CPU 10 can be performed and power consumption can be reduced greatly. The backup circuit 10M, which is an OS memory, can be provided to be stacked with a circuit which is included in the CPU core 11 and which is composed of a Si transistor, such as a scan flip-flop circuit. Consequently, the backup circuit 10M can be provided without increasing in the circuit area.

The accelerator 20 includes a memory circuit 21, an arithmetic circuit 22, and a control circuit 23. The accelerator 20 has a function of executing a program (also referred to as kernel or a kernel program) called from a host program. The accelerator 20 can perform parallel processing of a matrix operation in graphics processing, parallel processing of a product-sum operation of a neural network, and parallel processing of a floating-point operation in a scientific computation, for example. Thus, this enables the semiconductor device 101 to have higher performance than when the structure including only the CPU 10 is employed.

The memory circuit 21 includes a plurality of data retention circuits 20M. The data retention circuit 20M can have a circuit configuration of a NOSRAM. “NOSRAM (registered trademark)” is an abbreviation for “Nonvolatile Oxide Semiconductor Random Access Memory (RAM)”. A NOSRAM is a memory in which its memory cell is a 2-transistor (2T) or 3-transistor (3T) gain cell, and its access transistor is an OS transistor. A current flowing between a source and a drain in an off state, that is, a leakage current, is extremely low in an OS transistor. The NOSRAM can be used as a nonvolatile memory by retaining electric charge corresponding to data in the data retention circuit 20M, using characteristics of an extremely low leakage current. In particular, the NOSRAM is capable of reading out retained data without destruction (non-destructive reading), and thus is suitable for parallel processing of a product-sum operation of a neural network in which only a data reading operation is repeated many times.

The arithmetic circuit 22 has a function of performing arithmetic processing using a digital value. The digital value is unlikely to be affected by noise. Thus, the accelerator 20 is suitable for performing arithmetic processing by which a highly accurate arithmetic result is required to be obtained. Note that the arithmetic circuit 22 is preferably formed using a Si CMOS, i.e., a transistor containing silicon in a channel formation region (Si transistor). With this configuration, the arithmetic circuit 22 can be provided by being stacked with the data retention circuit 20M including an OS transistor. The control circuit 23 has a circuit configuration for controlling circuits such as driver circuits in the accelerator 20.

Note that the arithmetic circuit 22 may perform arithmetic processing using an analog value. The data retention circuit 20M can retain electric charge corresponding to the analog value. With this configuration, arithmetic processing utilizing an analog signal output from the data retention circuit 20M including an OS transistor can be performed.

The accelerator 20 can continuously retain an analog value as data and can output, to the CPU 10, the arithmetic result obtained by an arithmetic operation in the arithmetic circuit. The analog value can be continuously retained as data, whereby the frequency of data transfer for arithmetic processing can be reduced. In addition, the amount of arithmetic processing of the CPU 10 can also be reduced, whereby the frequency of data transfer between the memory device 30 and the CPU 10 can be reduced. That is, with the structure of one embodiment of the present invention, the number of times of access through a bus 40A and the amount of data transferred through the bus 40A can be reduced.

The memory device 30 functions as an on-chip memory. The on-chip memory is a memory device for storing data or a program to be input to and output from the circuit included in the semiconductor device 101, such as the CPU 10 or the accelerator 20. The memory device 30 has a function of storing data or a program to be input to and output from the circuit included in the semiconductor device 101, such as the CPU 10 or the accelerator 20.

The memory device 30 includes a memory cell array 31 and a peripheral circuit 32. The memory cell array 31 includes memory cells 30M. A DOSRAM or a NOSRAM is preferable for a storage circuit that can be used for the memory cell 30M. A DOSRAM (registered trademark) is ab abbreviation of “Dynamic Oxide Semiconductor RAM”, which indicates a RAM including 1T (transistor) 1C (capacitor)-type memory cells. The DOSRAM, as well as the NOSRAM, is a memory utilizing a low off-state current of an OS transistor.

The DOSRAM is a DRAM formed using an OS transistor and is a memory that temporarily stores information transmitted from the outside. When the DOSRAM is employed, in the memory device 30, the memory cell 30M including an OS transistor and the peripheral circuit 32 including a Si transistor (a transistor containing silicon in a channel formation region) can be provided in different layers stacked; thus, the entire circuit area can be reduced with the DOSRAM. Furthermore, the DOSRAMs can be efficiently placed, with a memory cell array being finely divided. The DOSRAMs can be stacked when including OS transistors that are provided in a plurality of layers.

The bus 40A is a bus for transmitting and receiving at high speed various signals between the CPU 10, the accelerator 20, the memory device 30, the DMAC 41, the PMU 42, the memory controller 43, the DDR SDRAM controller 44, the USB interface circuit 45, and the display interface circuit 46. As an example, an AMBA (Advanced Microcontroller Bus Architecture)-AHB (Advanced High-performance Bus) can be used as a bus.

The DMAC 41 is a direct memory access controller. With the DMAC 41, a peripheral device other than the CPU 10 can access the memory device 30 not through the CPU 10.

The PMU 42 has a circuit configuration for controlling power gating of a circuit such as the CPU core 11 of the CPU 10 included in the semiconductor device 101.

The memory controller 43 has a circuit structure for writing or reading out a program to be executed by the CPU 10 or the accelerator 20 from a program memory outside the semiconductor device 101.

The DDR SDRAM controller 44 has a circuit structure for writing or reading out data to or from the main memory 103, such as a DRAM, outside the semiconductor device 101.

The USB interface circuit 45 has a circuit configuration for transmitting and receiving data to and from a circuit provided outside the semiconductor device 101 through a USB terminal. The USB interface circuit 45 has a circuit configuration for transmitting and receiving signals to and from an external general-purpose device.

The display interface circuit 46 has a circuit structure for transmitting and receiving data to and from the display 102 outside the semiconductor device 101.

The power supply circuit 60 is a circuit for generating a voltage used in the semiconductor device 101. For example, it is a circuit that generates a negative voltage supplied to a back gate of an OS transistor for stabilizing electrical characteristics.

A bus 40B is a bus for transmitting and receiving at low speed various signals between the interrupt control circuit 51, the interface circuit 52, the battery control circuit 53, and the ADC/DAC interface circuit 54. As an example, an AMBA-APB (Advanced Peripheral Bus) can be used as the bus. Transmission and reception of various signals between the bus 40A and the bus 40B are performed through the bridge circuit 50.

The interrupt control circuit 51 has a circuit structure for performing interrupt processing in response to a request received from a peripheral device.

The interface circuit 52 has a circuit structure for operating an interface such as a UART (Universal Asynchronous Receiver/Transmitter), an I2C (Inter-Integrated Circuit), or an SPI (Serial Peripheral Interface).

The battery control circuit 53 has a circuit structure for transmitting and receiving data related to charging and discharging of the battery 104 outside the semiconductor device 101.

The ADC/DAC interface circuit 54 has a circuit structure for transmitting and receiving data to and from the sensor 105 outside of the semiconductor device 101 that outputs an analog signal, such as a MEMS (Micro Electro Mechanical Systems) device.

Note that a configuration may be employed in which another circuit operating at low speed is connected to the bus 40B, such as a timer circuit or a watchdog circuit.

As illustrated in FIG. 1B, in the limited capacity of the housing 111 of the electronic device 100, electronic components such as the display 102, the main memory 103, the battery 104, and the sensor 105 are stored in addition to the semiconductor device 101. The semiconductor device 101 employs a structure in which the backup circuit 10M is provided in the CPU 10, a structure in which the data retention circuit 20M is provided in the accelerator 20, and a structure in which the memory cell 30M including an OS transistor is provided in the memory device 30; thus, reduction in the frequency of data transfer for arithmetic processing in the accelerator 20, and increase in the data capacity of the memory device 30 functioning as the on-chip memory can be achieved besides the power gating of the CPU 10.

As illustrated in FIG. 1B, the semiconductor device 101 of the electronic device 100 employs a structure in which the backup circuit 10M is provided in the CPU 10, a structure in which the data retention circuit 20M is provided in the accelerator 20, and a structure in which the memory cell 30M including an OS transistor is provided in the memory device 30; thus, a sleep power when the electronic device 100 is in a sleep state (power in a non-display period) can be significantly reduced and the electronic device 100 can accordingly have improved convenience even when the capacity of the battery is small.

As illustrated in FIG. 1B, in the electronic device 100, the number of times of data transfer between the on-chip memory, the CPU, and the accelerator can be reduced. In addition, when the on-chip memory, the CPU, and the accelerator are tightly coupled, i.e., what is called SoC (System on Chip) is made, the power consumption can be reduced and heat generation can be suppressed by fine-grained power gating; thus, a semiconductor device with a reduced size and increased performance can be achieved by using a Si transistor with a minuter structure.

Note that an EL display including a light-emitting device can be used as the display 102, for example. In addition, the display 102 may include a light-receiving device in addition to the light-emitting device. The display 102 may alternatively be a liquid crystal display including a liquid crystal device. The display 102 may alternatively be a μLED display including a micro light-emitting diode (μLED) device.

In this specification and the like, a structure in which a connector such as an FPC (Flexible Printed Circuit) or a TCP (Tape Carrier Package) is attached to a substrate included in a display, or a structure in which an IC (integrated circuit) is directly mounted on a substrate included in a display by a COG (Chip On Glass) method is referred to as a display module or the like, in some cases. The display 102 may be a display module, or the display 102 may be formed by directly providing a light-emitting device over the semiconductor device 101.

As the main memory 103, a DRAM can be used, for example. The main memory 103 can be omitted in the case where the memory device 30, which is an on-chip memory, has a large memory capacity and can thereby serve also as the main memory 103.

As the battery 104, a secondary battery such as a lithium-ion battery, a solar cell, or the like can be used, for example.

As the sensor 105, for example, a control circuit for preventing overcharging, an imaging element, a sensor such as a gyroscope sensor or an acceleration sensor, a touch panel, or the like may be provided. Furthermore, a sensor or the like for measuring a pulse, a surface temperature, a blood oxygen level, or the like by touch on part of a human body may be provided. When a sensor such as a gyroscope sensor or an acceleration sensor is included, power consumption can be reduced by switching an on state and an off state in response to the direction or movement of the electronic device. When a touch panel is included, an operation of the electronic device, inputting information, or the like can be performed by touching a predetermined position of the touch panel.

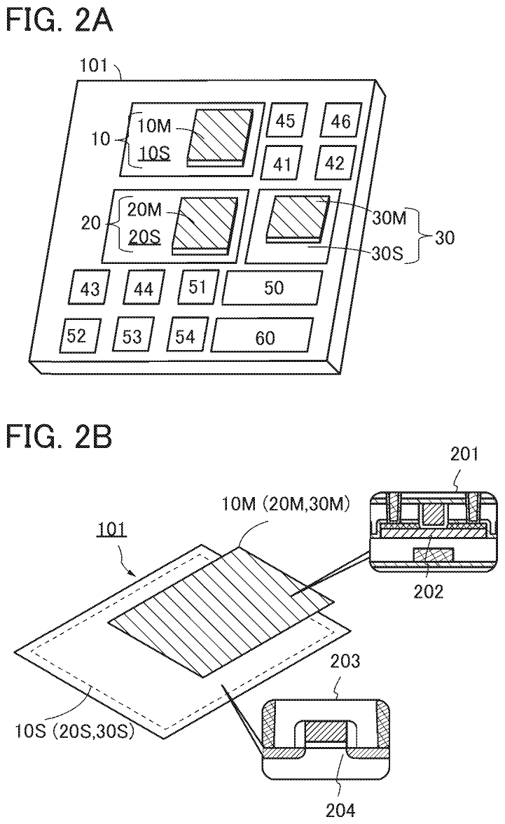

FIG. 2A is a diagram illustrating an arrangement example of circuit blocks when the structure illustrated in FIG. 1A is made into an SoC. As in the semiconductor device 101 illustrated in FIG. 2A, the components can be arranged in divided regions on a chip.

Note that the backup circuit 10M, the data retention circuit 20M, and the memory cell 30M described with reference to FIG. 1A can be placed over a circuit 10S, a circuit 20S, and a circuit 30S, respectively. The circuit 10S corresponds to a circuit that is composed of a Si transistor other than the backup circuit 10M in the CPU 10. The circuit 20S corresponds to a circuit that is composed of a Si transistor other than the data retention circuit 20M in the accelerator 20. The circuit 30S corresponds to a circuit that is composed of a Si transistor other than an OS transistor included in the memory cell 30M in the memory device 30.

FIG. 2B is a schematic view illustrating the backup circuit 10M (the data retention circuit 20M or the memory cell 30M) provided over the circuit 10S (the circuit 20S or the circuit 30S). As illustrated in FIG. 2B, the backup circuit 10M (the data retention circuit 20M or the memory cell 30M) includes a transistor 201 (OS transistor) containing a metal oxide in a semiconductor layer 202 including a channel formation region. The circuit 10S (the circuit 20S or the circuit 30S) includes a transistor 203 (Si transistor) containing silicon in a semiconductor layer 204 including a channel formation region. Thus, when the SoC is made, the CPU 10, the accelerator 20, and the memory device 30 can be arranged in the same region by integrating circuits as in the semiconductor device 101 illustrated in FIG. 2A.

According to one embodiment of the present invention described above, a novel electronic device and the like can be provided. Another embodiment of the present invention can provide an electronic device and the like with a novel structure which includes a semiconductor device having higher performance by adopting an SoC and in which heat generation and an increase in power consumption can be inhibited. Another embodiment of the present invention can provide an electronic device and the like with a novel structure in which the number of times of data transfer in a CPU can be reduced. Another embodiment of the present invention can provide an electronic device and the like with a novel structure in which both performance improvement of a semiconductor device and reduction in power consumption or heat generation of the semiconductor device can be achieved.

### <Structure Example of CPU 10>

An example of the CPU 10 including a CPU core capable of power gating is described.

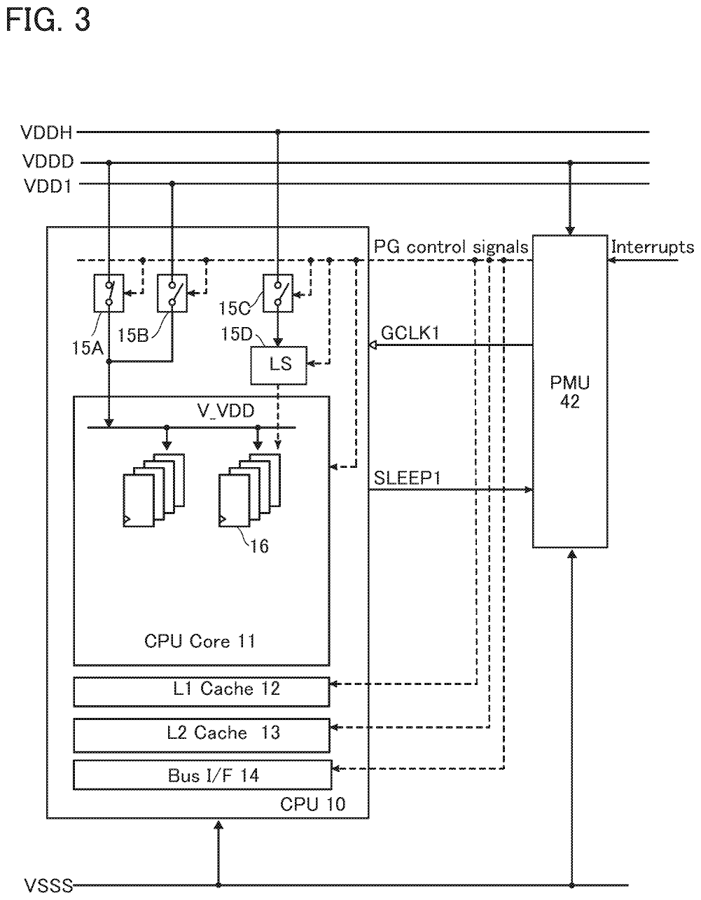

FIG. 3 illustrates a structure example of the CPU 10. The CPU 10 includes the CPU core 11, an L1 (level 1) cache memory device (L1 Cache) 12, an L2 cache memory device (L2 Cache) 13, a bus interface portion (Bus I/F) 14, power switches 15A to 15C, and a level shifter (LS) 15D. The CPU core 11 includes a flip-flop 16.

Through the bus interface portion 14, the CPU core 11, the L1 cache memory device 12, and the L2 cache memory device 13 are mutually connected to one another.

The PMU 42 generates a clock signal GCLK1 and various PG (power gating) control signals in response to signals such as an interrupt signal (Interrupts) input from the outside and a signal SLEEP1 issued from the CPU 10. The clock signal GCLK1 and the PG control signal are input to the CPU 10. The PG control signal controls the power switches 15A to 15C and the flip-flop 16.

The power switches 15A and 15B control supply of voltages VDDD and VDD1 to a virtual power supply line V_VDD (hereinafter referred to as a V_VDD line), respectively. The power switch 15C controls supply of a voltage VDDH to the level shifter (LS) 15D. A voltage VSSS is input to the CPU 10 and the PMU 42 not through the power switches. The voltage VDDD is input to the PMU 42 not through the power switches.

The voltages VDDD and VDD1 are drive voltages for a CMOS circuit. The voltage VDD1 is lower than the voltage VDDD and is a drive voltage in a sleep state. The voltage VDDH is a drive voltage for an OS transistor and is higher than the voltage VDDD.

The L1 cache memory device 12, the L2 cache memory device 13, and the bus interface portion 14 each include at least one power domain capable of power gating. The power domain capable of power gating is provided with one or a plurality of power switches. These power switches are controlled by the PG control signal.

The flip-flop 16 is used for a register. The flip-flop 16 is provided with a backup circuit. The flip-flop 16 is described below.

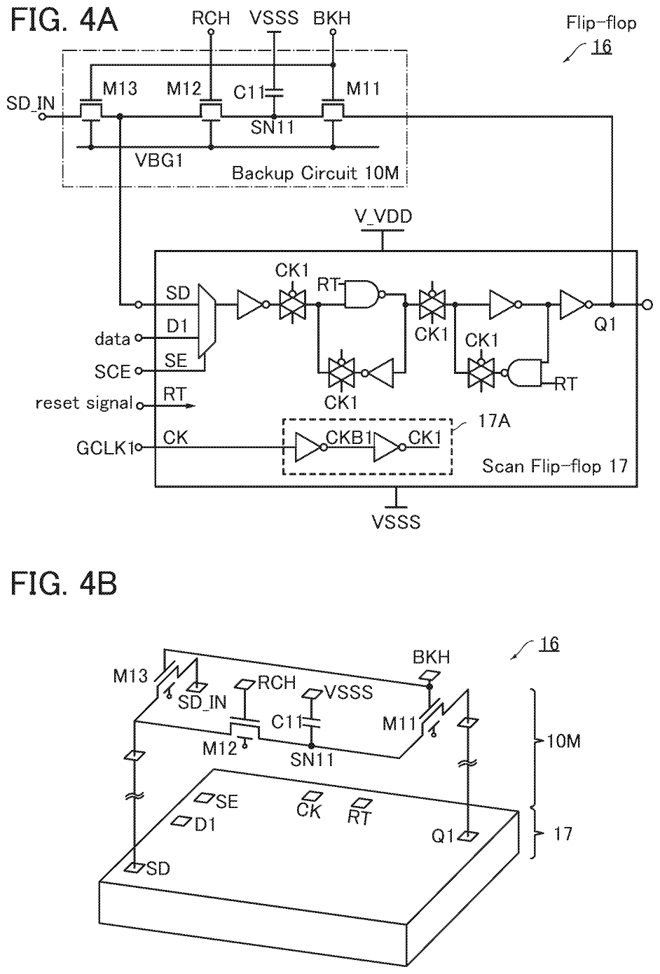

FIG. 4A shows a circuit structure example of the flip-flop 16. The flip-flop 16 includes a scan flip-flop circuit 17 and the backup circuit 10M.

The scan flip-flop circuit 17 includes nodes D1, Q1, SD, SE, RT, and CK and a clock buffer circuit 17A.

The node D1 is a data input node, the node Q1 is a data output node, and the node SD is a scan test data input node. The node SE is a signal SCE input node. The node CK is a clock signal GCLK1 input node. The clock signal GCLK1 is input to the clock buffer circuit 17A. Analog switches in the scan flip-flop circuit 17 are connected to nodes CK 1 and CKB1 of the clock buffer circuit 17A. The node RT is a reset signal input node.

The signal SCE is a scan enable signal, which is generated in the PMU 42. The PMU 42 generates signals BK and RC. The level shifter 15D level-shifts the signals BK and RC to generate signals BKH and RCH. The signals BK and RC are a backup signal and a recovery signal.

The circuit structure of the scan flip-flop circuit 17 is not limited to that in FIG. 4A. A flip-flop prepared in a standard circuit library can be applied.

The backup circuit 10M includes nodes SD_IN and SN11, transistors M11 to M13, and a capacitor C11.

The node SD_IN is a scan test data input node and is connected to the node Q1 of the scan flip-flop circuit 17. The node SN11 is a retention node of the backup circuit 10M. The capacitor C11 is a storage capacitor for retaining the voltage of the node SN11.

The transistor M11 controls continuity between the node Q1 and the node SN11. The transistor M12 controls continuity between the node SN11 and the node SD. The transistor M13 controls continuity between the node SD_IN and the node SD. The on/off of the transistors M11 and M13 is controlled by the signal BKH, and the on/off of the transistor M12 is controlled by the signal RCH.

The transistors M11 to M13 are OS transistors. The transistors M11 to M13 have back gates in the illustrated structure. The back gates of the transistors M11 to M13 are connected to a power supply line for supplying a voltage VBG1.

At least the transistors M11 and M12 are preferably OS transistors. Because of extremely low off-state current, which is a feature of the OS transistor, a decrease in the voltage of the node SN11 can be suppressed and almost no power is consumed to retain data; therefore, the backup circuit 10M has nonvolatile characteristics. Data is rewritten by charging and discharging of the capacitor C11; hence, there is theoretically no limitation on the number of times of rewriting of the backup circuit 10M, and data can be written and read out with low energy.

It is very preferable that all of the transistors in the backup circuit 10M be OS transistors. As shown in FIG. 4B, the backup circuit 10M can be stacked on the scan flip-flop circuit 17 configured with a silicon CMOS circuit.

The number of elements in the backup circuit 10M is much smaller than the number of elements in the scan flip-flop circuit 17; hence, there is no need to change the circuit structure and layout of the scan flip-flop circuit 17 in order to stack the backup circuit 10M. That is, the backup circuit 10M is a backup circuit that has very broad utility. In addition, the backup circuit 10M can be provided in a region where the scan flip-flop circuit 17 is formed; thus, even when the backup circuit 10M is incorporated, the area overhead of the flip-flop 16 can be zero. Thus, the backup circuit 10M is provided in the flip-flop 16, whereby power gating of the CPU core 11 is enabled. The power gating of the CPU core 11 is enabled with high efficiency owing to little power necessary for the power gating.

When the backup circuit 10M is provided, parasitic capacitance due to the transistor M11 is added to the node Q1; the parasitic capacitance is lower than parasitic capacitance due to a logic circuit connected to the node Q1, whereby there is no influence on the operation of the scan flip-flop circuit 17. That is, even when the backup circuit 10M is provided, the performance of the flip-flop 16 does not substantially decrease.

The CPU core 11 can be set to a clock gating state, a power gating state, or a resting state (non-operation) as a low power consumption state. The PMU 42 selects the low power consumption mode of the CPU core 11 on the basis of the interrupt signal, the signal SLEEP1, and the like. For example, in the case of transition from a normal operation state to a clock gating state, the PMU 42 stops generation of the clock signal GCLK1.

For example, in the case of transition from a normal operation state to a resting state (non-operation state), the PMU 42 performs voltage and/or frequency scaling. For example, when the voltage scaling is performed, the PMU 42 turns off the power switch 15A and turns on the power switch 15B to input the voltage VDD1 to the CPU core 11. The voltage VDD1 is voltage at which data in the scan flip-flop circuit 17 is not lost. When the frequency scaling is performed, the PMU 42 reduces the frequency of the clock signal GCLK1.

In the case where the CPU core 11 transitions from a normal operation state to a power gating state, data in the scan flip-flop circuit 17 is backed up to the backup circuit 10M. When the CPU core 11 is returned from the power gating state to the normal operation state, a recovery operation of writing back data in the backup circuit 10M to the scan flip-flop circuit 17 is performed.

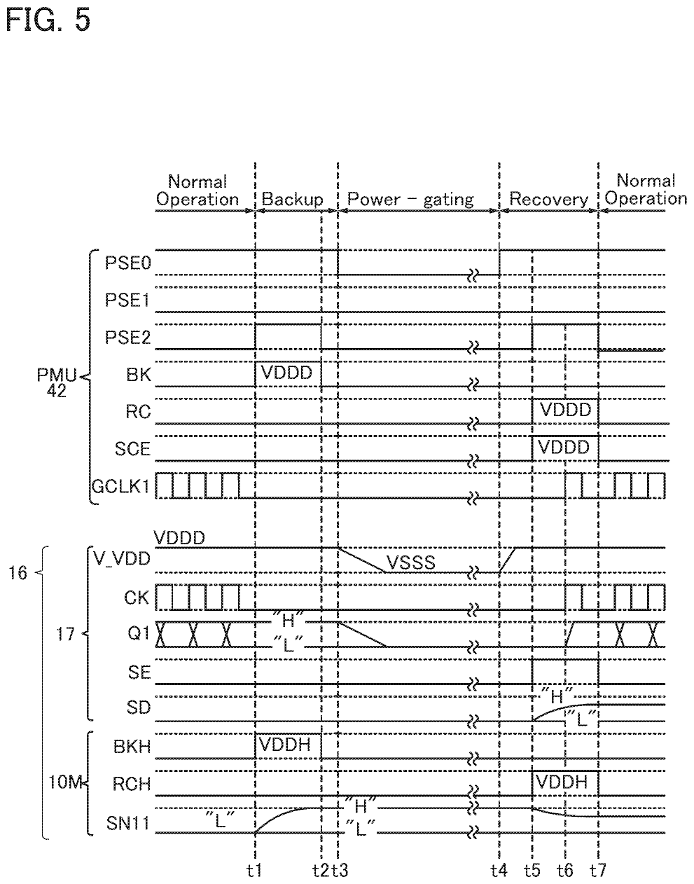

FIG. 5 illustrates an example of the power gating sequence of the CPU core 11. Note that in FIGS. 5, t1 to t7 represent the time. Signals PSE0 to PSE2 are control signals of the power switches 15A to 15C, which are generated in the PMU 42. When the signal PSE0 is at “H”/“L”, the power switch 15A is on/off. The same applies to the signals PSE1 and PSE2.

Until Time t1, a normal operation is performed. The power switch 15A is on, and the voltage VDDD is input to the CPU core 11. The scan flip-flop circuit 17 performs the normal operation. At this time, the level shifter 15D does not need to be operated; thus, the power switch 15C is off and the signals SCE, BK, and RC are each at “L”. The node SE is at “L”; thus, the scan flip-flop circuit 17 stores data in the node D1. Note that in the example of FIG. 5, the node SN11 of the backup circuit 10M is at “L” at Time t1.

A backup operation is described. At Time t1, the PMU 42 stops the clock signal GCLK1 and sets the signals PSE2 and BK at “H”. The level shifter 15D becomes active and outputs the signal BKH at “H” to the backup circuit 10M.

The transistor M11 in the backup circuit 10M is turned on, and data in the node Q1 of the scan flip-flop circuit 17 is written to the node SN11 of the backup circuit 10M. When the node Q1 of the scan flip-flop circuit 17 is at “L”, the node SN11 remains at “L”, whereas when the node Q1 is at “H”, the node SN11 becomes “H”.

The PMU 42 sets the signals PSE2 and BK at “L” at Time t2 and sets the signal PSE0 at “L” at Time t3. The state of the CPU core 11 transitions to a power gating state at Time t3. Note that at the timing when the signal BK falls, the signal PSE0 may fall.

A power-gating operation is described. When the signal PSE0 is set at “L”, data in the node Q1 is lost because the voltage of the V_VDD line decreases. The node SN11 retains data that is retained in the node Q1 at Time t3.

A recovery operation is described. When the PMU 42 sets the signal PSE0 at “H” at Time t4, the power gating state transitions to a recovery state. Charging of the V_VDD line starts, and the PMU 42 sets the signals PSE2, RC, and SCE at “H” in a state where the voltage of the V_VDD line becomes VDDD (at Time t5).

The transistor M12 is turned on, and charge in the capacitor C11 is distributed to the node SN11 and the node SD. When the node SN11 is at “H”, the voltage of the node SD increases. The node SE is at “H”, and thus, data in the node SD is written to a latch circuit on the input side of the scan flip-flop circuit 17. When the clock signal GCLK1 is input to the node CK at Time t6, data in the latch circuit on the input side is written to the node Q1. That is, data in the node SN11 is written to the node Q1.

When the PMU 42 sets the signals PSE2, SCE, and RC at “L” at Time t7, the recovery operation is terminated.

The backup circuit 10M using an OS transistor is extremely suitable for normally-off computing because both dynamic power consumption and static power consumption are low. Even when the flip-flop 16 is mounted, a decrease in the performance and an increase in the dynamic power of the CPU core 11 can be made hardly to occur.

Note that the CPU core 11 may include a plurality of power domains capable of power gating. In the plurality of power domains, one or a plurality of power switches for controlling voltage input are provided. In addition, the CPU core 11 may include one or a plurality of power domains where power gating is not performed. For example, the power domain where power gating is not performed may be provided with a power gating control circuit for controlling the flip-flop 16 and the power switches 15A to 15C.

Note that the application of the flip-flop 16 is not limited to the CPU 10. In an arithmetic device, the flip-flop 16 can be used as a register provided in a power domain capable of power gating.

### <Structure Example of Cache Memory Device>

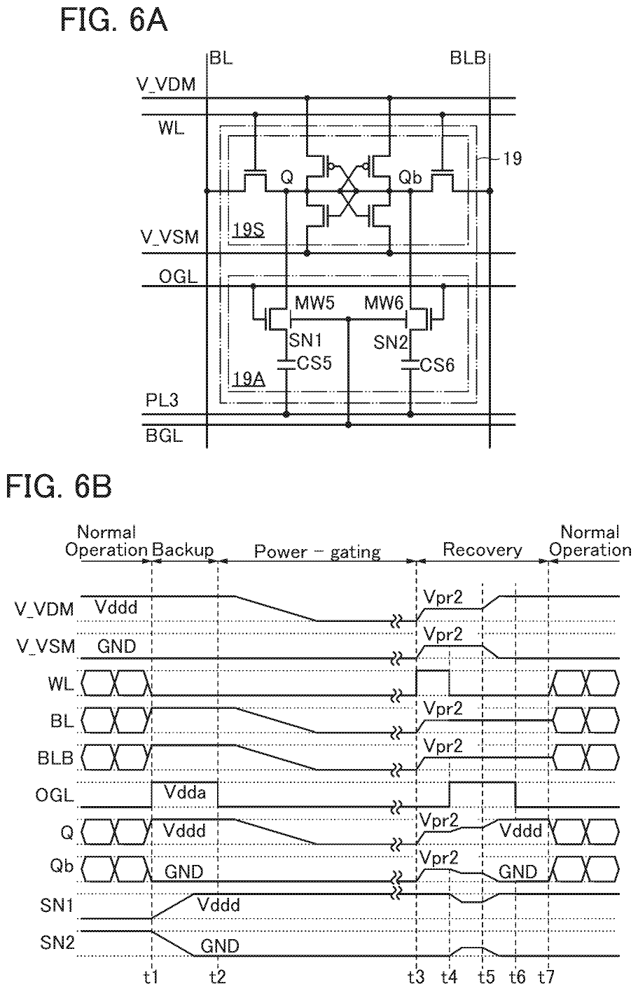

Although the CPU core 11 include the backup circuit in the illustrated structure example of the above CPU 10, the L1 cache memory device 12 and the L2 cache memory device 13 can include a backup circuit. FIG. 6A illustrates a memory cell 19 and is an example of a circuit diagram of a memory cell that can be used in a cache memory device such as the L1 cache memory device 12 or the L2 cache memory device 13. A memory cell 19S illustrated in FIG. 6A has the same circuit configuration as a standard 6T SRAM cell. A backup circuit 19A illustrated in FIG. 6A is a circuit in which the data in the memory cell 19S is to be saved.

The backup circuit 19A is a circuit for data backup of nodes Q and Qb in the memory cell 19S and is composed of two 1TIC cells. Nodes SN1 and SN2 are retention nodes. A gain cell composed of a transistor MW5 and a capacitor CS5 backs up data of the node Q. A gain cell composed of a transistor MW6 and a capacitor CS6 backs up data of the node Qb.

Since the transistors MW5 and MW6 are OS transistors, the backup circuit 19A can be provided by being stacked over the memory cell 19S. Accordingly, the area overhead of the memory cell 19 due to provision of the backup circuit 19A can be inhibited. The area overhead can be zero.

The memory cell 19S is electrically connected to power supply lines V_VDM and V_VSM, a word line WL, and a bit-line pair (BL and BLB). The power supply lines V_VDM and V_VSM are power supply lines for Vddd and GND, respectively. The backup circuit 19A is electrically connected to wirings OGL and BGL and a power supply line PL3. The voltage GND is input to the power supply line PL3.

The memory cell 19 operates as an SRAM cell in a normal state. The operation example of the memory cell 19 illustrated in FIG. 6A is described with reference to FIG. 6B. When the memory cell 19 is not accessed for a predetermined time or longer, the supply of the voltages Vddd and GND to the power supply lines V_VDM and V_VSM is stopped. Before the supply of the voltage Vddd is stopped, data of the nodes Q and Qb are written to the backup circuit 19A. Time is denoted by t1, t2, or the like in FIG. 6B.

Before Time t1, the memory cell 19 is in a normal operation state (a write state or a readout state). The memory cell 19 operates in a manner similar to that of a single-port SRAM. Here, at Time t1, the nodes Q/Qb are at “H”/“L”, and the nodes SN1/SN2 are at “L”/“H”.

At Time t1, “H” is input to a wiring OGL. Accordingly, a backup operation starts and the transistors MW5 and MW6 are turned on. The voltage of the node SN1 increases from GND to Vddd, and the voltage of the node SN2 decreases from Vddd to GND. The wiring OGL is at “L” at Time t2, whereby the backup operation terminates. Data of the nodes Q and Qb at t1 are written to the nodes SN1 and SN2.

At Time t2, power gating starts. The voltage of the power supply line V_VDM line is decreased from Vddd to GND. A voltage difference between the power supply line V_VDM and the power supply line V_VSM is reduced, whereby the memory cell 19S becomes inactive. Although data in the memory cell 19S is lost, the backup circuit 19A continues to retain data. Here, during the power gating, the bit lines BL and BLB are in floating states.

A recovery operation is an operation of recovering data of the memory cell 19S by data held in the backup circuit 19A. In the recovery operation, the memory cell 19S functions as a sense amplifier for sensing data in the nodes Q and Qb.

First, the reset operation of the nodes Q and Qb is performed. At Time t3, the voltage of the bit-line pair (BL and BLB) is precharged to a voltage Vpr2. In addition, the word line WL is in a selected state. Thus, the power supply line V_VDM line and the V_VSM line are precharged to the voltage Vpr2, and the voltages of the nodes Q and Qb are fixed to Vpr2.

The wiring OGL is at “H” at Time t4, whereby the transistors MW5 and MW6 are turned on. The charge in the capacitor CS5 is distributed to the node Q and the node SN1, the charge in the capacitor CS6 is distributed to the node Qb and the node SN2, and a voltage difference is generated between the node Q and the node Qb.

The supply of the voltages VDM and GND resumes at Time t5. When the memory cell 19S is activated, a voltage difference between the node Q and the node Qb is amplified. Finally, the voltages of the nodes Q and SN1 become Vddd, and the voltages of the nodes Qb and SN2 become GND. In other words, the states of the nodes Q/Qb are returned to the states at Time t1 (“H”/“L”).

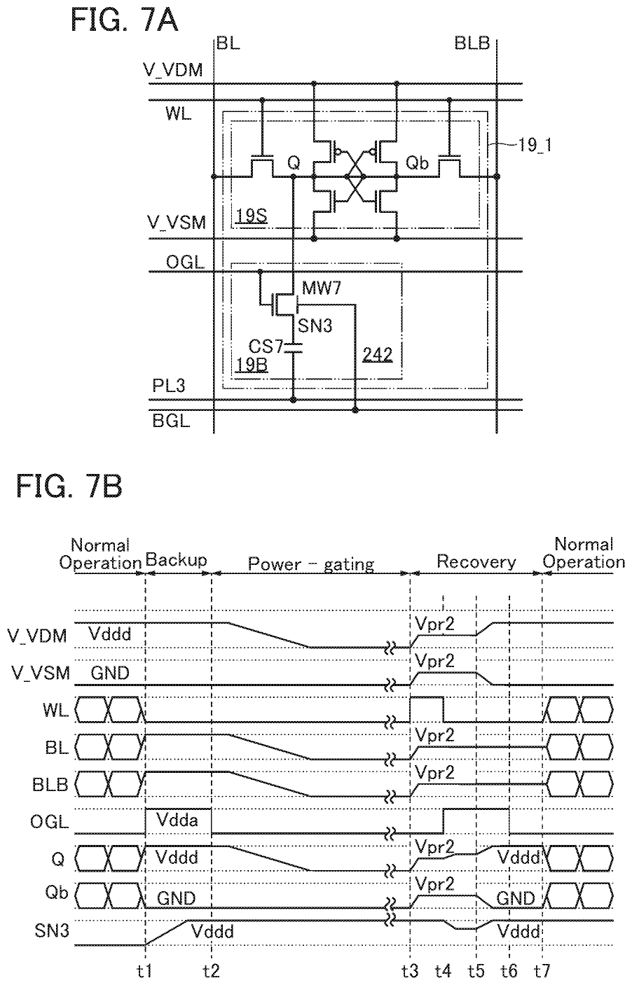

A memory cell 19_1 illustrated in FIG. 7A is a modification example of the memory cell 19 and includes the backup circuit 19A instead of a backup circuit 19B. The backup circuit 19B is composed of one 1TIC memory cell and includes a node SN3, a transistor MW7, and a capacitor CS7.

FIG. 7B is a timing chart showing an operation example of the memory cell 19_1. The memory cell 19_1 operates in a manner similar to that of the memory cell 19. The description of FIG. 6B can be referred to for the description of FIG. 7B.

The backup circuit 19B backs up only data of the node Q, but can restore data in the nodes Q and Qb with data held in the node SN3. This is because the voltages of the nodes Q and Qb are precharged to Vpr2 in advance, and thus, a potential difference can be generated between the node Q and the node Qb with the use of a charge in one capacitor CS7.

### <Structure Example of Accelerator 20>

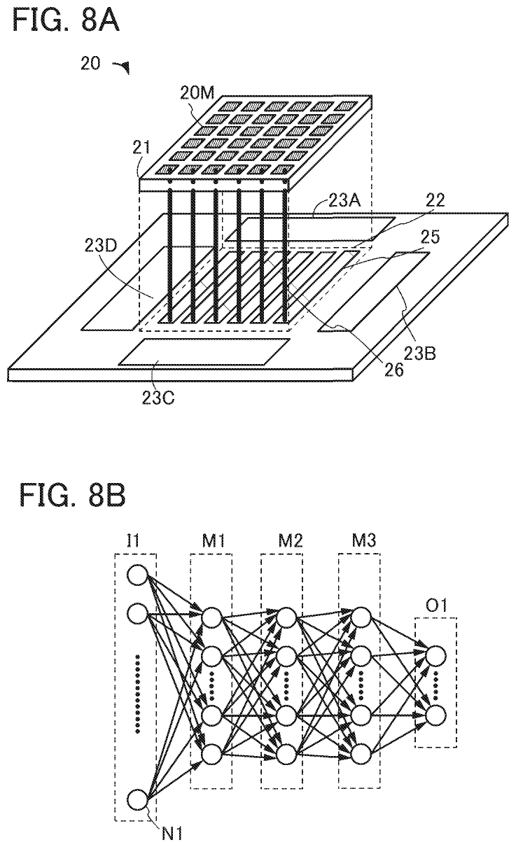

FIG. 8A is a block diagram for explaining the accelerator 20. FIG. 8A illustrates the control circuits 23 (23A to 23D), an arithmetic block 25, and a wiring 26 that connects the memory circuit 21 and the arithmetic circuit 22, in addition to the memory circuit 21 including the data retention circuit 20M and the arithmetic circuit 22, which are described with reference to FIG. 1A.

FIG. 8A illustrates a write bit line driver 23A, a word line driver 23B, a read bit line driver 23C, and a read driver 23D as examples of the component functioning as the control circuit 23. Note that the control circuit 23 may include a precharge circuit, a sense amplifier, a selector, an input buffer, an arithmetic control circuit, and the like.

The write bit line driver 23A and the word line driver 23B generate signals for writing data to the data retention circuit 20M, for example. The read bit line driver 23C and the read driver 23D generate signals for reading data from the data retention circuit 20M, for example.

The memory circuit 21 including the data retention circuit 20M has a function of storing data to be processed by the accelerator 20. Specifically, the memory circuit 21 can store data to be input to or output from the arithmetic circuit 22, such as weight data used for parallel processing of a product-sum operation of a neural network.

The data retention circuit 20M is electrically connected to the arithmetic block 25 included in the arithmetic circuit 22 through the wiring 26 and has a function of retaining a binary or ternary digital value. In the data retention circuit 20M, a transistor is an OS transistor, and the data retention circuit 20M is preferably an OS memory. The accelerator 20 can retain data owing to the data retention circuit 20M that is an OS memory even when supply of power supply voltage is stopped. Thus, the power gating of the accelerator 20 can be performed and power consumption can be reduced greatly.

The data retention circuit 20M formed using an OS transistor can be stacked with the arithmetic circuit 22 that can be formed using a Si CMOS. Consequently, the data retention circuit 20M can be provided without increasing the circuit area. The data retention circuit 20M and the arithmetic circuit 22 are electrically connected to each other through the wiring 26 provided to extend in the direction substantially perpendicular to a surface of the substrate provided with the arithmetic circuit 22. Note that “substantially perpendicular” refers to a state where an arrangement angle is greater than or equal to 85 degrees and less than or equal to 95 degrees.

The data retention circuit 20M can have a circuit structure of a NOSRAM. The NOSRAM can be used as a nonvolatile memory by retaining electric charge corresponding to data in the memory circuit, using characteristics of an extremely low leakage current. In particular, the NOSRAM is capable of reading out retained data without destruction (non-destructive reading), and thus is suitable for parallel processing of a product-sum operation of a neural network in which only a data reading operation is repeated many times.

A plurality of arithmetic blocks 25 included in the arithmetic circuit 22 have a function of performing arithmetic processing with a digital value. The digital value is unlikely to be affected by noise. Thus, the accelerator 20 is suitable for performing arithmetic processing that requires a highly accurate arithmetic result. Note that the arithmetic processing circuit 22 is preferably formed using a Si CMOS, i.e., a transistor containing silicon in a channel formation region (Si transistor). With this structure, an OS transistor can be stacked.

When the data retention circuit 20M is configured to retain and output data corresponding to a digital value, a hierarchical neural network based on the architecture of a Binary Neural Network (BNN) can be used. FIG. 8B illustrates a hierarchical neural network based on the architecture of BNN. FIG. 8B illustrates a fully connected neural network including a neuron N1, one input layer (I1), three intermediate layers (M1 to M3), and one output layer (O1). Given that the number of neurons in the input layer I1 is 786, the number of neurons in each of the intermediate layers M1 to M3 is 256, and the number of neurons in the output layer O1 is 10, the number of connections in the layers is (784×256)+(256×256)+(256×256)+(256×10), i.e., 334336 in total. That is, the weight parameter required for the neural network calculation is approximately 330 K bits in total, whereby the memory capacity is adequate for a small system.

The arithmetic block 25 has a function of performing any one of an integer arithmetic operation, a single precision floating-point arithmetic operation, a double precision floating-point arithmetic operation, and the like using data of the digital value retained in each data retain circuit 20M of the memory circuit 21. The arithmetic block 25 has a function of repeating the same processing such as a product-sum operation.

Note that the arithmetic block 25 employ such a structure that one the arithmetic block 25 is provided for every read bit line of the data retention circuit 20M, for every one column (Column-Parallel Calculation). With this structure, data of one row (all bit lines at the maximum) of the memory circuit 21 can be subjected to arithmetic processing in parallel. As compared to a product-sum operation using the CPU 10, there is no limitation on the data bus size (e.g., 32 bits) between the CPU and the memory, and thus the parallelism of an arithmetic operation can be greatly increased in Column-Parallel Calculation; accordingly, an arithmetic efficiency regarding an enormous amount of arithmetic processing such as learning of a deep neural network (deep learning) or a scientific computation that performs a floating-point arithmetic operation, which is the AI technology, can be improved. In addition, data output from the data retention circuit 20M can be read out after completion of the arithmetic operation of the data, whereby the number of times of memory access (data transfer between the CPU and the memory or an arithmetic operation in the CPU) can be reduced and power required for memory access can be reduced. Furthermore, when the physical distance between the arithmetic circuit 22 and the memory circuit 21 is decreased, for example, a wiring distance can be shortened by stacking layers, parasitic capacitance generated in a signal line can be reduced and low power consumption can be achieved.

One embodiment of the present invention can reduce the number of times of data transfer between the CPU 10 and the accelerator 20. In other words, a semiconductor device functioning as an accelerator used for the AI technology or the like with an enormous amount of calculation and an enormous number of parameters has a non-von Neumann architecture, and can perform parallel processing with extremely low power consumption as compared with a von Neumann architecture, in which power consumption increases with increasing processing speed.

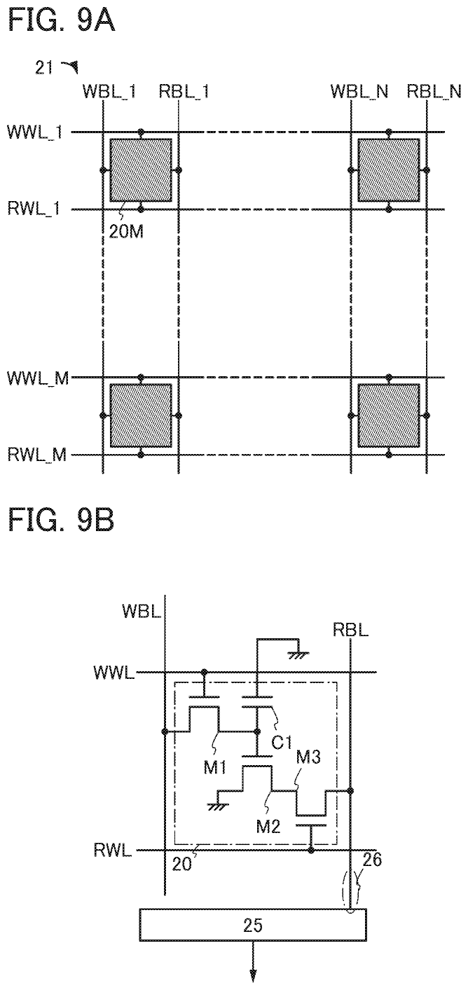

FIG. 9A is a diagram illustrating a circuit configuration example applicable to the memory circuit 21. FIG. 9A shows write word lines WWL_1 to WWL_M, read word lines RWL_1 to RWL_M, write bit lines WBL_1 to WBL_N, and read bit lines RBL_1 to RBL_N, which are arranged in a matrix of M rows and N columns (M and N are natural numbers greater than or equal to 2). The data retention circuits 20M connected to the word lines and the bit lines are also illustrated.

FIG. 9B illustrates a circuit configuration example applicable to the data retention circuit 20M. The data retention circuit 20M includes a transistor M1, a transistor M2, a transistor M3, and a capacitor C1.

One of a source and a drain of the transistor M1 is connected to a write bit line WBL. A gate of the transistor M1 is connected to a write word line WWL. The other of the source and the drain of the transistor M1 is connected to one electrode of the capacitor C1 and a gate of the transistor M2. One of a source and a drain of the transistor M2 and the other electrode of the capacitor C1 are connected to a wiring supplying a fixed potential such as a ground potential. The other of the source and the drain of the transistor M2 is connected to one of a source and a drain of the transistor M3. A gate of the transistor M3 is connected to a read word line RWL. The other of the source and the drain of the transistor M3 is connected to a read bit line RBL. As described above, the read bit line RBL is connected to the arithmetic block 25 through the wiring 26 or the like provided to extend in the direction substantially perpendicular to the surface of the substrate provided with the arithmetic circuit 22.

The circuit structure of the data retention circuit 20M illustrated in FIG. 9B corresponds to a NOSRAM of a 3-transistor (3T) gain cell. The transistor M1 to the transistor M3 are OS transistors. A current flowing between a source and a drain in an off state, that is, a leakage current, is extremely low in an OS transistor. The NOSRAM can be used as a nonvolatile memory by retaining electric charge corresponding to data in the memory circuit, using characteristics of an extremely low leakage current.

### <Structure Example of Memory Device 30>

Here, a structure example of the memory device 30 that is provided with the memory cell 30M including an OS transistor is described.

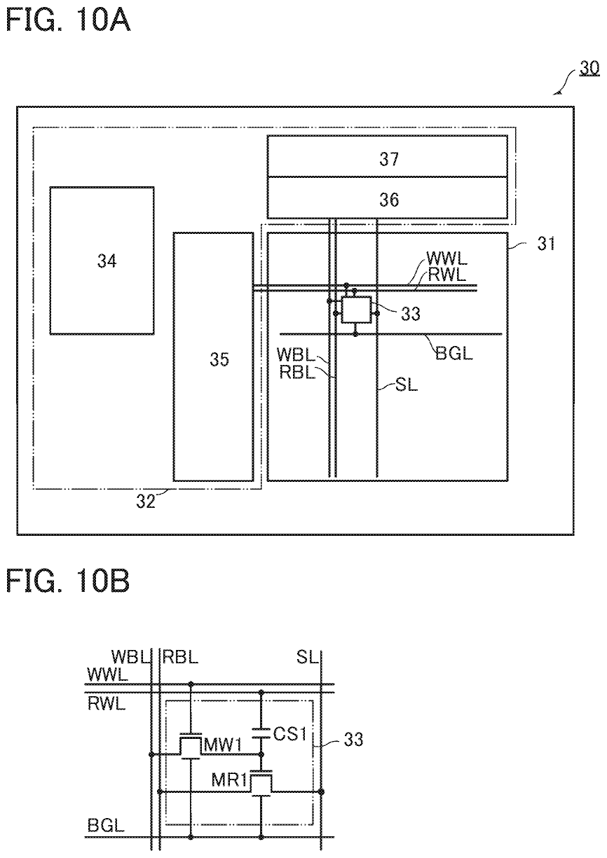

The memory device 30 illustrated in FIG. 10A includes the memory cell array 31 and the peripheral circuit 32. A control circuit 34, a row circuit 35, a column circuit 36, and an input/output circuit 37 are provided to form the peripheral circuit 32.

The memory cell array 31 includes a memory cell 33, the read word line RWL, the write word line WWL, the read bit line RBL, the write bit line WBL, a source line SL, and the wiring BGL. Note that the read word line RWL and the write word line WWL are referred to as a word line RWL and a word line WWL, respectively, in some cases. The read bit line RBL and the write bit line WBL are referred to as a bit line RBL and a bit line WBL, respectively, in some cases.

The control circuit 34 controls the memory device 30 as a whole and performs data writing and data reading. The control circuit 34 processes command signals from the outside (e.g., a chip enable signal, a write enable signal, and the like) and generates control signals for other circuits of the peripheral circuit 32.

The row circuit 35 has a function of selecting a row to be accessed. For example, the row circuit 35 includes a row decoder and a word line driver. The column circuit 36 has a function of precharging the bit lines WBL and RBL, a function of writing data to the bit line WBL, a function of amplifying data of the bit line RBL, a function of reading data from the bit line RBL, and the like. The input/output circuit 37 has a function of holding writing data, a function of holding readout data, and the like.

The configuration of the peripheral circuit 32 is changed as appropriate depending on the configuration, readout method, writing method, or the like of the memory cell array 31.

FIG. 10B illustrates a circuit structure example of the memory cell 33. The memory cell 33 here is a 2-transistor (2T) gain cell. The memory cell 33 includes transistors MW1 and MR1 and a capacitor CS1. The transistor MW1 is a write transistor and the transistor MR1 is a read transistor. Backgates of the transistors MW1 and MR1 are electrically connected to the wiring BGL.

Since the read transistor is composed of an OS transistor, the memory cell 33 does not consume power for data retention. Thus, the memory cell 33 is a memory cell with low power consumption that can retain for a long time, and the memory device 30 can be used as a nonvolatile memory device. The OS transistor and the capacitor can be stacked with a Si transistor. Accordingly, the memory cell array 31 can be stacked with the peripheral circuit 32, resulting in improvement in the integration degree of the memory cell array 31.

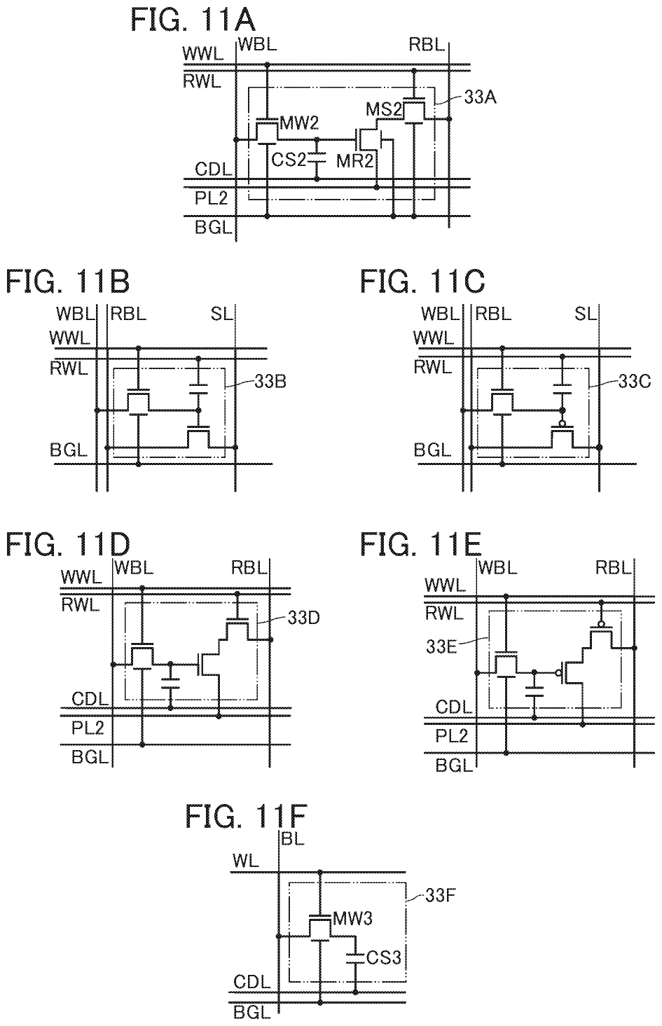

Other configuration examples of a memory cell are described with reference to FIG. 11A to FIG. 11F.

A memory cell 33A illustrated in FIG. 11A is a 3T gain cell, which includes transistors MW2, MR2, and MS2, and a capacitor CS2. The transistors MW2, MR2, and MS2 are a write transistor, a read transistor, and a selection transistor, respectively. Backgates of the transistors MW2, MR2, and MS2 are electrically connected to the wiring BGL. The memory cell 33A is electrically connected to the word lines RWL and WWL, the bit lines RBL and WBL, a capacitor line CDL, and a power supply line PL2. For example, the voltage GND (low-level-side power supply voltage) is input to the capacitor line CDL and the power supply line PL2.

FIG. 11B and FIG. 11C illustrate other configuration examples of a 2T gain cell. In a memory cell 33B illustrated in FIG. 11B, a read transistor is composed of an n-channel Si transistor. In a memory cell 33C illustrated in FIG. 11C, a read transistor is composed of a p-channel Si transistor. As illustrated in FIG. 11B and FIG. 11C, the transistors in the memory cell may be a combination of an OS transistor and a Si transistor.

FIG. 11D and FIG. 11E illustrate other configuration examples of a 3T gain cell. In a memory cell 33D illustrated in FIG. 11D, a read transistor and a selection transistor are composed of an n-channel Si transistor. In a memory cell 33E illustrated in FIG. 11E, a read transistor and a selection transistor are composed of a p-channel Si transistor. In the example of FIG. 11E, the voltage Vddd (high-level-side power supply voltage) is input to the power supply line PL2.

In the above-described gain cells, a bit line serving as both the read the bit line RBL and the write the bit line WBL may be provided.

FIG. 11F illustrates an example of a 1T1C (capacitor) memory cell. A memory cell 33F illustrated in FIG. 11F is electrically connected to the word line WL, the bit line BL, the capacitor line CDL, and the wiring BGL. The memory cell 33F includes a transistor MW3 and a capacitor CS3. A backgate of the transistor MW3 is electrically connected to the wiring BGL.

A circuit configuration of the memory cell 30M in the memory device 30 can be a circuit configuration in which a Si transistor is combined, for example, in addition to a circuit configuration including only OS transistors.

According to one embodiment of the present invention described above, a novel electronic device and the like can be provided. Another embodiment of the present invention can provide an electronic device or the like with a novel structure which includes a semiconductor device having higher performance by adopting an SoC and in which heat generation and an increase in power consumption can be inhibited. Another embodiment of the present invention can provide an electronic device and the like with a novel structure in which the number of times of data transfer in a CPU can be reduced. Another embodiment of the present invention can provide an electronic device and the like with a novel structure in which both performance improvement of a semiconductor device and reduction in power consumption or heat generation of the semiconductor device can be achieved.

### Embodiment 2

This embodiment describes an example of an operation of the case where part of arithmetic operation of a program executed by the CPU 10 is executed by the accelerator 20 in the electronic device 100 that is described above in Embodiment 1. Note that in this embodiment, structures denoted by the same reference numerals as those in the above embodiment are not repeatedly described in some cases.

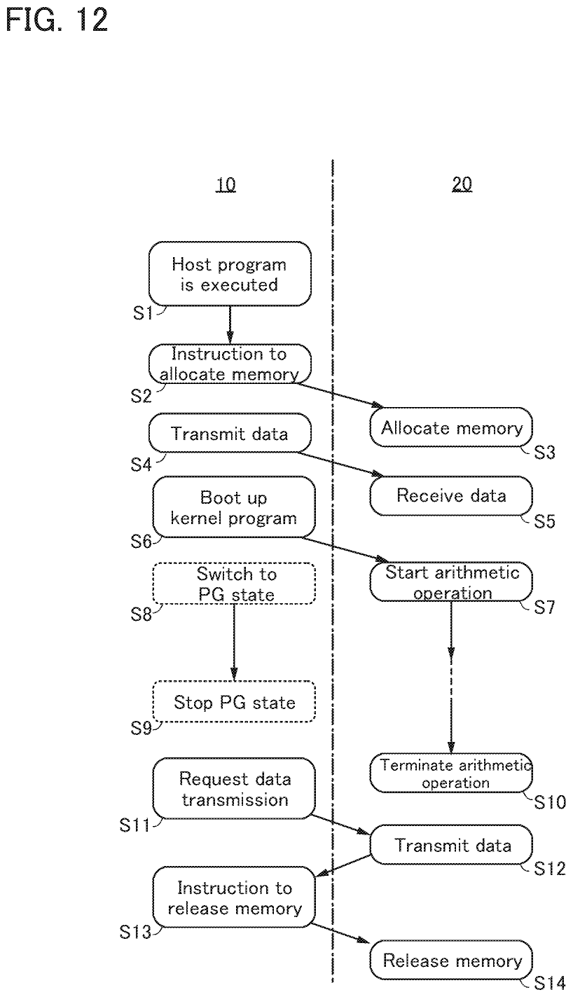

FIG. 12 shows an operation example of the case where the accelerator 20 executes part of arithmetic operation of a program executed by the CPU 10.

The host program is executed by the CPU 10 (Step S1).

In the case where the CPU 10 confirms an instruction to allocate, to the memory circuit 21, a region for data needed in performing an arithmetic operation using the accelerator 20 (Step S2), the CPU 10 allocates the region for the data to the memory circuit 21 (Step S3).

Next, the CPU 10 transmits input data from the main memory 103 or the memory device 30 to the above-described memory circuit 21 (Step S4). The above-described memory circuit 21 receives the input data and stores the input data in the region allocated in Step S2 (Step S5).

In the case where the CPU 10 confirms an instruction to boot up the kernel program (Step S6), the accelerator 20 starts execution of the kernel program (Step S7).

Immediately after the accelerator 20 starts the execution of the kernel program, the CPU 10 may be switched from the state of performing an arithmetic operation to a PG state (Step S8). In that case, just before the accelerator 20 terminates the execution of the kernel program, the CPU 10 is switched from the PG state to a state of performing an arithmetic operation (Step S9). By bringing the CPU 10 into a PG state during the period from Step S8 to Step S9, the power consumption and heat generation of the semiconductor device 101 as a whole can be suppressed.

When the accelerator 20 terminates the execution of the kernel program, output data is stored in the above-described memory circuit 21 (Step S10).

After the execution of the kernel program is terminated, in the case where the CPU 10 confirms an instruction to transmit the output data stored in the memory circuit 21 to the main memory 103 or the memory device 30 (Step S11), the above-described output data is transmitted to the above-described main memory 103 or the memory device 30 and stored in the above-described main memory 103 or the memory device 30 (Step S12).

In the case where the CPU 10 confirms an instruction to release the region for the data allocated to the memory circuit 21 (Step S13), the region allocated to the above-described memory circuit 21 is released (Step S14).

By repeating the operations from Step S1 to Step S14 described above, part of the arithmetic operation of the program executed by the CPU 10 can be executed by the accelerator 20 while the power consumption and heat generation of the CPU 10 and the accelerator are suppressed.

This embodiment can be combined with the description of the other embodiments as appropriate.

### Embodiment 3

In this embodiment, structure examples and modification examples of the semiconductor device 101 in which the CPU 10, the accelerator 20, and the memory device 30 are tightly coupled in the structure of the electronic device 100 described above in Embodiment 1 will be described.

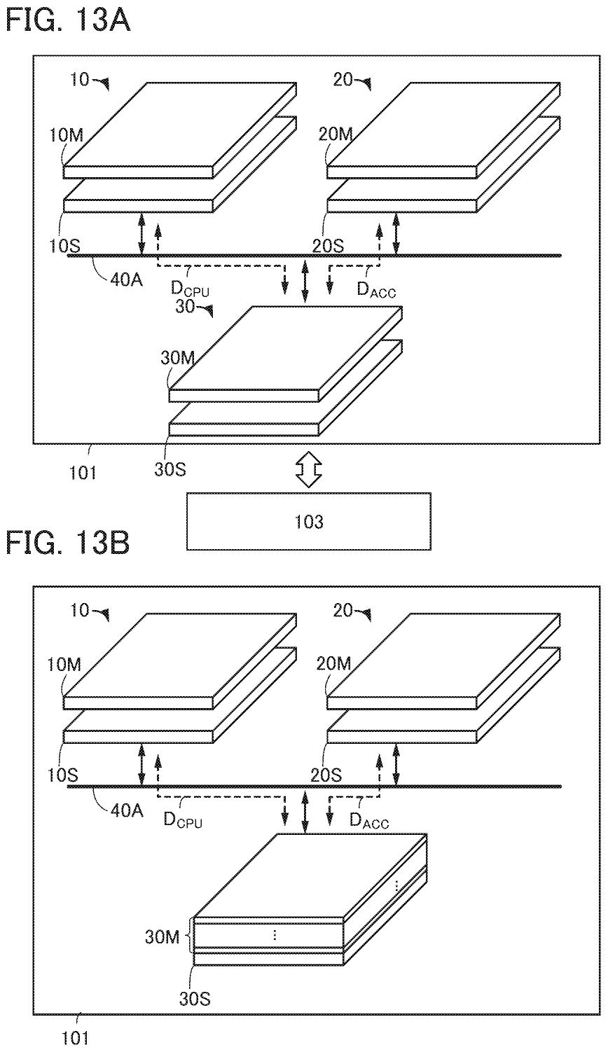

FIG. 13A illustrates the main memory 103 including a DRAM and the like in addition to the semiconductor device 101 including the CPU 10, the accelerator 20, and the memory device 30 which are connected to the bus 40A. In FIG. 13A, data transferred between the memory device 30 and the CPU 10 is shown as data Dept. In FIG. 13A, data transferred between the memory device 30 and the accelerator 20 is shown as data D_{ACC}.

As described above, in the structure of one embodiment of the present invention, the memory circuit 21 including the data retention circuit 20M in the accelerator 20 can continuously retain data, and the arithmetic result obtained by an arithmetic operation in the arithmetic circuit 22 can be output to the CPU 10. Thus, the data D_{ACC} for the arithmetic processing from the memory device 30 can be reduced. In addition, the amount of arithmetic processing of the CPU 10 can also be reduced, whereby the data Dept transferred between the memory device 30 and the CPU 10 can be reduced. That is, with the structure of one embodiment of the present invention, the number of access times through the bus 40A and the amount of transferred data can be reduced.

Note that OS transistors included in the backup circuit 10M of the CPU 10, the data retention circuit 20M of the accelerator 20, and the memory cell 30M of the memory device 30 can be stacked with the circuit 10S, the circuit 20S, and the circuit 30S that can be formed using Si CMOS. Consequently, the backup circuit 10M, the data retention circuit 20M, and the memory cell 30M can be provided without an increase in the circuit area.

When the memory device 30 is an OS memory such as a DOSRAM or a NOSRAM, the memory cell 30M is formed by stacking layers including OS transistors as illustrated in FIG. 13B and the highly integrated memory device 30 can be obtained; thus, the memory capacity per unit area can be increased. In this case, the main memory 103 that is provided separately from the semiconductor device 101 can be omitted.

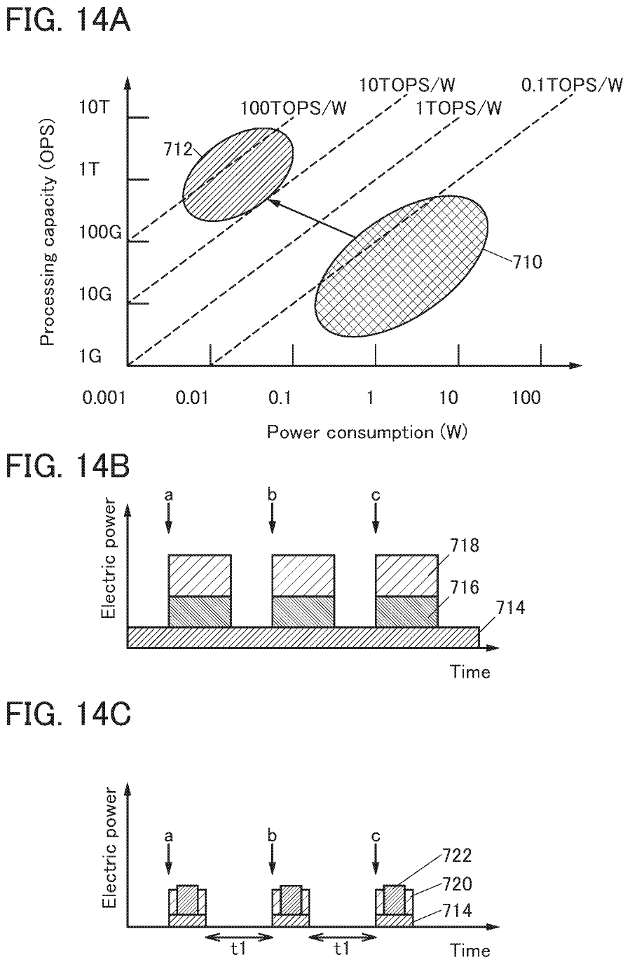

FIG. 14A illustrates the relationship between processing performance (OPS: Operations Per Second) and power consumption (W). In FIG. 14A, the vertical axis represents processing capacity and the horizontal axis represents power consumption. Furthermore, in FIG. 14A, as indicators of the arithmetic efficiency, dashed lines indicating 0.1 TOPS/W (Tera Operations Per Second/W), 1 TOPS/W, 10 TOPS/W, and 100 TOPS/W are shown.

In FIG. 14A, a region 710 is a region including a conventional general-purpose AI accelerator (Neumann type) and a region 712 is a region including the semiconductor device of one embodiment of the present invention. Note that a CPU (Central Processing Unit), a GPU (Graphics Processing Unit), an FPGA (Field-Programmable Gate Array), and the like are included in the region 710, for example.

As shown in FIG. 14A, the power consumption of the semiconductor device of one embodiment of the present invention can be lower than that of the conventional general-purpose AI accelerator (Neumann type) by approximately two digits, and the processing performance can be increased greatly (e.g., 1000 times or more). Note that an arithmetic efficiency of 100 TOPS/W or more can be expected with use of the semiconductor device of one embodiment of the present invention.

Here, specific examples of a conventional structure and a structure to which the semiconductor device of one embodiment of the present invention is applied are described with reference to FIG. 14B and FIG. 14C. FIG. 14B is an image diagram of power consumption of a semiconductor device having a conventional structure in image recognition, and FIG. 14C is an image diagram of power consumption of the semiconductor device having the structure of one embodiment of the present invention in image recognition.

In FIG. 14B and FIG. 14C, the vertical axis represents electric power and the horizontal axis represents time. In FIG. 14B, electric power 714 indicates leakage electric power, electric power 716 indicates CPU electric power, and electric power 718 indicates memory electric power. In FIG. 14C, the electric power 714 indicates leakage electric power, electric power 720 indicates CPU electric power, and electric power 722 indicates accelerator electric power. Note that the electric power 722 includes electric power used by the arithmetic circuit and the memory device.

In each of FIG. 14B and FIG. 14C, an arrow a, an arrow b, and an arrow c indicate signals in image recognition. Note that it is assumed that input of the signals indicated by the arrow a, the arrow b, and the arrow c starts arithmetic processing such as image recognition in the semiconductor devices.

As shown in FIG. 14B, a certain amount of leakage electric power (the electric power 714) is generated with respect to time in the semiconductor device having the conventional structure. In contrast, as shown in FIG. 14C, in the case where the semiconductor device of one embodiment of the present invention is employed, leakage electric power (the electric power 714) is generated while CPU electric power (the electric power 720) and accelerator electric power (the electric power 722) are used, but normally-off drive without generation of leakage electric power (the electric power 714) is possible in a period where CPU electric power (the electric power 720) and accelerator electric power (the electric power 722) are not used (in a period t1 shown in FIG. 14C). Thus, power consumption can be greatly reduced. That is, an ultralow power semiconductor device can be provided.

As described above, parts of circuits included in the memory device 30, the CPU 10, and the accelerator 20 of the semiconductor device 101 are formed using OS transistors, whereby an ultralow power semiconductor device in which the circuits are integrated can be achieved. Note that in a modification example of one embodiment of the present invention, an SoC may be made by providing another device above the circuit including an OS transistor.

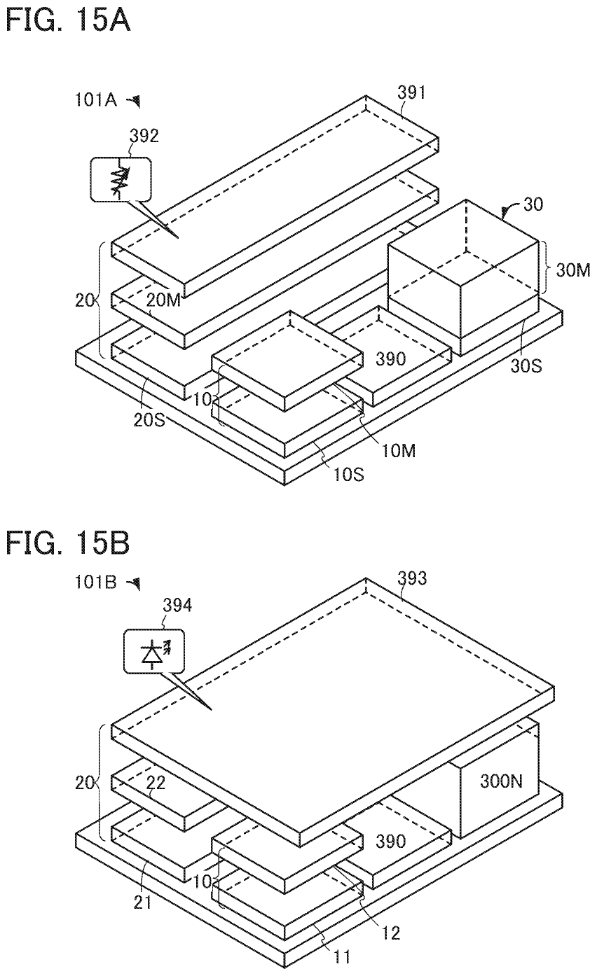

For example, in a semiconductor device 101A shown in the schematic view of FIG. 15A, a layer 391 including a variable resistor device 392 which is a memory device different from an OS memory is provided above the backup circuit 10M which is a layer including an OS transistor.

As illustrated in FIG. 15A, in the CPU 10, the backup circuit 10M including an OS transistor can be provided above the circuit 10S including the CPU core 11 and the like, and the layer 391 including the variable resistor device 392 can be provided above the backup circuit 10M. As illustrated in FIG. 15A, in the accelerator 20, the data retention circuit 20M that is a layer including an OS transistor can be provided above the circuit 20S including the arithmetic circuit 22 and the like. Similarly, the memory cell 30M provided by stacking the memory cell 30M can be placed over the circuit 30S including the peripheral circuit 32 and the like. In addition, a circuit 390, which includes a Si transistor and is included in the semiconductor device 101, and the like can be provided.

As the variable resistor device 392, a flash memory, a ferroelectric memory (FeRAM), a magnetoresistive memory (MRAM), a phase change memory (PRAM), a resistance-change memory (ReRAM), or the like can be used, for example.

As a magnetoresistive memory (MRAM), an STT-MRAM (Spin Transfer Torque-Magnetoresistive Random Access Memory), which is a memory using a magnetic tunnel junction (hereinafter MTJ) element, can be used. The MTJ element includes an unfixed layer (also referred to as a recording layer, a free layer, or a mobile layer) composed of a single layer or a stacked layer of ferromagnetic film, a fixed layer (also referred to as a fixed magnetized layer, a pin layer, or a reference layer), and an insulating layer (also referred to as a barrier layer, a tunnel insulating film, or a non-magnetic layer).

In the case of the SoC in which the circuits such as the CPU 10, the accelerator 20, and the memory device 30 are tightly coupled as illustrated in FIG. 15A, although heat generation is a problem, an OS transistor is preferable because the amount of change in the electrical characteristics due to heat is small as compared with a Si transistor. By integration of the circuits in the three-dimensional direction as illustrated in FIG. 15A, parasitic capacitance can be reduced as compared with a stacked-layer structure using a through silicon via (TSV), for example. Power consumption needed for charging and discharging wirings can be reduced. Consequently, the arithmetic processing efficiency can be improved.

For another example, in a semiconductor device 101B shown in a schematic view in FIG. 15B, a layer 393 including a light-emitting device 394 which is a memory device different from an OS memory is provided above the layers including OS transistors, such as the backup circuit 10M, the data retention circuit 20M, and the memory cell 30M. As the light-emitting device 394, a light-emitting device such as an organic light-emitting diode can be used.

In the case of the SoC in which the circuits such as the CPU 10, the accelerator 20, and the memory device 30 are tightly coupled as illustrated in FIG. 15B, although heat generation is a problem, an OS transistor is preferable because the amount of change in the electrical characteristics due to heat is small as compared with a Si transistor. By integration of the circuits in the three-dimensional direction as illustrated in FIG. 15B, parasitic capacitance can be reduced as compared with a stacked-layer structure using a through silicon via (TSV), for example. Power consumption needed for charging and discharging wirings can be reduced. Consequently, the arithmetic processing efficiency can be improved.

The configuration, structure, method, and the like described in this embodiment can be used in combination as appropriate with the configurations, structures, methods, and the like described in the other embodiments, the example, and the like.

### Embodiment 4

In this embodiment, structures of transistors that can be used for the semiconductor device included in the electronic device described in the above embodiments are described. As an example, a structure in which transistors having different electrical characteristics are stacked is described. With the structure, the flexibility in design of the semiconductor device can be increased. Stacking transistors having different electrical characteristics can increase the degree of integration of the semiconductor device.

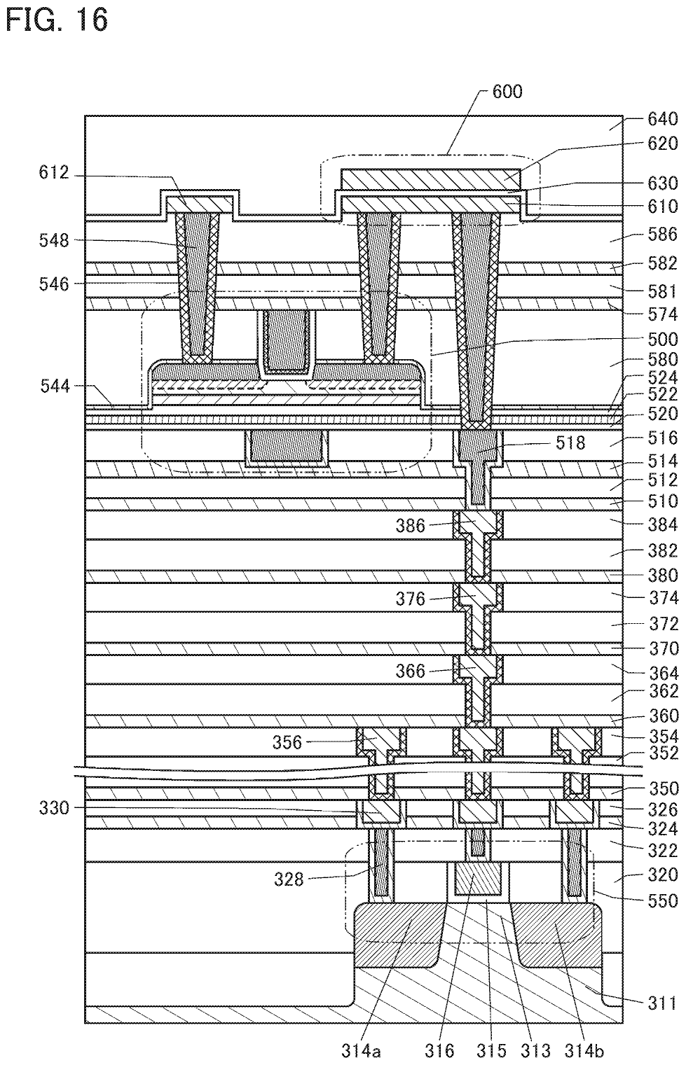

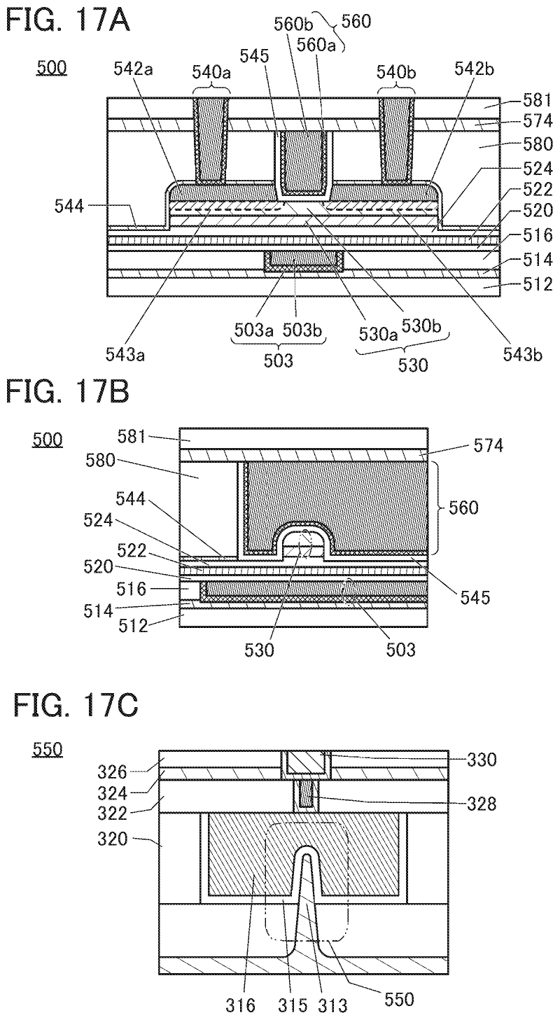

FIG. 16 illustrates part of a cross-sectional structure of a semiconductor device. A semiconductor device illustrated in FIG. 16 includes a transistor 550, a transistor 500, and a capacitor 600. FIG. 17A is a cross-sectional view of the transistor 500 in the channel length direction, FIG. 17B is a cross-sectional view of the transistor 500 in the channel width direction, and FIG. 17C is a cross-sectional view of the transistor 550 in the channel width direction. For example, the transistor 500 and the transistor 550 respectively correspond to the Si transistor and the OS transistor that are described in the above embodiment.

In FIG. 16, the transistor 500 is provided above the transistor 550, and the capacitor 600 is provided above the transistor 550 and the transistor 500.

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 17C, a top surface and a side surface in the channel width direction of the semiconductor region 313 of the transistor 550 is covered with the conductor 316 with the insulator 315 therebetween. The use of such a Fin-type transistor as the transistor 550 can increase the effective channel width and thus improve on-state characteristics of the transistor 550. In addition, since contribution of an electric field of a gate electrode can be increased, the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably contain a semiconductor such as a silicon-based semiconductor, and preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure using silicon whose effective mass is controlled by applying stress to the crystal lattice and changing the lattice spacing may be employed. Alternatively, the transistor 550 may be a HEMT (High Electron Mobility Transistor) with use of GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, a semiconductor material such as silicon containing the element which imparts n-type conductivity, such as arsenic or phosphorus, or the element which imparts p-type conductivity, such as boron, or a conductive material such as a metal material, an alloy material, or a metal oxide material can be used.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (Silicon on Insulator) substrate, for example

The SOI substrate may be an SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature heating or an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A transistor formed using a single crystal substrate contains a single crystal semiconductor in a channel formation region.

An insulator 320, an insulator 322, an insulator 324, and an insulator 326 are provided to be stacked in this order to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like may be used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to improve planarity.

In addition, for the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, silicon nitride deposited by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

The amount of released hydrogen can be analyzed by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm² in TDS analysis in a film-surface temperature range of 50° C. to 500° C., for example.

Note that the permittivity of the insulator 326 is preferably lower than that of the insulator 324. For example, the dielectric constant of the insulator 326 is preferably lower than 4, further preferably lower than 3. The dielectric constant of the insulator 326 is, for example, preferably 0.7 times or less, further preferably 0.6 times or less the dielectric constant of the insulator 324. When a material with a low permittivity is used for an interlayer film, the parasitic capacitance generated between wirings can be reduced.

In addition, a conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, there are cases where part of a conductor functions as a wiring and part of a conductor functions as a plug.

As a material for each of the plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

A wiring layer may be provided over the insulator 326 and the conductor 330. For example, in FIG. 16, an insulator 350, an insulator 352, and an insulator 354 are provided to be stacked in this order. Furthermore, a conductor 356 is formed in the insulator 350, the insulator 352, and the insulator 354. The conductor 356 has a function of a plug or a wiring that is connected to the transistor 550. Note that the conductor 356 can be provided using a material similar to those for the conductor 328 and the conductor 330.

Note that for example, as the insulator 350, like the insulator 324, an insulator having a barrier property against hydrogen is preferably used. Furthermore, the conductor 356 preferably contains a conductor having a barrier property against hydrogen. In particular, the conductor having a barrier property against hydrogen is formed in an opening portion included in the insulator 350 having a barrier property against hydrogen. With this structure, the transistor 550 and the transistor 500 can be separated by a barrier layer, so that diffusion of hydrogen from the transistor 550 into the transistor 500 can be inhibited.

For the conductor having a barrier property against hydrogen, tantalum nitride or the like is preferably used, for example. In addition, by stacking tantalum nitride and tungsten, which has high conductivity, the diffusion of hydrogen from the transistor 550 can be inhibited while the conductivity as a wiring is kept. In that case, a structure in which a tantalum nitride layer having a barrier property against hydrogen is in contact with the insulator 350 having a barrier property against hydrogen is preferable.

A wiring layer may be provided over the insulator 354 and the conductor 356. For example, in FIG. 16, an insulator 360, an insulator 362, and an insulator 364 are provided to be stacked in this order. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, as the insulator 360, like the insulator 324, an insulator having a barrier property against hydrogen is preferably used. Furthermore, the conductor 366 preferably contains a conductor having a barrier property against hydrogen. In particular, the conductor having a barrier property against hydrogen is formed in an opening portion of the insulator 360 having a barrier property against hydrogen. With this structure, the transistor 550 and the transistor 500 can be separated by a barrier layer, so that diffusion of hydrogen from the transistor 550 into the transistor 500 can be inhibited.

A wiring layer may be provided over the insulator 364 and the conductor 366. For example, in FIG. 16, an insulator 370, an insulator 372, and an insulator 374 are stacked sequentially. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, like the insulator 324, the insulator 370 is preferably formed using an insulator having a barrier property against hydrogen. Furthermore, the conductor 376 preferably contains a conductor having a barrier property against hydrogen. In particular, the conductor having a barrier property against hydrogen is formed in an opening portion of the insulator 370 having a barrier property against hydrogen. With this structure, the transistor 550 and the transistor 500 can be separated by a barrier layer, so that diffusion of hydrogen from the transistor 550 into the transistor 500 can be inhibited.

A wiring layer may be provided over the insulator 374 and the conductor 376. For example, in FIG. 16, an insulator 380, an insulator 382, and an insulator 384 are provided to be stacked in this order. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, like the insulator 324, the insulator 380 is preferably formed using an insulator having a barrier property against hydrogen. Furthermore, the conductor 386 preferably contains a conductor having a barrier property against hydrogen. In particular, the conductor having a barrier property against hydrogen is formed in an opening portion of the insulator 380 having a barrier property against hydrogen. With this structure, the transistor 550 and the transistor 500 can be separated by a barrier layer, so that diffusion of hydrogen from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device of this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are provided to be stacked in this order over the insulator 384. A substance having a barrier property against oxygen, hydrogen, or the like is preferably used for any of the insulator 510, the insulator 512, the insulator 514, and the insulator 516.

For example, for the insulator 510 and the insulator 514, it is preferable to use a film having a barrier property that prevents diffusion of hydrogen, impurities, or the like from the substrate 311, a region where the transistor 550 is provided, or the like into the region where the transistor 500 is provided. Thus, a material similar to that for the insulator 324 can be used.

For the film having a barrier property against hydrogen, silicon nitride deposited by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

In addition, for the film having a barrier property against hydrogen, a metal oxide such as aluminum oxide, hafnium oxide, or tantalum oxide is preferably used for the insulator 510 and the insulator 514, for example.

In particular, aluminum oxide has an excellent blocking effect that prevents the passage of both oxygen and impurities such as hydrogen and moisture that are factors of change in electrical characteristics of the transistor. Accordingly, aluminum oxide can prevent mixing of impurities such as hydrogen and moisture into the transistor 500 in the manufacturing process and after the manufacturing of the transistor. In addition, release of oxygen from an oxide included in the transistor 500 can be inhibited. Therefore, aluminum oxide is suitably used for a protective film of the transistor 500.

In addition, for the insulator 512 and the insulator 516, a material similar to that for the insulator 320 can be used, for example. When a material with a relatively low permittivity is used for these insulators, parasitic capacitance generated between wirings can be reduced. A silicon oxide film, a silicon oxynitride film, or the like can be used for the insulator 512 and the insulator 516, for example.

Furthermore, a conductor 518, a conductor included in the transistor 500 (e.g., a conductor 503), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated by a layer having a barrier property against oxygen, hydrogen, and water; thus, diffusion of hydrogen from the transistor 550 into the transistor 500 can be inhibited.

The transistor 500 is provided above the insulator 516.

As illustrated in FIG. 17A and FIG. 17B, the transistor 500 includes the conductor 503 placed to be embedded in the insulator 514 and the insulator 516, an insulator 520 placed over the insulator 516 and the conductor 503, an insulator 522 placed over the insulator 520, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and has an opening overlapping with a region between the conductor 542a and the conductor 542b, an insulator 545 placed on a bottom surface and a side surface of the opening, and a conductor 560 placed on the formation surface of the insulator 545.

As illustrated in FIG. 17A and FIG. 17B, an insulator 544 is preferably placed between the insulator 580 and the oxide 530a, the oxide 530b, the conductor 542a, and the conductor 542b. In addition, as illustrated in FIG. 17A and FIG. 17B, the conductor 560 preferably includes a conductor 560a provided inside the insulator 545 and a conductor 560b embedded inside the conductor 560a. Moreover, as illustrated in FIG. 17A and FIG. 17B, an insulator 574 is preferably placed over the insulator 580, the conductor 560, and the insulator 545.

Note that in this specification and the like, the oxide 530a and the oxide 530b are sometimes collectively referred to as an oxide 530.

Note that although a structure of the transistor 500 in which two layers of the oxide 530a and the oxide 530b are stacked in a region where a channel is formed and its vicinity is illustrated, the present invention is not limited thereto. For example, it is possible to employ a structure in which a single layer of the oxide 530b or a stacked-layer structure of three or more layers is provided.

Furthermore, although the conductor 560 is illustrated to have a stacked-layer structure of two layers in the transistor 500, the present invention is not limited thereto. For example, the conductor 560 may have a single-layer structure or a stacked-layer structure of three or more layers. The transistor 500 illustrated in FIG. 16 and FIG. 17A is just an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b function as a source electrode and a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. In other words, in the transistor 500, the gate electrode can be placed between the source electrode and the drain electrode in a self-aligned manner. Thus, the conductor 560 can be formed without an alignment margin, resulting in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

The conductor 560 functions as a first gate (also referred to as a top gate) electrode in some cases. In addition, the conductor 503 sometimes functions as a second gate (also referred to as bottom gate) electrode. In that case, the threshold voltage of the transistor 500 can be controlled by changing a potential applied to the conductor 503 not in synchronization with but independently of a potential applied to the conductor 560. In particular, the threshold voltage of the transistor 500 can be higher than 0 V and the off-state current can be reduced by applying a negative potential to the conductor 503. Thus, drain current at the time when a potential applied to the conductor 560 is 0 V can be lower in the case where a negative potential is applied to the conductor 503 than in the case where the negative potential is not applied to the conductor 503.

The conductor 503 is provided to overlap with the oxide 530 and the conductor 560. Thus, in the case where potentials are applied to the conductor 560 and the conductor 503, an electric field generated from the conductor 560 and an electric field generated from the conductor 503 are connected, so that a channel formation region formed in the oxide 530 can be covered.

In this specification and the like, a transistor structure in which a channel formation region is electrically surrounded by electric fields of a pair of gate electrodes (a first gate electrode and a second gate electrode) is referred to as a surrounded channel (S-channel) structure. Furthermore, in this specification and the like, the surrounded channel (S-channel) structure has a feature in that the side surface and the vicinity of the oxide 530 in contact with the conductor 542a and the conductor 542b functioning as the source electrode and the drain electrode are of I-type like the channel formation region. The side surface and the vicinity of the oxide 530 in contact with the conductor 542a and the conductor 542b are in contact with the insulator 544 and thus can be of I-type like the channel formation region. Note that in this specification and the like, “I-type” can be equated with “highly purified intrinsic” to be described later. The S-channel structure disclosed in this specification and the like is different from a Fin-type structure and a planar structure. With the S-channel structure, resistance to a short-channel effect can be enhanced, that is, a transistor in which a short-channel effect is less likely to occur can be provided.

In addition, the conductor 503 has a structure similar to that of the conductor 518; a conductor 503a is formed in contact with an inner wall of an opening in the insulator 514 and the insulator 516, and a conductor 503b is formed on the inner side. Note that although the transistor 500 having a structure in which the conductor 503a and the conductor 503b are stacked is illustrated, the present invention is not limited thereto. For example, the conductor 503 may be provided as a single layer or to have a stacked-layer structure of three or more layers.

Here, for the conductor 503a, a conductive material having a function of inhibiting diffusion of impurities such as a hydrogen atom, a hydrogen molecule, a water molecule, and a copper atom (through which the impurities are less likely to pass) is preferably used. Alternatively, it is preferable to use a conductive material that has a function of inhibiting diffusion of oxygen (e.g., at least one of an oxygen atom, an oxygen molecule, and the like) (through which oxygen is less likely to pass). Note that in this specification, the function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that contains tungsten, copper, or aluminum as its main component is preferably used for the conductor 503b. Note that although the conductor 503 is illustrated to have a stacked layer of the conductor 503a and the conductor 503b in this embodiment, the conductor 503 may have a single-layer structure.

The insulator 520, the insulator 522 and the insulator 524 have a function of a second gate insulating film.

Here, as the insulator 524 that is in contact with the oxide 530, an insulator that contains oxygen more than oxygen in the stoichiometric composition is preferably used. Such oxygen is easily released from the film by heating. In this specification and the like, oxygen released by heating is sometimes referred to as “excess oxygen”. That is, a region containing excess oxygen (also referred to as an “excess-oxygen region”) is preferably formed in the insulator 524. When such an insulator containing excess oxygen is provided in contact with the oxide 530, oxygen vacancies (V_{O}) in the oxide 530 can be reduced and the reliability of the transistor 500 can be improved. When hydrogen enters the oxygen vacancies in the oxide 530, such defects (hereinafter, referred to as V_{O}H in some cases) serve as donors and generate electrons serving as carriers in some cases. In other cases, bonding of part of hydrogen to oxygen bonded to a metal atom generates electrons serving as carriers. Thus, a transistor using an oxide semiconductor that contains a large amount of hydrogen is likely to be normally-on. Moreover, hydrogen in an oxide semiconductor is easily transferred by a stress such as heat or an electric field; thus, a large amount of hydrogen in an oxide semiconductor might reduce the reliability of a transistor. In one embodiment of the present invention, V_{O}H in the oxide 530 is preferably reduced as much as possible so that the oxide 530 becomes a highly purified intrinsic or substantially highly purified intrinsic oxide. It is important to remove impurities such as moisture and hydrogen in an oxide semiconductor (sometimes described as “dehydration” or “dehydrogenation treatment”) and to compensate for oxygen vacancies by supplying oxygen to the oxide semiconductor (sometimes described as “oxygen adding treatment”) in order to obtain an oxide semiconductor whose V_{O}H is sufficiently reduced. When an oxide semiconductor with sufficiently reduced impurities such as V_{O}H is used for a channel formation region of a transistor, stable electrical characteristics can be given.

As the insulator including an excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of 100° C. to 700° C., or 100° C. to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of V_{O}H is cut occurs, i.e., a reaction of “V_{O}H→V_{O}+H” occurs. Part of hydrogen generated at this time is bonded to oxygen to be H₂O, and removed from the oxide 530 or an insulator near the oxide 530 in some cases. Part of hydrogen may be gettered into a conductor 542 in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a fabrication process of the transistor 500, heat treatment is preferably performed with a surface of the oxide 530 exposed. The heat treatment is performed at higher than or equal to 100° C. and lower than or equal to 450° C., preferably higher than or equal to 350° C. and lower than or equal to 400° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. This can supply oxygen to the oxide 530 to reduce oxygen vacancies (V_{O}). The heat treatment may be performed under reduced pressure. Alternatively, the heat treatment may be performed in an atmosphere containing an oxidizing gas at 10 ppm or more, 1% or more, or 10% or more in order to compensate for released oxygen, after heat treatment in a nitrogen gas or inert gas atmosphere. Alternatively, the heat treatment may be performed in a nitrogen gas or inert gas atmosphere successively after heat treatment is performed in an atmosphere containing an oxidizing gas at 10 ppm or more, 1% or more, or 10% or more.

Note that the oxygen adding treatment performed on the oxide 530 can promote a reaction in which oxygen vacancies in the oxide 530 are filled with supplied oxygen, i.e., a reaction of “V_{O}+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

In addition, in the case where the insulator 524 includes an excess-oxygen region, it is preferable that the insulator 522 have a function of inhibiting diffusion of oxygen (e.g., an oxygen atom, an oxygen molecule, or the like) (through which oxygen is less likely to pass).

When the insulator 522 has a function of inhibiting diffusion of oxygen, impurities or the like, oxygen contained in the oxide 530 is not diffused to the insulator 520 side, which is preferable. Furthermore, the conductor 503 can be inhibited from reacting with oxygen contained in the insulator 524, the oxide 530, or the like.

For the insulator 522, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as a leakage current might arise because of a thinner gate insulating film. When a high-k material is used for an insulator functioning as the gate insulating film, a gate potential at the time of an operation of the transistor can be reduced while the physical thickness is maintained.

It is particularly preferable to use an insulator containing an oxide of one or both of aluminum and hafnium, which is an insulating material having a function of inhibiting diffusion of impurities, oxygen, and the like (through which oxygen is less likely to pass). Aluminum oxide, hafnium oxide, an oxide containing aluminum and hafnium (hafnium aluminate), or the like is preferably used as the insulator containing an oxide of one or both of aluminum and hafnium. In the case where the insulator 522 is formed using such a material, the insulator 522 functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over any of the above insulators.

It is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and a high relative dielectric constant.

Note that the transistor 500 in FIG. 17A and FIG. 17B includes the insulator 520, the insulator 522, and the insulator 524 as the second gate insulating film having a three-layer structure; however, the second gate insulating film may have a single-layer structure or a stacked-layer structure of two layers or four or more layers. In such cases, without limitation to a stacked-layer structure formed of the same material, a stacked-layer structure formed of different materials may be employed.

In the transistor 500, a metal oxide functioning as an oxide semiconductor is preferably used as the oxide 530 including a channel formation region. For example, as the oxide 530, a metal oxide such as an In-M-Zn oxide (the element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an ALD (Atomic Layer Deposition) method. Note that the metal oxide functioning as an oxide semiconductor is described in detail in another embodiment.

The metal oxide functioning as the channel formation region in the oxide 530 has a bandgap of preferably 2 eV or greater, further preferably 2.5 eV or greater. With the use of a metal oxide having such a wide band gap, the off-state current of the transistor can be reduced.

When the oxide 530 includes the oxide 530a under the oxide 530b, it is possible to inhibit diffusion of impurities into the oxide 530b from the components formed below the oxide 530a.

Note that the oxide 530 preferably has a stacked-layer structure of a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. Moreover, the atomic ratio of the element M to In in the metal oxide used as the oxide 530a is preferably greater than the atomic ratio of the element M to In in the metal oxide used as the oxide 530b. Furthermore, the atomic ratio of In to the element M in the metal oxide used as the oxide 530b is preferably greater than the atomic ratio of In to the element Min the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gently changes at a junction portion of the oxide 530a and the oxide 530b. In other words, the energy level of the conduction band minimum at the junction portion of the oxide 530a and the oxide 530b continuously changes or is continuously connected. This can be obtained by decreasing the density of defect states in a mixed layer formed at the interface between the oxide 530a and the oxide 530b.

Specifically, when the oxide 530a and the oxide 530b contain a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is used as the oxide 530a.

At this time, the oxide 530b serves as a main carrier path. When the oxide 530a has the above-described structure, the density of defect states at the interface between the oxide 530a and the oxide 530b can be made low. Thus, the influence of interface scattering on carrier conduction is small, and thus the transistor 500 can have a high on-state current.

The conductor 542a and the conductor 542b functioning as the source electrode and the drain electrode are provided over the oxide 530b. For the conductor 542a and the conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Furthermore, a metal nitride film of tantalum nitride or the like is preferable because it has a barrier property against hydrogen or oxygen.

Although the conductor 542a and the conductor 542b have a single-layer structure in FIG. 17A, they may have a stacked-layer structure of two or more layers. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed thereover; and a three-layer structure where a molybdenum film or a molybdenum nitride film is formed, an aluminum film or a copper film is stacked over the molybdenum film or the molybdenum nitride film, and a molybdenum film or a molybdenum nitride film is formed thereover. Note that a transparent conductive material containing indium oxide, tin oxide, or zinc oxide may be used.

As illustrated in FIG. 17A, a region 543a and a region 543b are sometimes formed as low-resistance regions at the interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier density of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. At this time, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator containing an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or do not significantly lose their conductivity even after absorbing oxygen. Design is appropriately set in consideration of required transistor characteristics.

When the insulator 544 is included, diffusion of impurities such as water and hydrogen contained in the insulator 580 into the oxide 530b can be inhibited. Furthermore, oxidation of the conductor 542 due to excess oxygen contained in the insulator 580 can be inhibited.

The insulator 545 functions as a first gate insulating film. Like the insulator 524, the insulator 545 is preferably formed using an insulator that contains excess oxygen and releases oxygen by heating

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

When an insulator containing excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen contained in the insulator 545 to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 into the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 can be used.

Note that the insulator 545 may have a stacked-layer structure like the second gate insulating film. As miniaturization and high integration of transistors progress, a problem such as a leakage current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have a high dielectric constant.

Although the conductor 560 functioning as the first gate electrode has a two-layer structure in FIG. 17A and FIG. 17B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, a reduction in conductivity of the conductor 560b due to oxidation caused by oxygen contained in the insulator 545 can be inhibited. As a conductive material having a function of inhibiting diffusion of oxygen, for example, tantalum, tantalum nitride, ruthenium, ruthenium oxide, or the like is preferably used. For the conductor 560a, the oxide semiconductor that can be used as the oxide 530 can be used. In that case, when the conductor 560b is deposited by a sputtering method, the conductor 560a can have a reduced electrical resistance value to be a conductor. This can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus is preferably a conductor having high conductivity. For example, a conductive material containing tungsten, copper, or aluminum as its main component can be used. The conductor 560b may have a stacked-layer structure, for example, a stacked-layer structure of any of the above conductive materials and titanium or titanium nitride.

The insulator 580 is provided over the conductor 542a and the conductor 542b with the insulator 544 therebetween. The insulator 580 preferably includes an excess-oxygen region. For example, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like is preferably contained as the insulator 580. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick for that, the conductor 560 might have a shape with a high aspect ratio. In this embodiment, the conductor 560 is provided to be embedded in the opening in the insulator 580; thus, even when the conductor 560 has a shape with a high aspect ratio, the conductor 560 can be formed without collapsing during the process.

The insulator 574 is preferably provided in contact with a top surface of the insulator 580, a top surface of the conductor 560, and a top surface of the insulator 545. When the insulator 574 is deposited using a sputtering method, excess-oxygen regions can be provided in the insulator 545 and the insulator 580. Thus, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness greater than or equal to 0.5 nm and less than or equal to 3.0 nm can inhibit diffusion of hydrogen and nitrogen. Thus, aluminum oxide deposited by a sputtering method serves as an oxygen supply source and can also have a function of a barrier film against impurities such as hydrogen.

An insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are positioned in openings formed in the insulator 581, the insulator 574, the insulator 580, and the insulator 544. The conductor 540a and the conductor 540b are provided to face each other with the conductor 560 therebetween. The structure of the conductor 540a and the conductor 540b are similar to a structure of a conductor 546 and a conductor 548 that will be described later.

An insulator 582 is provided over the insulator 581. A substance having a barrier property against oxygen, hydrogen, or the like is preferably used for the insulator 582. Thus, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of change in electrical characteristics of the transistor. Accordingly, aluminum oxide can prevent mixing of impurities such as hydrogen and moisture into the transistor 500 in the manufacturing process and after the manufacturing of the transistor. In addition, release of oxygen from an oxide included in the transistor 500 can be inhibited. Therefore, aluminum oxide is suitably used for a protective film of the transistor 500.

In addition, an insulator 586 is provided over the insulator 582. For the insulator 586, a material similar to that for the insulator 320 can be used. When a material with a relatively low permittivity is used for these insulators, parasitic capacitance generated between wirings can be reduced. A silicon oxide film, a silicon oxynitride film, or the like can be used as the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be provided using a material similar to those for the conductor 328 and the conductor 330.

After the transistor 500 is formed, an opening may be formed to surround the transistor 500 and an insulator having a high barrier property against hydrogen or water may be formed to cover the opening. Surrounding the transistor 500 with the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as part of the manufacturing steps of the transistor 500. The insulator having a high barrier property against hydrogen or water is formed using a material similar to that for the insulator 522 or the insulator 514, for example.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, a metal film containing an element selected from molybdenum, titanium, tantalum, tungsten, aluminum, copper, chromium, neodymium, and scandium; a metal nitride film containing the above element as its component (a tantalum nitride film, a titanium nitride film, a molybdenum nitride film, or a tungsten nitride film); or the like can be used. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each having a single-layer structure are shown in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In the case where the conductor 620 is formed concurrently with another component such as a conductor, Cu (copper), Al (aluminum), or the like, which is a low-resistance metal material, is used.

An insulator 640 is provided over the conductor 620 and the insulator 630. For the insulator 640, a material similar to that for the insulator 320 can be used. In addition, the insulator 640 may function as a planarization film that covers an uneven shape therebelow.

With the use of this structure, a semiconductor device using a transistor including an oxide semiconductor can be miniaturized or highly integrated.

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and an SOI (Silicon on Insulator) substrate. Alternatively, a plastic substrate having heat resistance to the processing temperature in this embodiment may be used. Examples of a glass substrate include barium borosilicate glass, aluminosilicate glass, aluminoborosilicate glass, and soda lime glass. Alternatively, crystallized glass or the like can be used.

Alternatively, a flexible substrate, an attachment film, paper including a fibrous material, a base film, or the like can be used as the substrate. As examples of the flexible substrate, the bonding film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Alternatively, polyamide, polyimide, an aramid resin, an epoxy resin, an inorganic vapor deposition film, and paper can be used. Specifically, the use of a semiconductor substrate, a single crystal substrate, an SOI substrate, or the like enables the manufacture of small-sized transistors with a small variation in characteristics, size, shape, or the like and with high current capability. A circuit using such transistors achieves lower power consumption or higher integration.

A flexible substrate may be used as the substrate, and a transistor, a resistor, a capacitor, and/or the like may be formed directly over the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance, a flexible substrate, or the like. As the above-described separation layer, a stack of inorganic films, a tungsten film and a silicon oxide film, an organic resin film of polyimide or the like formed over a substrate, or a silicon film containing hydrogen can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, it is possible to manufacture a flexible semiconductor device or a highly durable semiconductor device, to provide heat resistance, or to reduce a weight or a thickness.

Providing a semiconductor device over a flexible substrate can suppress an increase in weight and can produce a non-breakable semiconductor device.

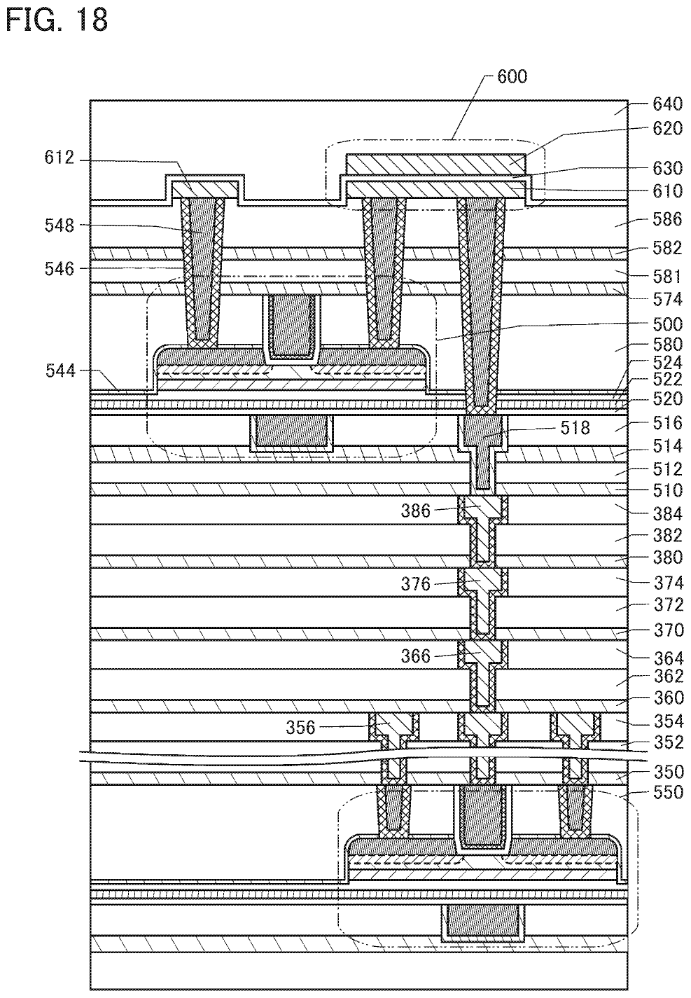

Note that the transistor 550 illustrated in FIG. 16 is an example and the structure is not limited thereto; an appropriate transistor is used in accordance with a circuit structure, a driving method, or the like. For example, when the semiconductor device is a single-polarity circuit using only OS transistors (which represent transistors having the same polarity, e.g., only n-channel transistors), the transistor 550 has a structure similar to that of the transistor 500 as illustrated in FIG. 18.

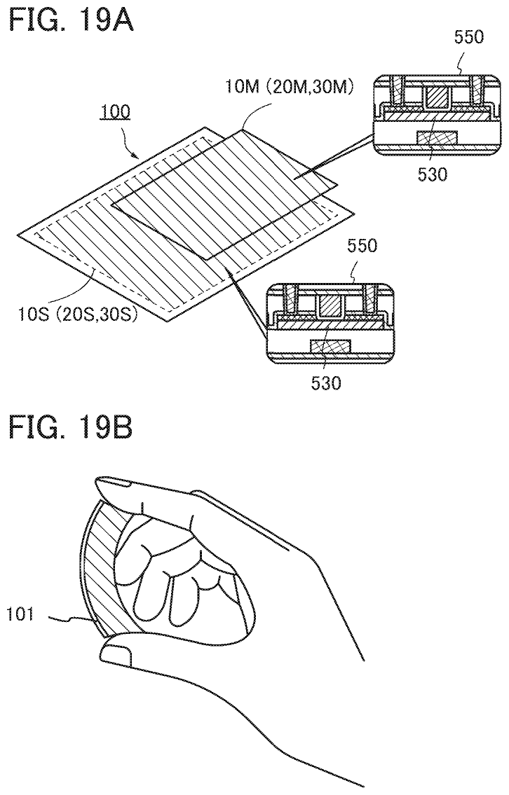

When the configuration illustrated in FIG. 18 is applied to the semiconductor device 101, both the circuit 10S (the circuit 20S or the circuit 30S) and the backup circuit 10M (the data retention circuit 20M or the memory cell 30M) over the circuit 10S, which are described in Embodiment 1, can be formed using OS transistors. Specifically, as illustrated in FIG. 19A, the circuit 10S (the circuit 20S or the circuit 30S) and the backup circuit 10M (the data retention circuit 20M or the memory cell 30M) includes the transistor 550 (OS transistor) containing the oxide 530 in a semiconductor layer including a channel formation region.

In the case where the circuit 10S (the circuit 20S or the circuit 30S) is configured with a Si transistor, breakage due to force by bending, twisting, or the like might be caused because the silicon substrate provided with the Si transistor is poor in flexibility. In contrast, when a circuit included in the semiconductor device 101 is formed with the OS transistors illustrated in FIG. 18 and FIG. 19A, providing the OS transistors over a flexible substrate formed using a polyimide resin or the like makes it possible to obtain the semiconductor device 101 that can be freely changed in shape as illustrated in FIG. 19B. Furthermore, the semiconductor device 101 can be less likely to be broken by impact. Thus, the electronic device including the semiconductor device 101 can be a well-designed electronic device in which the semiconductor device can be inhibited from being broken by impact.

The configuration, structure, method, and the like described in this embodiment can be used in combination as appropriate with the configurations, structures, methods, and the like described in the other embodiments, the example, and the like.

### Embodiment 5

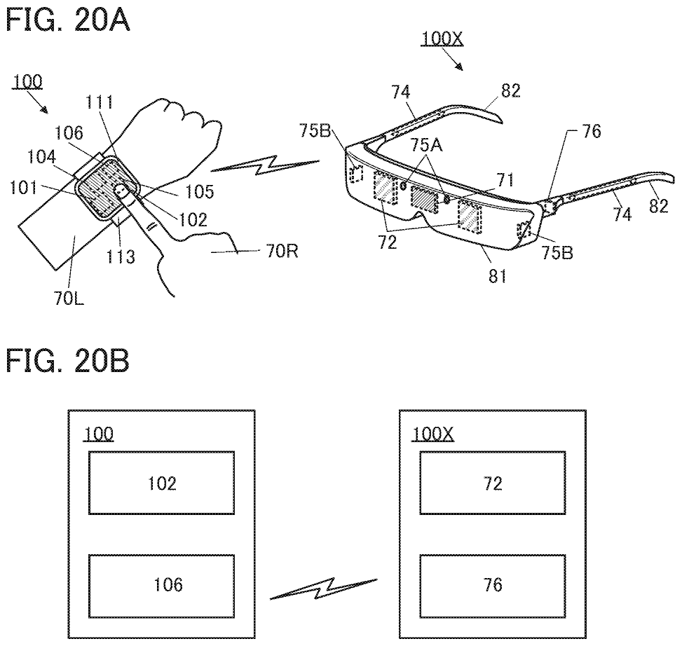

In this embodiment, a display system using a combination of the electronic device of one embodiment of the present invention and another electronic device will be described with reference to FIG. 20 to FIG. 25.

### <Structure Example of Display System>

FIG. 20A to FIG. 20C are diagrams illustrating structure examples of a display system of one embodiment of the present invention.

As illustrated in FIG. 20A, the display system of one embodiment of the present invention includes the electronic device 100 described above in Embodiment 1 and the like and a head-mounted type electronic device 100X (also referred to as an HMD (Head Mounted Display). The electronic device 100 and the electronic device 100X each include a wireless communication means. The display of the electronic device 100X includes a region with a higher pixel density (also referred to as resolution) than that of the electronic device 100. The display system has a function of displaying a screen of the electronic device 100 or part of the screen on the electronic device 100X with the use of the above wireless communication means.

As illustrated in FIG. 20A, the display system of one embodiment of the present invention includes a plurality of electronic devices. The plurality of electronic devices perform data communication using a wireless communication means and image data displayed on a screen of one electronic device can be partly processed by a processing method such as up-conversion or down-conversion of the data, so that the processed data can be displayed on another electronic device. Such a display system enables greater user convenience, image display with the most suitable image quality for an individual electronic device, or lower power consumption of the electronic devices.

The electronic device 100 illustrated in FIG. 20A includes the display 102, the housing 111, a communication portion 106, the semiconductor device 101, the battery 104, the sensor 105, and the band 113. A right hand 70R of a user and a left hand 70L of the user are illustrated in FIG. 20A. The electronic device 100X includes a housing 81, a control portion 71, a display 72, a battery 74, a sensor 75A and a sensor 75B (referred to as a sensor 75 in some cases), a communication portion 76, and a wearing portion 82. Note that wireless communication between the electronic device 100 and the electronic device 100X can be performed between the communication portion 106 and the communication portion 76 as illustrated in FIG. 20A. Note that the communication portion 106 has a function of transmitting information to the electronic device 100X in accordance with the operation of the electronic device 100. The communication portion 76 has a function of transmitting information to the electronic device 100 in accordance with the operation of the electronic device 100X.

The electronic device 100X illustrated in FIG. 20A has one or both of a function of displaying a content of augmented reality (AR) and a function of displaying a content of virtual reality (VR). Note that the electronic device 100X may also have a function of displaying contents of substitutional reality (SR) or contents of mixed reality (MR), in addition to contents of AR and VR. The electronic device 100X having a function of displaying contents of AR, VR, SR, MR, or the like enables the user to reach a higher level of immersion.

Note that the sensor 75A included in the electronic device 100X has a function of a camera portion that obtains information on the outside of the electronic device 100X. As an example, FIG. 20A illustrates a state where two sensors 75A are provided outside the housing 81 and information on the surroundings on the user side is obtained. When a plurality of sensors 75A are arranged as camera portions for obtaining information on the surroundings of the user in this manner, information which cannot be obtained by naked eyes can be obtained with the sensors 75A, compared to the case of obtaining information on the surroundings of the user by naked eyes. Therefore, the amount of information that can be obtained by the user can be increased. For example, data obtained by the sensor 75A can be output to the display 72, or the display 102 included in the electronic device 100.

The sensor 75B included in the electronic device 100X has a function of a camera portion that obtains information on the user side of the electronic device 100X. As an example, FIG. 20A illustrates a state where two sensors 75A are provided inside the housing 81 so that images of the user's eyes can be captured and information around the user's eyes is obtained. When the sensors 75A are arranged as camera portions for obtaining information on the user's eyes, eye tracking (gaze tracking) can be performed. Thus, the display 72 can perform display in accordance with the user's gaze.

The user can wear the electronic device 100X on a head with the wearing portion 82 included in the electronic device 100X. Note that FIG. 20A shows an example where the wearing portion has a shape like a temple of glasses (also referred to as a joint or the like); however, the shape is not limited thereto. The wearing portion 82 can have any shape with which the user can wear the electronic device, for example, a shape of a helmet or a band.

Although the example where the sensor 75A is used as a camera portion is shown here, a range sensor capable of measuring a distance between the user and an object (hereinafter also referred to as a sensing portion) may be used. That is, the sensor 75A and the sensor 75B are each one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The user can manipulate an image (also referred to as data object) displayed on the display 72 of the electronic device 100X with an intuitive gesture operation as if the image is an actual object. For example, the user can pinch an image that is displayed to have a plate-like shape and be floating with the hand. The pinched image can be removed by being thrown like a Frisbee. The pinched image can be moved up, down, left, and right. The pinched image can be moved back and forth, so that the image can be enlarged and downsized. The pinched image can be reversed. At this time, a rotation axis can be in the vertical direction, the horizontal direction, or the oblique direction. When the edge of the field of view where nothing is displayed is pinched and dragged, the plate-like image can be drawn out. When the plate-like image is pushed to the direction apart from the user, the image can be removed. In addition, the user can remove the image by putting the hand on the edge of the plate-like image and then moving the hand left or right. After such an image removing movement, another image may be displayed. The user may register specific information in the electronic device 100X in advance. For example, movements from an action of spreading a palm to an action of putting a thumb and an index finger together (a movement of making a circle with a thumb and an index finger) can be registered as first processing information, and second processing information can be executed on the basis of the first processing information. Note that as the second processing information, for example, the user can freely register data on an operation such as removing an image, displaying a specific image, or displaying a shortcut icon.

It is preferable to provide a plurality of sensing portions in an electronic device or an electronic apparatus so that a highly accurate gesture operation by the user using a plurality of actions such as an action using both hands can be provided for the operation of the electronic device. This enables three-dimensional positional information on a plurality of objects to be detected with higher accuracy, so that input with a complicated gesture operation is possible.

The user can manipulate an image (also referred to as data object) displayed on the display 72 of the electronic device 100X with a gesture operation using both hands, for example, as if the image is an actual object. For example, the user can pinch an image that is displayed to have a plate-like shape and be floating by its two portions (e.g., upper and bottom portions, left and right portions, or diagonally opposite portions). The image that the user is pinching with both hands can be enlarged by being stretched. The image that the user is pinching with both hands can be downsized by being shrunk. The user can remove the image by pinching the image with both hands or putting the hands on both edges of the image and then squeezing the image with both hands. The user can remove the image by pinching the image by its upper side with both hands and then tearing up the image from side to side. The user can remove the image by pinching the image with both hands and then folding the image. The user can pinch the image with one hand and perform a gesture operation (e.g., tapping, swiping, pinching in, or pinching out) on the image with the other hand. As described above, the user can register a specific motion and processing information associated with the motion in the electronic device 100X in advance.

Each of the electronic device 100 and the electronic device 100X is preferably capable of being connected to a network in the display system of one embodiment of the present invention. In that case, the electronic device 100 and the electronic device 100X can be used separately as a communication tool. For example, an image or part of an image displayed on the electronic device 100X worn by a first user can be displayed on the electronic device 100X worn by a second user. Alternatively, an image or part of an image displayed on the electronic device 100X worn by the first user can be displayed on the electronic device 100 held by the second user. With such a display system, the same image data can be shared between a plurality of users, so that communicability can be increased. With the use of the display system of one embodiment of the present invention, a highly convenient display system or a method for operating the display system can be provided.

Note that the processing that can be executed by the electronic device 100 and the electronic device 100X in this embodiment is merely an example, and various types of processing can be executed in accordance with application software incorporated in the electronic device 100 or the electronic device 100X.

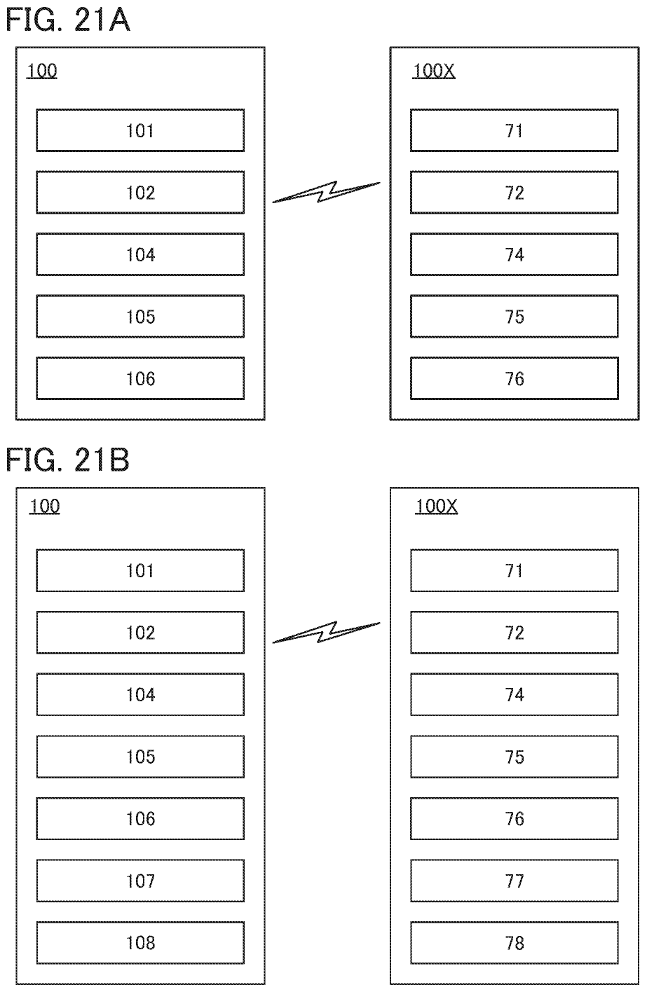

Next, an electronic device and a display system of one embodiment of the present invention will be described with reference to FIG. 20B, FIG. 21A, and FIG. 21B.

FIG. 20B is a diagram illustrating an electronic device and a display system of one embodiment of the present invention. As illustrated in FIG. 20B, the electronic device 100 includes at least the display 102 and the communication portion 106, and the electronic device 100X includes the display 72 and the communication portion 76.

As illustrated in FIG. 21A, the electronic device 100 includes the display 102, the communication portion 106, the semiconductor device 101, the battery 104, and the sensor 105. As illustrated in FIG. 21A, the electronic device 100X includes the display 72, the communication portion 76, the control portion 71, the battery 74, and the sensor 75.

Note that although FIG. 20B and FIG. 21A illustrate a structure in which the electronic device 100 and the electronic device 100X have the same functions, the structure is not limited thereto. For example, as illustrated in FIG. 21B, the electronic device 100 and the electronic device 100X may have different functions.

In FIG. 21B, the electronic device 100 includes a camera portion 107 (also referred to as a sensing portion) and a communication portion 108 in addition to the components illustrated in FIG. 21A. The electronic device 100X includes a camera portion 77 and a headphone portion 78 in addition to the components illustrated in FIG. 21A. The camera portion 77 and the camera portion 107 includes an imaging portion such as an image sensor. Moreover, a plurality of cameras may be provided so as to cover a plurality of fields of view, such as a telescope field of view and a wide field of view. The communication portion 108 can have a communication function different from that of the communication portion 106. For example, the communication portion 106 has a function of performing communication with the communication portion 76, and the communication portion 108 has a function capable of audio call or a communication means capable of electronic payment or the like, utilizing the third-generation mobile communication system (3G), the fourth-generation mobile communication system (4G), the fifth-generation mobile communication system (5G), or the like.

The display 72 illustrated in FIG. 20A, FIG. 20B, FIG. 21A, and FIG. 21B preferably has higher definition than the display 102. The definition of the display 102 can be HD (number of pixels: 1280×720), FHD (number of pixels: 1920×1080), or WQHD (number of pixels: 2560×1440), for example. In addition, the definition of the display 72 is preferably as high as WQXGA (number of pixels: 2560×1600), 4K2K (number of pixels: 3840×2160), or 8K4K (number of pixels: 7680×4320). In particular, definition of 4K2K, 8K4K, or higher is preferable.

The display 72 preferably has a higher pixel density (resolution) than the display 102. For example, the pixel density of the display 102 can be higher than or equal to 100 ppi and lower than 1000 ppi, preferably higher than or equal to 300 ppi and lower than or equal to 800 ppi. The pixel density of the display 72 can be higher than or equal to 1000 ppi and lower than or equal to 10000 ppi, preferably higher than or equal to 2000 ppi and lower than or equal to 6000 ppi, further preferably higher than or equal to 3000 ppi and lower than or equal to 5000 ppi.

Note that there is no particular limitation on the screen ratio (aspect ratio) of the display 102 and the display 72. For example, the display 102 and the display 72 can each be compatible with a variety of screen ratios such as 1:1 (a square), 3:4, 16:9, and 16:10.

Note that the display 102 is preferably formed over a glass substrate, and the display 72 is preferably formed over a silicon substrate. Forming the display 102 over a glass substrate can reduce manufacturing costs. However, in the case where the display 102 is formed over a glass substrate, it is sometimes difficult to increase the pixel density of the display 102 (to typically higher than or equal to 1000 ppi) because of the manufacturing apparatus. Thus, in the electronic device and the display system of one embodiment of the present invention, the pixel density of the display 72 can be increased (to typically higher than or equal to 1000 ppi) by forming the display 72 over a silicon substrate. In other words, an image having a resolution with which the display 102 is incompatible can be displayed on the display 72 complementarily.

The display system of one embodiment of the present invention includes two electronic devices having different definitions or different pixel densities. In order for one of the electronic devices to have image data that can be suitably displayed on the other electronic device, a part or the whole of image data can be compressed or extended.

By increasing the definition or resolution of the display 72, the pixels can be imperceptible (e.g., lines that might be caused between pixels can be invisible) to the user and accordingly the user can reach a higher level of immersion, realistic sensation, and sense of depth.

The electronic device 100 illustrated in FIG. 20A includes a period in which a display does not perform display, and functions as an input/output means (e.g., a controller) of the electronic device 100X in the period. Such a function can extend the usage period of the battery 104 included in the electronic device 100. In other words, the display system of one embodiment of the present invention can achieve power saving. Note that a lithium-ion secondary battery can be used as the battery 104, for example.

Next, the components of the electronic devices and the display system of one embodiment of the present invention illustrated in FIG. 20A, FIG. 20B, FIG. 21A, and FIG. 21B will be described below.

### <Display>

The display 102 and the display 72 each have a function of performing display. For the display 102 and the display 72, one or more selected from a liquid crystal display device, a light-emitting device including organic EL, and a light-emitting device including a light-emitting diode such as a micro LED can be used, for example. In consideration of productivity and emission efficiency, a light-emitting device including organic EL is suitably used for the display 102 and the display 72.

### <Communication Portion>

The communication portion 106 and the communication portion 76 each have a function of wireless or wired communication. The communication portion 106 and the communication portion 76 preferably have a function of wireless communication to reduce the number of components, such as a connection cable.

When having a wireless communication function, the communication portion 106 and the communication portion 76 can communicate through an antenna. As for the communication means (communication method) between the communication portion 106 and the communication portion 76, for example, the communication can be performed in such a manner that each device is connected to a computer network such as the Internet, which is the infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA 2000 (Code Division Multiple Access 2000), or W-CDMA (registered trademark), or a communications standard developed by IEEE such as Wi-Fi (registered trademark), Bluetooth (registered trademark), or ZigBee (registered trademark).

### <Semiconductor Device and Control Portion>

The semiconductor device 101 and the control portion 71 each have a function of controlling a display. The semiconductor device 101 and the control portion 71 each include a CPU, a GPU, a memory, and the like. Note that an arithmetic circuit such as a CPU or a GPU can perform image processing, for example, up-conversion processing or down-conversion processing of image data. Thus, image data with low definition can be up-converted or image data with high definition can be down-converted in accordance with the definition of the display, which enables display of a high-quality image on the display.

### <Battery>

The battery 104 and the battery 74 each have a function of supplying power to a display. As the battery 104 and the battery 74, a primary battery or a secondary battery can be used, for example. As the secondary battery, a lithium-ion secondary battery can be preferably used, for example.

### <Sensor Portion>

The sensor 105 and the sensor 75 each have a function of obtaining information on one or more of the senses of sight, hearing, touch, taste, smell, and the like of the user. Specifically, the sensor 105 has a function of measuring at least one of force, displacement, position, speed, acceleration, angular velocity, rotational frequency, distance, light, magnetism, temperature, sound, time, electric field, current, voltage, electric power, radiation, humidity, gradient, oscillation, a smell, and infrared rays.

The sensor 75 preferably has a function of measuring brain waves in addition to the above function of the sensor 105. For example, the sensor 75, which has a plurality of electrodes in contact with the user's head, can have a mechanism of measuring brain waves from a weak current flowing through the electrodes. When the sensor 75 has a function of measuring brain waves, an image on the display 102 or an image on part of the display 102 can be displayed on the user's intended area of the display 72. In this case, the user does not need to use both hands to operate the electronic device and can perform an input operation or the like with nothing in the hands (with both hands being free).

### [Example 1 of Image]

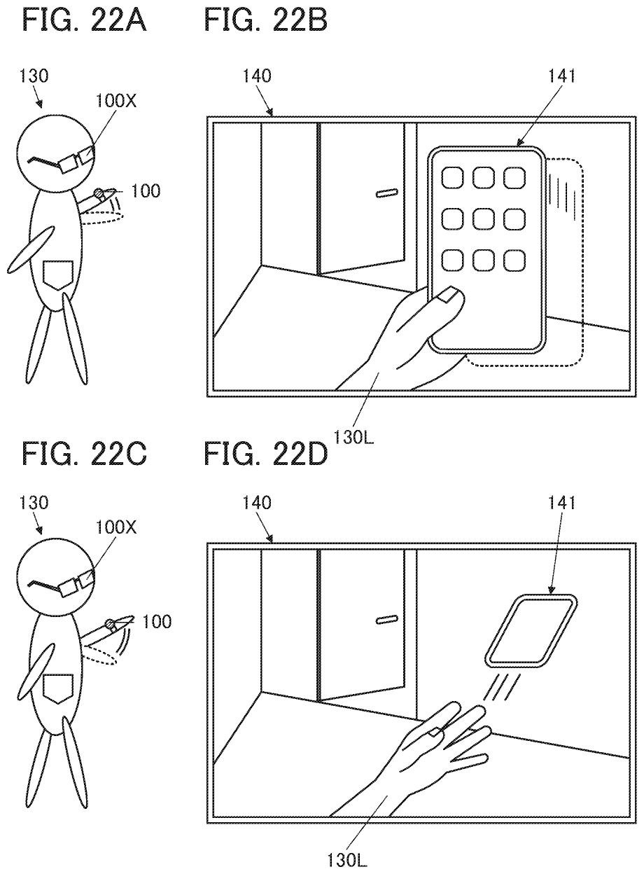

Next, examples of the electronic devices and an image of the display system of one embodiment of the present invention will be described with reference to FIG. 22A, FIG. 22B, FIG. 22C, and FIG. 22D.

Hereinafter, examples of a manipulation method that a user can experience with the display system of one embodiment of the present invention and examples of an image that can be presented to the user will be described.

FIG. 22A illustrates a state where a user 130 wearing the glasses-type electronic device 100X performs a gesture operation. At this time, since the display of the electronic device 100 is turned off, the power consumption of the electronic device 100 can be reduced. Since the electronic device 100 is worn on an arm of the user 130, the user 130 can operate a display system with both hands being free. At this time, for the operation of the display system, it is possible to use information obtained with the sensor 75A on the electronic device 100X side and information based on a movement path of an arm that is obtained with an acceleration sensor used as the sensor 105 provided in the electronic device 100.

FIG. 22B illustrates an example of an image 140 in the field of view of the user 130 who is in a room as illustrated in FIG. 22A. In the image 140 illustrated in FIG. 22B, image information 141 is superimposed on a captured image of a real-world indoor scenery including a floor, a wall, a door, and the like. Here, the image information 141 is part of an image displayed on the display of the electronic device 100. The user 130 can operate the electronic device 100 that is paired with the electronic device 100X while wearing the electronic device 100X.

When the user 130 makes a motion holding a space where the image information 141 is shown with a left hand 130L, the electronic device 100X recognizes this motion as a gesture operation and makes the position of the image information 141 changeable. The movement of the left hand 130L of the user 130 in this state can change the position of the image information 141 in accordance with the movement of the left hand 130L, as illustrated in FIG. 22B. At this time, the image information 141 can be not only moved left and right, up and down, and back and forth but also rotated in accordance with the movement of the left hand 130L.

FIG. 22C illustrates a state where the user 130 performs a gesture operation with a motion different from that in FIG. 22A. The electronic device 100 whose display is turned off as in the above example is in a pocket of the user 130.

FIG. 22D illustrates the image 140 in the field of view of the user 130 who is in a room as illustrated in FIG. 22C. The user 130 makes a motion holding the space where the image information 141 is shown and then makes a motion throwing an object like a Frisbee, whereby the image information 141 can be abandoned. At this time, the image information 141 moves in the direction apart from the user 130, and is displayed to disappear at a certain point or ejected to the outside of the field of view. In this manner, a content image displayed in the field of view can be abandoned (closed) with a gesture operation of the user 130.

As described above, the electronic devices and the display system of one embodiment of the present invention can be operated by a new manipulation method or operation method.

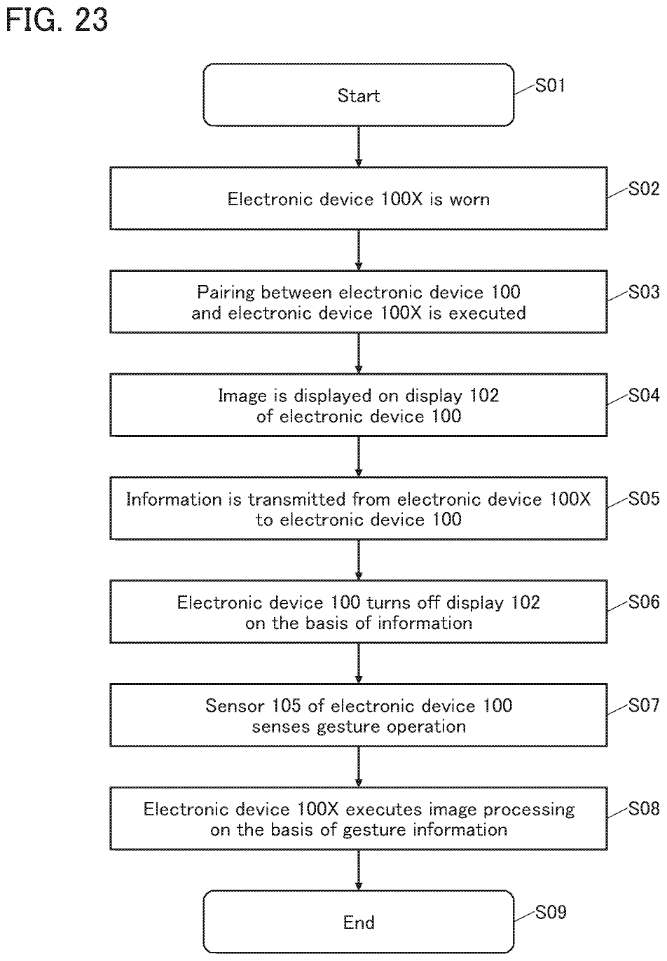

Next, an example of an operation method of the display system of one embodiment of the present invention will be described with reference to FIG. 23.

### [Operation Method Example 1 of Display System]

An example of an operation method of the display system will be described below. FIG. 23 is a flowchart for the operation method of the display system.

In Step S01, the operation starts. At this time, the electronic device 100 is in a start-up state (a state where a manipulation is possible), and the electronic device 100X is in a power-on state.

In Step S02, the electronic device 100X is worn. The electronic device 100X recognizes being worn, and the system starts. In Step S02, for example, when the electronic device 100X has a goggle-type shape, an image of the front view of a camera may be presented to the user or an image of other contents may be displayed.

In Step S03, pairing between the electronic device 100 and the electronic device 100X is executed. When the pairing is completed, the electronic device 100 and the electronic device 100X are in a state where two-way data communication is possible.

In Step S04, a first image displayed on the display 102 of the electronic device 100 is displayed on the display of the electronic device 100X. Thus, the user can see information displayed on the electronic device 100X without looking at the screen of the electronic device 100.

At this time, since the pixel density of the display differs between the electronic device 100 and the electronic device 100X, instead of displaying the first image as it is, a second image, which is obtained by performing image processing such as up-conversion or down-conversion on the first image so that the image can have an optimal size when displayed on the display of the electronic device 100X, is preferably displayed on the electronic device 100X.

In Step S05, information is transmitted from the electronic device 100X to the electronic device 100. The information includes, for example, a code that means the completion of display of the first image.

In Step S06, the display 102 of the electronic device 100 is turned off on the basis of the received information. At this time, the electronic device 100 maintains the touch sensor of the display 102 in an active state. Accordingly, the display 102 of the electronic device 100 functions as an input means (a touch pad) or the like.

In Step S07, the electronic device 100X senses a gesture operation of the user with the sensing portion included in the electronic device 100X and obtains gesture information corresponding to the gesture operation.

In Step S08, the electronic device 100X executes various types of processing on the basis of the gesture information. For example, image processing can be performed on image information displayed on the display of the electronic device 100X, and the image information after image processing can be displayed on the display.

In Step S09, the processing ends. Step S10 corresponds to detaching the electronic device 100X, turning off the power of the electronic device 100 or the electronic device 100X, or canceling the pairing between the electronic device 100 and the electronic device 100X, for example.

The above is the description of the operation method example of the display system of one embodiment of the present invention.

### [Example 2 of Image]

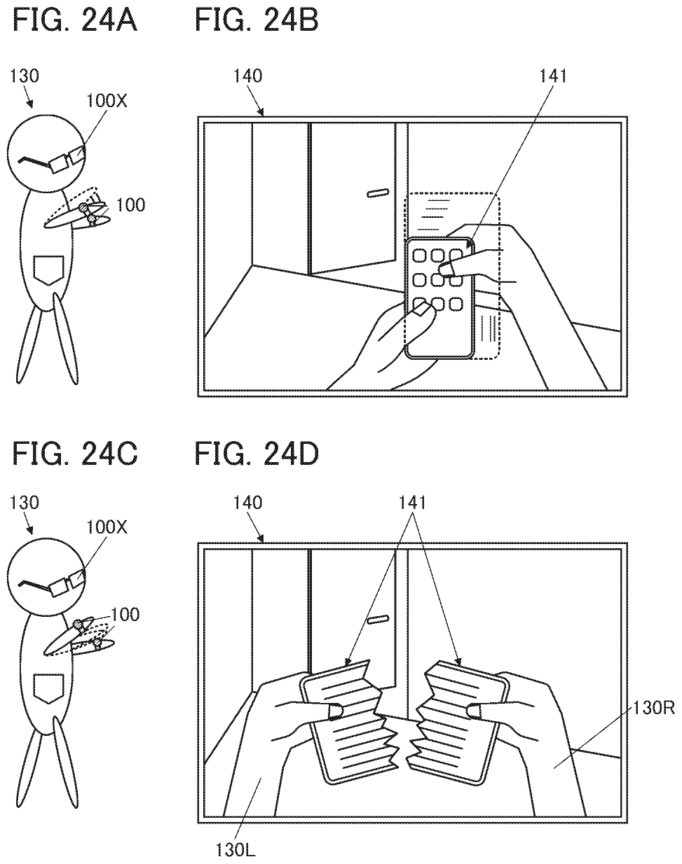

Next, examples of a manipulation method that a user can experience with the display system of one embodiment of the present invention and examples of an image that can be presented to the user, which are different from those described above, will be described with reference to FIG. 24A, FIG. 24B, FIG. 24C, and FIG. 24D.

FIG. 24A illustrates a state where the user 130 wearing the glasses-type electronic device 100X performs a gesture operation. At this time, since the display of the electronic device 100 is turned off, the power consumption of the electronic device 100 can be reduced. Since the electronic device 100 is worn on an arm of the user 130, the user 130 can operate a display system with both hands being free.

FIG. 24B illustrates an example of the image 140 in the field of view of the user 130 who is in a room as illustrated in FIG. 24A. In the image 140 illustrated in FIG. 24B, the image information 141 is superimposed on a captured image of a real-world indoor scenery including a floor, a wall, a door, and the like. Here, the image information 141 is part of an image displayed on the display of the electronic device 100. The user 130 can operate the electronic device 100 that is paired with the electronic device 100X while wearing the electronic device 100X.

When the user 130 makes a motion holding the space where the image information 141 is shown with the left hand 130L and the right hand 130R as illustrated in FIG. 24B, the electronic device 100X recognizes this motion as a gesture operation and makes the shape of the image information 141 changeable. When the left hand 130L and the right hand 130R become close to each other in this state, the shape of the image information 141 is changed such that the image information 141 is downsized as illustrated in FIG. 24B. By contrast, when the left hand 130L and the right hand 130R become apart from each other, the image information 141 can be enlarged. At this time, the image information 141 can be moved or rotated in accordance with the movements of the left hand 130L and the right hand 130R. At this time, information based on the movement paths of the left and the right arms wearing the electronic devices 100 can be used for the movements of the left hand 130L and the right hand 130R.

FIG. 24C illustrates a state where the user 130 performs a gesture operation with a motion different from that in FIG. 24A. The electronic device 100 whose display is turned off as in the above example is worn on an arm of the user 130.

FIG. 24D illustrates the image 140 in the field of view of the user 130 in a room as illustrated in FIG. 24C. The user 130 makes a motion holding the space where the image information 141 is shown with the left hand 130L and the right hand 130R and then makes a motion spreading the hands to left and right, whereby the image information 141 can be abandoned. At this time, the image information 141 is displayed to be teared up from side to side as illustrated in FIG. 24D. In this manner, a content image displayed in the field of view can be abandoned (closed) with a gesture operation of the user 130.

As described above, the electronic devices and the display system of one embodiment of the present invention can be operated by a new manipulation method.

### [Operation Method Example 2 of Display System]

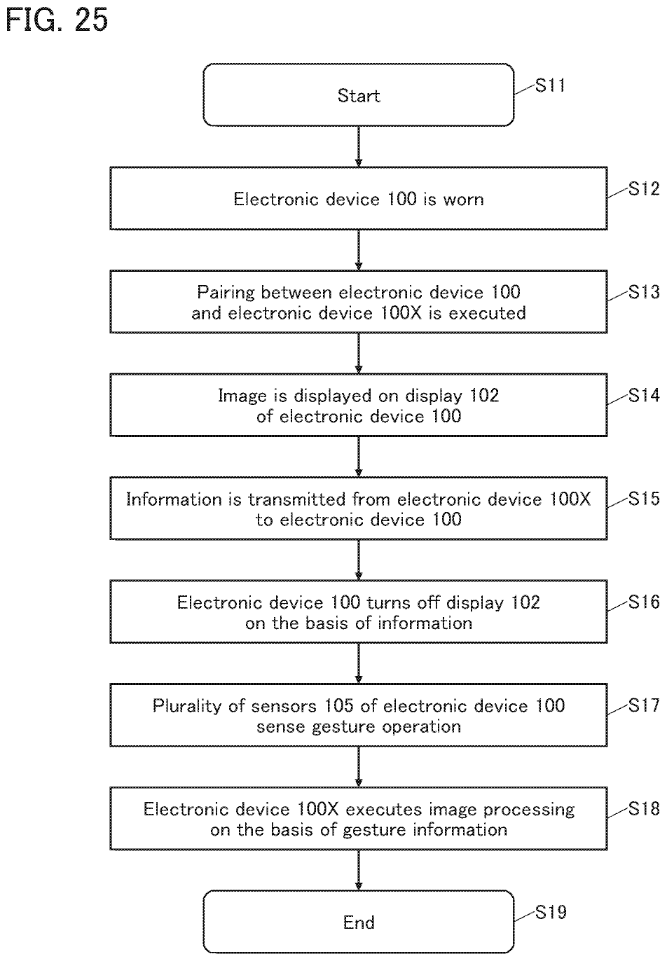

An example of an operation method of the display system will be described below. FIG. 25 is a flowchart for the operation method of the display system.

In Step S11, the operation starts. At this time, the electronic device 100 is in a start-up state (a state where a manipulation is possible), and the electronic device 100X is in a power-on state.

In Step S12, the electronic device 100X is worn. The electronic device 100X recognizes being worn, and the system starts. In Step S12, for example, when the electronic device 100X has a goggle-type shape, an image of the front view of a camera may be presented to the user or an image of other contents may be displayed.

In Step S13, pairing between the electronic device 100 and the electronic device 100X is executed. When the pairing is completed, the electronic device 100 and the electronic device 100X are in a state where two-way data communication is possible.

In Step S14, the first image displayed on the display 102 of the electronic device 100 is displayed on the display of the electronic device 100X. Thus, the user can see information displayed on the electronic device 100X without looking at the screen of the electronic device 100.

At this time, since the pixel density of the display differs between the electronic device 100 and the electronic device 100X, instead of displaying the first image as it is, a second image, which is obtained by performing image processing such as up-conversion or down-conversion on the first image so that the image can have an optimal size when displayed on the display of the electronic device 100X, is preferably displayed on the electronic device 100X.

In Step S15, information is transmitted from the electronic device 100X to the electronic device 100. The information includes, for example, a code that means the completion of display of the first image.

In Step S16, the display 102 of the electronic device 100 is turned off on the basis of the received information. At this time, the electronic device 100 maintains the touch sensor of the display 102 in an active state. Accordingly, the display 102 of the electronic device 100 functions as an input means (a touch pad) or the like.

In Step S17, the electronic device 100X senses a gesture operation of the user with a plurality of sensing portions included in the electronic device 100X. The electronic device 100X obtains gesture information corresponding to the gesture operation on the basis of information output from the plurality of sensing portions (such information is also referred to as input data).

In Step S18, the electronic device 100X executes various types of processing on the basis of the gesture information. For example, image processing can be performed on image information displayed on the display of the electronic device 100X, and the image information after image processing can be displayed on the display.

In Step S19, the processing ends. Step S19 corresponds to detaching the electronic device 100X, turning off the power of the electronic device 100 or the electronic device 100X, or canceling the pairing between the electronic device 100 and the electronic device 100X, for example.

The above is the description of the operation method example of the display system of one embodiment of the present invention.

As described above, with the use of the electronic devices and the display system of one embodiment of the present invention, an electronic device with a novel structure or a display system with a novel structure can be provided. With the use of the electronic devices and the display system of one embodiment of the present invention, a manipulation method for an electronic device with a novel structure or a manipulation method for a display system with a novel structure can be provided.

### <Structure Example of Display>

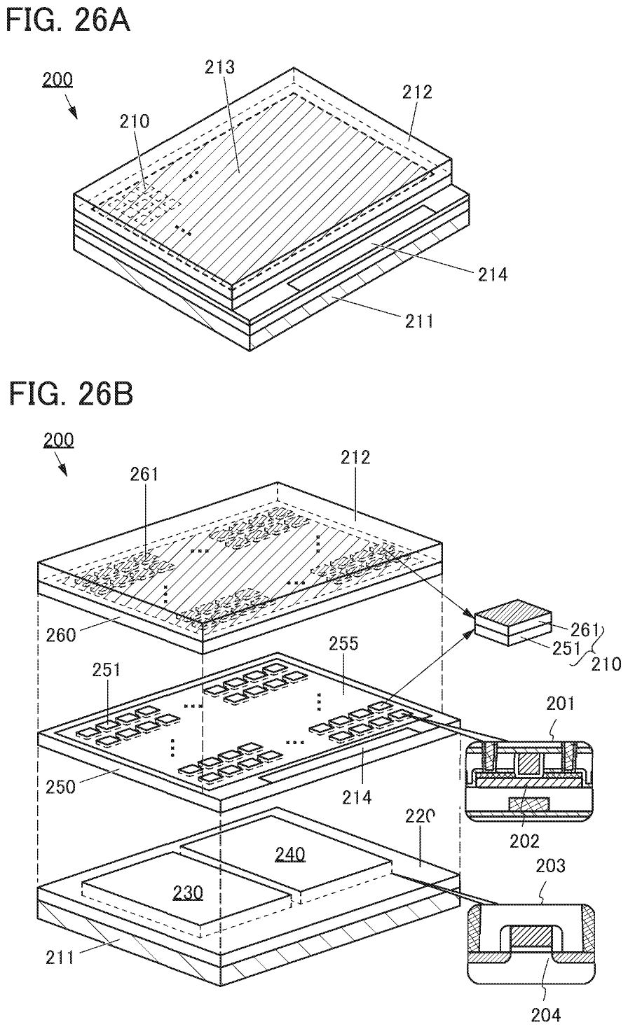

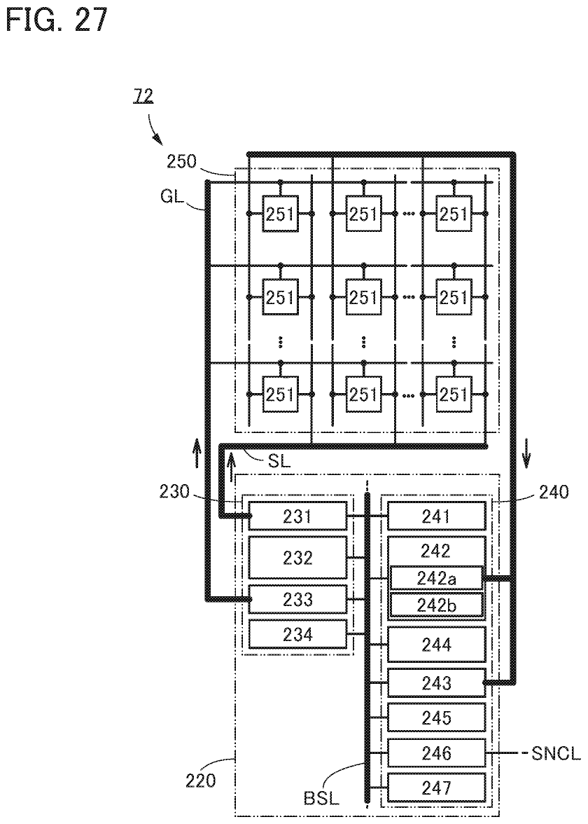

The structure of the display 72 illustrated in FIG. 20A is described with reference to FIG. 26A, FIG. 26B, and FIG. 27. Note that the structure example of the display described below can be employed for not only the display 72 but also the display 102.

FIG. 26A and FIG. 26B are perspective views of a display (a display apparatus 200) that can be used in the display 72 illustrated in FIG. 20A.

The display apparatus 200 includes a substrate 211 and a substrate 212. The display apparatus 200 includes a display portion composed of elements provided between the substrate 211 and the substrate 212. The display portion is a region where an image is displayed in the display apparatus 200. The display portion is a region where a plurality of pixels 210 each of which is composed of a pixel circuit 251 and a light-emitting device 261 connected to the pixel circuit 251 are provided.

Using the pixels 210 arranged in a matrix of 1920×1080, a display with a definition what is called a full high definition (also referred to as “2K definition”, “2K1K”, “2K”, or the like) can be achieved. For example, using the pixels 210 arranged in a matrix of 3840×2160, a display with a definition what is called an ultra-high definition (also referred to as “4K definition”, “4K2K”, “4K”, or the like) can be achieved. For example, using the pixels 210 arranged in a matrix of 7680×4320, a display with a definition what is called a super high definition (also referred to as “8K definition”, “8K4K”, “8K”, or the like) can be achieved. By increasing the number of pixels 210, a display that can perform full-color display with 16K or 32K definition can also be obtained.

In addition, the pixel density (definition) of the display apparatus 200 is preferably higher than or equal to 1000 ppi and lower than or equal to 10000 ppi. For example, the resolution may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display apparatus 200. For example, the display apparatus 200 is compatible with a variety of screen ratios such as 1:1 (a square), 4:3, 16:9, and 16:10.

In this specification and the like, the term “element” can be replaced with the term “device” in some cases. For example, a display element, a light-emitting element, and a liquid crystal element can be rephrased as a display device, a light-emitting device, and a liquid crystal device, respectively.

In the display apparatus 200, a variety of signals and power supply potentials are input from the outside via a terminal portion 214, so that display can be performed. A plurality of layers are provided between the substrate 211 and the substrate 212, and each of the layers is provided with a transistor for a circuit operation, or a display element that emits light. A pixel circuit having a function of controlling light emission of the display element, a driver circuit having a function of controlling the pixel circuit, a functional circuit having a function of controlling the driver circuit, and the like are provided in the plurality of layers.

FIG. 26B is a perspective view schematically illustrating the structures of the layers provided between the substrate 211 and the substrate 212.

A layer 220 is provided over the substrate 211. The layer 220 includes a driver circuit 230 and a functional circuit 240. The layer 220 includes the transistor 203 containing silicon in the semiconductor layer 204 including a channel formation region. The substrate 211 is a silicon substrate, for example. A silicon substrate is preferable because of having higher thermal conductivity than a glass substrate. When the driver circuit 230 and the functional circuit 240 are provided in the same layer, a wiring electrically connecting the driver circuit 230 and the functional circuit 240 can be shortened. As a result, charge and discharge time of a control signal used when the functional circuit 240 controls the driver circuit 230 becomes short, leading to a reduction in power consumption.

The transistor 201 can be, for example, a transistor containing single crystal silicon in its channel formation region (also referred to as a “c-Si transistor”). In particular, the use of a transistor containing single crystal silicon in a channel formation region as the transistor provided in the layer 220 can increase the on-state current of the transistor. This is preferable because circuits included in the layer 220 can be driven at high speed. The Si transistor can be formed by microfabrication to have a channel length of 3 nm to 10 nm, for example; thus, a CPU, an accelerator such as a GPU, an application processor, or the like can be integral with the display portion in the display apparatus 200.

As the transistor provided in the layer 220, a transistor containing polycrystalline silicon in its channel formation region (also referred to as a “Poly-Si transistor)) may be used. As polycrystalline silicon, low-temperature polysilicon (LTPS) may be used. Note that a transistor containing LTPS in its channel formation region is also referred to as an “LTPS transistor”.

The driver circuit 230 includes a gate driver circuit, a source driver circuit, or the like, for example. In addition, an arithmetic circuit, a memory circuit, a power supply circuit, and the like may be included. Since the gate driver circuit, the source driver circuit, and other circuits can be placed to be overlapped with the display portion, the width of a non-display region (also referred to as a bezel) provided along the outer periphery of the display portion of the display apparatus 200 can be extremely narrowed compared with the case where these circuits and the display portion are arranged side by side, so that the display apparatus 200 can be downsized.

The functional circuit 240 has a function of an application processor for controlling the circuits in the display apparatus 200 and generating signals used for controlling the circuits, for example. In addition, the functional circuit 240 may include a CPU and a circuit for correcting image data, such as an accelerator (e.g., a GPU). Furthermore, the functional circuit 240 may include an LVDS (Low Voltage Differential Signaling) circuit, an MIPI (Mobile Industry Processor Interface) circuit, and/or a D/A (Digital to Analog) converter circuit, or the like having a function of an interface for receiving image data or the like from the outside of the display apparatus 200. Moreover, the functional circuit 240 may include a circuit for compressing and decompressing image data and/or a power supply circuit, for example. In other words, the functional circuit 240 can partly function as the control portion 71.

A layer 250 is provided over the layer 220. The layer 250 includes a pixel circuit group 255 including a plurality of pixel circuits 251. The layer 250 includes the transistor 201 containing a metal oxide (also referred to as an oxide semiconductor) in the semiconductor layer 202 including a channel formation region. Note that the layer 250 can be stacked over the layer 220.

A Si transistor may be provided in the layer 250. For example, the pixel circuits 251 may each include a transistor containing single crystal silicon or polycrystalline silicon in its channel formation region. LTPS may be used as the polycrystalline silicon. The layer 250 can be formed over another substrate and bonded to the layer 220, for example.

In addition, the pixel circuit 251 may include a plurality of kinds of transistors formed using different semiconductor materials, for example. In the case where the pixel circuit 251 includes a plurality of kinds of transistors formed using different semiconductor materials, the transistors may be provided in different layers for each kind of transistor. For example, in the case where the pixel circuit 251 include a Si transistor and an OS transistor, a layer including the Si transistor and a layer including the OS transistor may be provided to overlap with each other. Providing the transistors to overlap with each other reduces the area occupied by the pixel circuits 251. Thus, the resolution of the display apparatus 200 can be improved. Note that a structure in which an LTPS transistor and an OS transistor are used in combination is referred to as LTPO in some cases.

An OS transistor has characteristics of an extremely low off-state current. Thus, it is particularly preferable to use the OS transistor as a transistor provided in a pixel circuit because analog data written to the pixel circuit can be retained for a long time.

A layer 260 is provided over the layer 250. Over the layer 260, the substrate 212 is provided. The substrate 212 is preferably a substrate having a light-transmitting property or a layer formed with a material having a light-transmitting property. The layer 260 includes a plurality of light-emitting devices 261. The layer 260 can be stacked over the layer 250. As the light-emitting device 261, an organic electroluminescent element (also referred to as an organic EL element) or the like can be used, for example. Note that the light-emitting device 261 is not limited thereto; an inorganic EL element formed with an inorganic material may be used, for example. Note that an “organic EL element” and an “inorganic EL element” are collectively referred to as an “EL element” in some cases. The light-emitting device 261 may contain an inorganic compound such as quantum dots. For example, when used for the light-emitting layer, the quantum dots can function as a light-emitting material.

As shown in FIG. 26B, the display apparatus 200 of one embodiment of the present invention can have a structure in which the light-emitting device 261, the pixel circuits 251, the driver circuit 230, and the functional circuit 240 are stacked; thus, the aperture ratio (effective display area ratio) of the pixels can be extremely high. For example, the pixel aperture ratio can be greater than or equal to 40% and less than 100%, preferably greater than or equal to 50% and less than or equal to 95%, further preferably greater than or equal to 60% and less than or equal to 95%. Furthermore, the pixel circuit 251 can be arranged extremely densely, and thus the resolution of the pixels can be extremely high. For example, the pixels can be arranged in the display portion of the display apparatus 200 (a region where the pixel circuits 251 and the light-emitting device 261 are stacked) with a definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

The display apparatus 200 has an extremely high resolution and thus can be suitably used for a device for VR such as a head-mounted display or a glasses-type device for AR. For example, even in the case of a structure in which the display portion of the display apparatus 200 is seen through an optical member such as a lens, pixels of the extremely-high-resolution display portion included in the display apparatus 200 are not seen when the display portion is enlarged by the lens, so that display providing a high sense of immersion can be performed.

Note that in the case where the display apparatus 200 is used as a wearable display apparatus for VR or AR, the display portion can have a screen diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion may have a screen diagonal size of 1.5 inches or around 1.5 inches. When the display portion has a screen diagonal size less than or equal to 2.0 inches, preferably, approximately 1.5 inches, the number of times of light exposure treatment using a light exposure apparatus (typified by a scanner apparatus) can be one; thus, the productivity of a manufacturing process can be improved.

The display apparatus 200 of one embodiment of the present invention can be used for an electronic device other than a wearable electronic device. In that case, the display portion can have a screen diagonal size greater than 2.0 inches. The structure of transistors used in the pixel circuit 251 may be selected as appropriate depending on the diagonal size of the display portion. In the case where single crystal Si transistors are used in the pixel circuit 251, for example, the diagonal size of the display portion is preferably greater than or equal to 0.1 inches and less than or equal to 3 inches. In the case where LTPS transistors are used in the pixel circuit 251, the diagonal size of the display portion is preferably greater than or equal to 0.1 inches and less than or equal to 30 inches, further preferably greater than or equal to 1 inch and less than or equal to 30 inches. In the case where LTPO (a structure in which an LTPS transistor and an OS transistor are combined) is employed in the pixel circuit 251, the diagonal size of the display portion is preferably greater than or equal to 0.1 inches and less than or equal to 50 inches, further preferably greater than or equal to 1 inch and less than or equal to 50 inches. In the case where OS transistors are used in the pixel circuit 251, the diagonal size of the display portion is preferably greater than or equal to 0.1 inches and less than or equal to 200 inches, further preferably greater than or equal to 50 inches and less than or equal to 100 inches.

With single crystal Si transistors, a size increase is extremely difficult because of the size of a single crystal Si substrate. Furthermore, since a laser crystallization apparatus is used in the manufacturing process, LTPS transistors are unlikely to respond to a size increase (typically to a screen diagonal greater than 30 inches). By contrast, since the manufacturing process does not necessarily require a laser crystallization apparatus or the like or can be performed at a relatively low process temperature (typically, lower than or equal to 450° C.), OS transistors can be used for a display panel with a relatively large area (typically, a screen diagonal greater than or equal to 50 inches and less than or equal to 100 inches). In addition, LTPO is applicable to a display panel with a size midway between the case of using LTPS transistors and the case of using OS transistors (typically, a diagonal size greater than or equal to 1 inch and less than or equal to 50 inches).

A specific configuration example of the driver circuit 230 and the functional circuit 240 will be described with reference to FIG. 27. The block diagram of the display apparatus 200 in FIG. 27 shows a plurality of wirings connecting the pixel circuits 251, the driver circuit 230, and the functional circuit 240, a bus wiring in the display apparatus 200, and the like.

In the display apparatus 200 shown in FIG. 27, the plurality of pixel circuits 251 are arranged in a matrix in the layer 250.

Furthermore, the driver circuit 230 and the functional circuit 240 are provided in the layer 220 in the display apparatus 200 shown in FIG. 27. The driver circuit 230 includes, for example, a source driver circuit 231, a digital-to-analog converter circuit 232, a gate driver circuit 233, and a level shifter 234. The functional circuit 240 includes, for example, a memory device 241, a GPU (AI accelerator) 242, an EL correction circuit 243, a timing controller 244, a CPU 245, a sensor controller 246, and a power supply circuit 247. The functional circuit 240 has a function of an application processor.

In addition, the display apparatus 200 in FIG. 27 has a structure in which, for example, a bus wiring BSL is electrically connected to each of the circuits included in the driver circuit 230 and each of the circuits included in the functional circuit 240.

The source driver circuit 231 has a function of transmitting image data to the pixel circuit 251 included in the pixel 210, for example. Thus, the source driver circuit 231 is electrically connected to the pixel circuit 251 through a wiring SL. Note that a plurality of source driver circuits 231 are preferably provided. When the plurality of source driver circuits 231 are arranged for the respective sections of the display portion where the pixel circuits 251 are provided, driving such that the driving frequency differs between the sections of the display portion can be performed.

The digital-to-analog converter circuit 232 has a function of, for example, converting image data that has been digitally processed by a GPU, a correction circuit, or the like into analog data. The image data converted into analog data is amplified by an amplifier circuit such as an operational amplifier and is transmitted to the pixel circuits 251 via the source driver circuit 231. Note that the digital-to-analog converter circuit 232 may be included in the source driver circuit 231, or the image data may be transmitted to the source driver circuit 231, the digital-to-analog converter circuit 232, and the pixel circuits 251 in this order.

The gate driver circuit 233 has a function of selecting a pixel circuit to which image data is to be transmitted in the pixel circuit 251, for example. Thus, the gate driver circuit 233 is electrically connected to the pixel circuit 251 through a wiring GL. Note that a plurality of gate driver circuits 233 are preferably provided such that the number of the gate driver circuits 233 corresponds to the number of the source driver circuits 231. When the plurality of gate driver circuits 233 are arranged for the respective sections of the display portion where the pixel circuits 251 are provided, driving such that the driving frequency differs between the sections of the display portion can be performed.

The level shifter 234 has a function of converting signals to be input to the source driver circuit 231, the digital-to-analog converter circuit 232, the gate driver circuit 233, and the like into signals having appropriate levels, for example.

The memory device 241 has a function of storing image data to be displayed by the pixel circuit 251, for example. Note that the memory device 241 can be configured to store the image data as digital data or analog data.

In the case where the memory device 241 stores image data, the memory device 241 is preferably a nonvolatile memory. In that case, a NAND memory or the like can be used as the memory device 241, for example.

In the case where the memory device 241 stores temporary data generated in the GPU 242, the EL correction circuit 243, the CPU 245, or the like, the memory device 241 is preferably a volatile memory. In that case, an SRAM (Static Random Access Memory), a DRAM (Dynamic Random Access Memory), or the like can be used as the memory device 241, for example.

The GPU 242 has a function of performing processing for outputting image data read from the memory device 241 to the pixel circuit 251, for example. In particular, the GPU 242 is configured to perform pipeline processing in parallel and thus can perform high-speed processing of image data to be output to the pixel circuit 251. The GPU 242 can also function as a decoder for restoring an encoded image.

In addition, the functional circuit 240 may include a plurality of circuits that can improve the display quality of the display apparatus 200. As such circuits, for example, correction circuits (dimming and toning) that detect color irregularity of a displayed image and correct the color irregularity to obtain an optimal image may be provided. Furthermore, in the case where a light-emitting device using an organic EL material is employed for the display element, the functional circuit 240 may be provided with an EL correction circuit. The functional circuit 240 includes, for example, the EL correction circuit 243.

The above-described image correction may be performed using artificial intelligence. For example, current flowing through a pixel circuit (or voltage applied to the pixel circuit) may be monitored and acquired, a displayed image may be acquired with an image sensor or the like, the current (or voltage) and the image may be treated as input data in an arithmetic operation of artificial intelligence (e.g., an artificial neural network or the like), and whether to correct the image or not may be judged based on the output result.

Such an arithmetic operation of artificial intelligence can be applied to not only image correction but also up-conversion processing for increasing the definition of image data. As an example, FIG. 27 illustrates the GPU 242 that includes blocks for performing arithmetic operations for various kinds of correction (e.g., color irregularity correction 242a and up-conversion 242b).

The up-conversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+ method, a SRCNN (Super-Resolution Convolutional Neural Network) method, and the like.

The algorithm used for the up-conversion processing may be different for each region determined in accordance with a gaze point. For example, up-conversion processing for a region including a gaze point and the vicinity of the gaze point is performed using an algorithm with a low processing speed but high accuracy, and up-conversion processing for a region other than the above region is performed using an algorithm with low accuracy but a high processing speed. With such a structure, the processing time required for the up-conversion processing can be shortened. In addition, power consumed by up-conversion processing can be reduced.

Without limitation to up-conversion processing, down-conversion processing for decreasing the definition of image data may be performed. In the case where the definition of image data is higher than the definition of the display apparatus 200, part of the image data is not displayed on the display portion, in some cases. In that case, down-conversion processing enables the entire image data to be displayed on the display portion.

The timing controller 244 has a function of controlling the driving frequency at which an image is displayed, for example. In the case where a still image is displayed on the display apparatus 200, for example, the timing controller 244 can lower the driving frequency to reduce power consumption of the display apparatus 200.

The CPU 245 has a function of performing general-purpose processing such as execution of an operating system, data control, and execution of a variety of arithmetic operations and programs, for example. The CPU 245 has a function of, for example, giving an instruction for a writing operation or a reading operation of image data in the memory device 241, an operation for correcting image data, an operation for a later-described sensor, or the like. Furthermore, the CPU 245 may have a function of transmitting a control signal to at least one of the circuits included in the functional circuit 240, for example.

The sensor controller 246 has a function of controlling a sensor, for example. FIG. 27 illustrates a wiring SNCL as a wiring electrically connected to the sensor.

The sensor can be, for example, a touch sensor that can be provided in the display portion of the display apparatus 200. Alternatively, the sensor can be an illuminance sensor, for example.

The power supply circuit 247 has a function of generating voltage to be supplied to the pixel circuits 251, the circuits included in the driver circuit 230 and the functional circuit 240, and the like. Note that the power supply circuit 247 may have a function of selecting a circuit to which voltage is to be supplied. The power supply circuit 247 stops supply of voltage to the CPU 245, the GPU 242, and the like during a period in which a still image is displayed, so that the power consumption of the whole the display apparatus 200 can be reduced, for example.

As described above, the display apparatus of one embodiment of the present invention can have a structure in which display elements, pixel circuits, a driver circuit, and a functional circuit are stacked. The driver circuit and the functional circuit that are peripheral circuits can be provided to be overlapped with the pixel circuits and thus the bezel width can be made extremely narrow, so that a display apparatus with reduced size can be achieved. Alternatively, when the display apparatus according to one embodiment of the present invention has a structure where circuits are stacked, wirings for connecting the circuits can be shortened, which results in a display apparatus with reduced weight. Alternatively, the display apparatus of one embodiment of the present invention can have a high pixel resolution, and thus can be a display apparatus with high display quality.

### <Operation Example of Electronic Device>

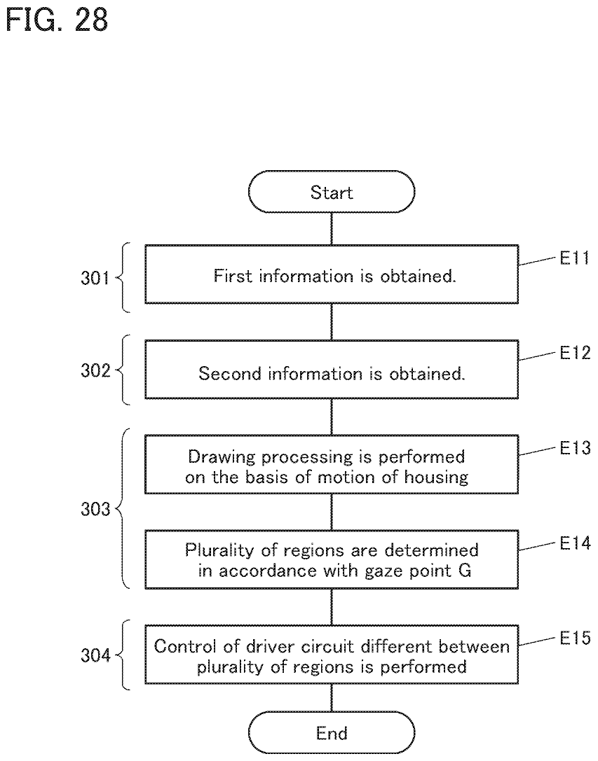

An operation example of the display apparatus 200 will be described with reference to drawings. FIG. 28 is a flow chart for describing an operation example of the electronic device 100X including the display 72 to which the display apparatus 200 can be used.

The movement of the electronic device 100X is detected by the sensor 75A, an acceleration sensor, or the like, whereby first information (information on the motion of the housing 81) is obtained (Step E11).

An image of the user's eye is captured using the sensor 75A or the like, whereby second information (information on the user's sight line) is obtained (Step E12).

Next, the electronic device 100X performs drawing processing of 360-degree omnidirectional image data on the basis of the first information (Step E13).

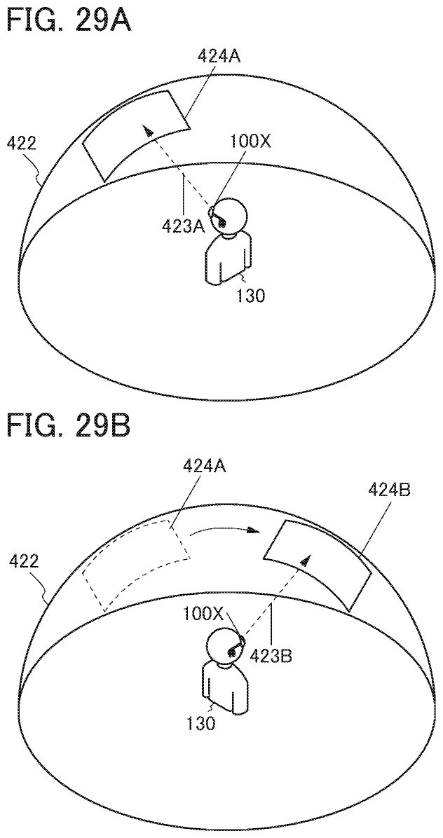

Step E13 is described by giving a specific example. The schematic view in FIG. 29A illustrates the user 130 positioned at the center of a 360-degree omnidirectional image data 422. The user can see an image 424A in a direction 423A displayed on the display apparatus 200 of the electronic device 100X.

The schematic view in FIG. 29B shows the state where the user 130 that has been in the state of the schematic view in FIG. 29A moves his/her head to see an image 424B that is in a direction 423B. The image 424A changes into the image 424B in accordance with the motion of the housing of the electronic device 100X, so that the user 130 can perceive the space expressed by the 360-degree omnidirectional image data 422.

As illustrated in FIG. 29A and FIG. 29B, the user 130 moves the housing of the electronic device 100X in accordance with the movement of the head. When an image obtained from the 360-degree omnidirectional image data 422 in accordance with the motion of the electronic device 100X is processed with higher drawing processing capacity, the user 130 can perceive a virtual space closer to the real world.

Next, the electronic device 100X determines a plurality of regions of the display portion in the display apparatus in accordance with a gaze point G based on the second information (Step E14). For example, a first region S1 including the gaze point G is determined and a second region S2 adjacent to the first region S1 is determined. An outer region of the second region is referred to as a third region S3.

Step E14 is described by giving a specific example.

In general, the human visual field is roughly classified into the following five fields, although varying between individuals. The discrimination visual field refers to a region within approximately 5° from the center of vision including the gaze point, where visual performance such as eyesight and color identification is the most excellent. The effective visual field refers to a region that is horizontally within approximately 30° and vertically within approximately 20° from the center of vision (gaze point) and adjacent to the outside of the discrimination visual field, where instant identification of particular information is possible only with an eye movement. The stable visual field refers to the region that is horizontally within approximately 90° and vertically within approximately 70° from the center of vision and adjacent to the outside of the effective visual field, where identification of particular information is possible without any difficulty with a head movement. The inducting visual field refers to the region that is horizontally within approximately 100° and vertically within approximately 85° from the center of vision and adjacent to the outside of the stable visual field, where the existence of a particular target can be sensed but the identification ability is low. The supplementary visual field refers to the region that is horizontally within approximately 100° to 200° and vertically within approximately 85° to 130° from the center of vision and adjacent to the outside of the inducting visual field, where the identification ability for a particular target is significantly low to an extent that the existence of a stimulus can be sensed.

From the above, it is found that the image quality in the discrimination visual field and the effective visual field is important in an image 424. The image quality in the discrimination visual field is particularly important.

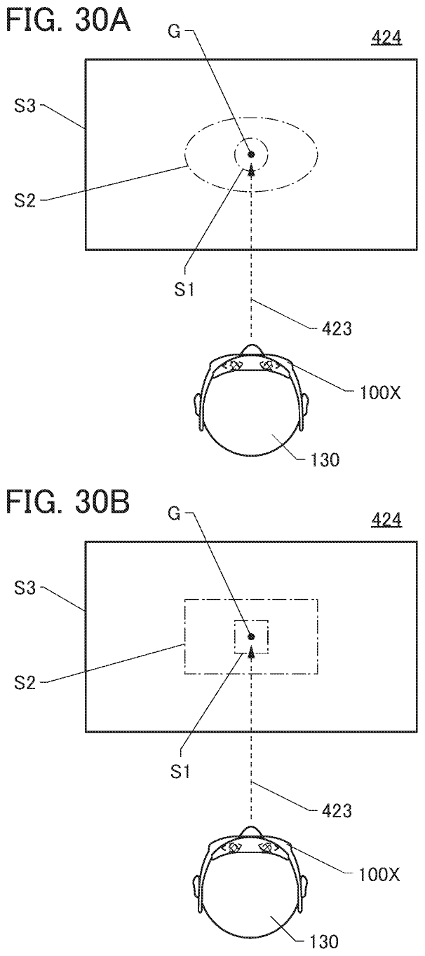

FIG. 30A is a schematic view illustrating the state where the user 130 sees the image 424 displayed on the display portion of the display apparatus 200 of the electronic device 100X from the front (image display surface). The image 424 shown in FIG. 30A also corresponds to the display portion. The gaze point G at the end of a gaze 423 of the user 130 is illustrated on the image 424. In this specification and the like, a region including the discrimination visual field and a region including the effective visual field on the image 424 are referred to as “the first region S1” and “the second region S2”, respectively. Furthermore, a region including the stable visual field, the inducting visual field, and/or the supplementary visual field is referred to as “the third region S3”.

Although the boundary (outline) between the first region S1 and the second region S2 is illustrated by a curved line in FIG. 30A, one embodiment of the present invention is not limited thereto. As illustrated in FIG. 30B, the boundary (outline) between the first region S1 and the second region S2 may be rectangular or polygonal. Alternatively, the boundary may have a shape in which a straight line and a curved line are combined. The display portion of the display apparatus 200 may be divided into two regions; one of the regions including the discrimination visual field and the effective visual field may be referred to as the first region S1, and the other region may be referred to as the second region S2. In this case, the third region S3 is not formed.

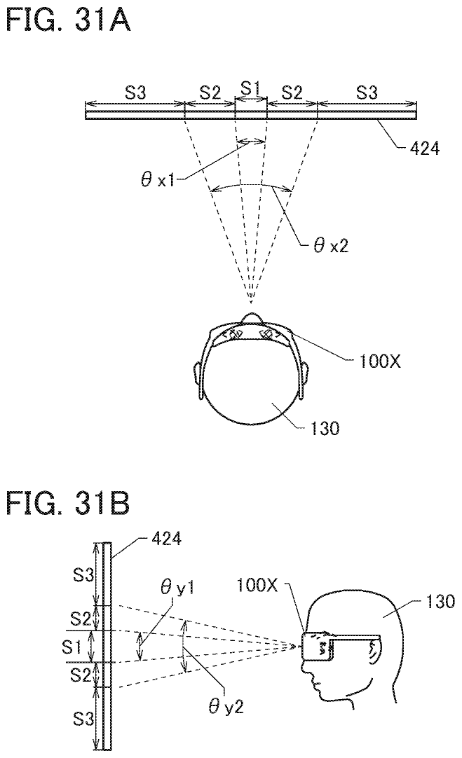

FIG. 31A is a top view of the image 424 displayed on the display portion of the display apparatus 200 of the electronic device 100X, and FIG. 31B is a side view of the image 424 displayed on the display portion of the display apparatus 200 of the electronic device 100X. In this specification and the like, the angle of the first region S1 in the horizontal direction is shown by “angle θx1”, and the angle of the second region S2 in the horizontal direction is shown by “angle θx2” (see FIG. 31A). In this specification and the like, the angle of the first region S1 in the vertical direction is shown by “angle θy1”, and the angle of the second region S2 in the vertical direction is shown by “angle θy2” (see FIG. 31B).

For example, by setting the angle θx1 to 10° and the angle θy1 to 10°, the area of the first region S1 can be widened. In that case, part of the effective visual field is included in the first region S1. Furthermore, by setting the angle θx2 to 45° and the angle θy2 to 35°, the area of the second region S2 can be widened. In that case, part of the stable visual field is included in the second region S2.

The position of the gaze point G varies to some extent by a swing of the gaze of the user 130. Thus, the angle θx1 and the angle θy1 are each preferably greater than or equal to 5° and smaller than 20°. When the area of the first region S1 is set larger than the discrimination visual field, the operation of the display apparatus 200 is stabilized and the image visibility is improved.

When the gaze 423 of the user 130 moves, the gaze point G also moves. Thus, the first region S1 and the second region S2 also move. For example, in the case where the fluctuation amount of the gaze 423 exceeds a certain amount, it is judged that the gaze 423 is moving. That is, when the fluctuation amount of the gaze point G exceeds a certain amount, it is judged that the gaze point G is moving. In the case where the fluctuation amount of the gaze 423 becomes lower than or equal to the certain amount, it is judged that the gaze 423 has stopped, and the first region S1 to the third region S3 are determined. That is, when the fluctuation amount of the gaze point G becomes lower than or equal to the certain amount, it is judged that the gaze point G has stopped, and the first region S1 to the third region S3 are determined.

The functional circuit 240 performs control of the driver circuit 230 differing between a plurality of regions (the first region S1 to the third region S3) (Step E15).

### <Configuration Example of Pixel Circuit>

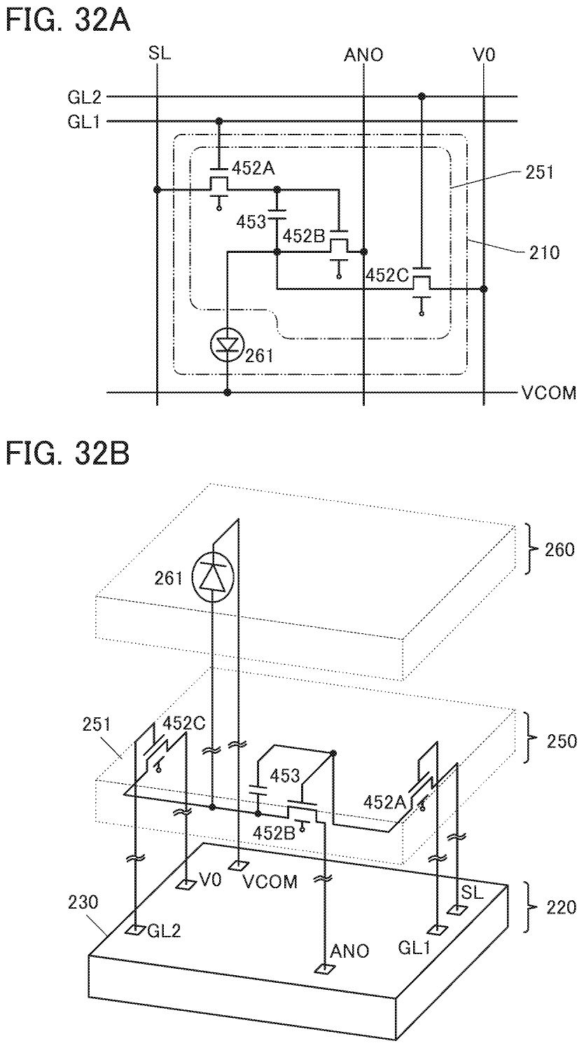

FIG. 32A and FIG. 32B illustrate a configuration example of the pixel circuit 251 and the light-emitting device 261 connected to the pixel circuit 251. FIG. 32A is a diagram illustrating the connection between elements, and FIG. 32B is a diagram illustrating the vertical positional relation of the layer 220 including the driver circuit, the layer 250 including a plurality of transistors of the pixel circuit, and the layer 260 including the light-emitting device.

The pixel circuit 251 illustrated as an example in FIG. 32A and FIG. 32B includes a transistor 452A, a transistor 452B, a transistor 452C, and a capacitor 453. The transistor 452A, the transistor 452B, and the transistor 452C can be OS transistors. Each of the OS transistors, the transistor 452A, the transistor 452B, and the transistor 452C, preferably includes a back gate electrode, in which case a structure in which the back gate electrode is supplied with the same signal as that supplied to a gate electrode or a structure in which the back gate electrode is supplied with a signal different from that supplied to the gate electrode can be used.

The transistor 452B includes a gate electrode electrically connected to the transistor 452A, a first electrode electrically connected to the light-emitting device 261, and a second electrode electrically connected to a wiring ANO. The wiring ANO supplies a potential for supplying current to the light-emitting device 261.

The transistor 452A includes a first terminal electrically connected to the gate electrode of the transistor 452B, a second terminal electrically connected to the wiring SL which functions as a source line, and the gate electrode having a function of controlling the conduction state or non-conduction state on the basis of the potential of a wiring GL1 which functions as a gate line.

The transistor 452C includes a first terminal electrically connected to a wiring V0, a second terminal electrically connected to the light-emitting device 261, and the gate electrode having a function of controlling the conducting state or the non-conducting state on the basis of the potential of a wiring GL2 functioning as a gate line. The wiring V0 is a wiring for supplying a reference potential and a wiring for outputting a current flowing through the pixel circuit 251 to the driver circuit 230 or the functional circuit 240.

The capacitor 453 includes a conductive film electrically connected to the gate electrode of the transistor 452B and a conductive film electrically connected to a second electrode of the transistor 452C.

The light-emitting device 261 includes a first electrode electrically connected to the first electrode of the transistor 452B and a second electrode electrically connected to a wiring VCOM. The wiring VCOM supplies a potential for supplying current to the light-emitting device 261.

Accordingly, the intensity of light emitted from the light-emitting device 261 can be controlled in accordance with an image signal supplied to the gate electrode of the transistor 452B. Furthermore, variations in the gate-source voltage of the transistor 452B can be inhibited by the reference potential of the wiring V0 supplied through the transistor 452C.

A current value that can be used for setting pixel parameters can be output from the wiring V0. Specifically, the wiring V0 can function as a monitor line for outputting current flowing through the transistor 452B or current flowing through the light-emitting device 261 to the outside. Current output to the wiring V0 is converted into voltage by a source follower circuit or the like and output to the outside. Alternatively, a current output to the wiring V0 can be converted into a digital signal by an A-D converter or the like and output to the functional circuit 240 or the like.

Note that the light-emitting device described in one embodiment of the present invention refers to a self-luminous display element such as an organic EL element (also referred to as an OLED (Organic Light Emitting Diode)). The light-emitting device electrically connected to the pixel circuit can be a self-luminous light-emitting device such as an LED (Light Emitting Diode), a micro LED, a QLED (Quantum-dot Light Emitting Diode), a semiconductor laser, or the like.

Note that in the structure illustrated as an example in FIG. 32B, the wirings electrically connecting the pixel circuit 251 and the driver circuit 230 can be shortened, so that wiring resistance of the wirings can be reduced. Thus, data writing can be performed at high speed, leading to a high-speed operation of the display apparatus 200. Therefore, even when the number of the pixel circuits 251 included in the display apparatus 200 is large, a sufficiently long frame period can be feasible and thus the pixel density of the display apparatus 200 can be increased. In addition, the increased pixel density of the display apparatus 200 can increase the resolution of an image displayed by the display apparatus 200. For example, the pixel density of the display apparatus 200 can be higher than or equal to 1000 ppi, higher than or equal to 5000 ppi, or higher than or equal to 7000 ppi. Thus, the display apparatus 200 can be, for example, a display apparatus for AR or VR and can be suitably used in an electronic apparatus with a short distance between the display portion and the user, such as an HMD.

### Modification Example

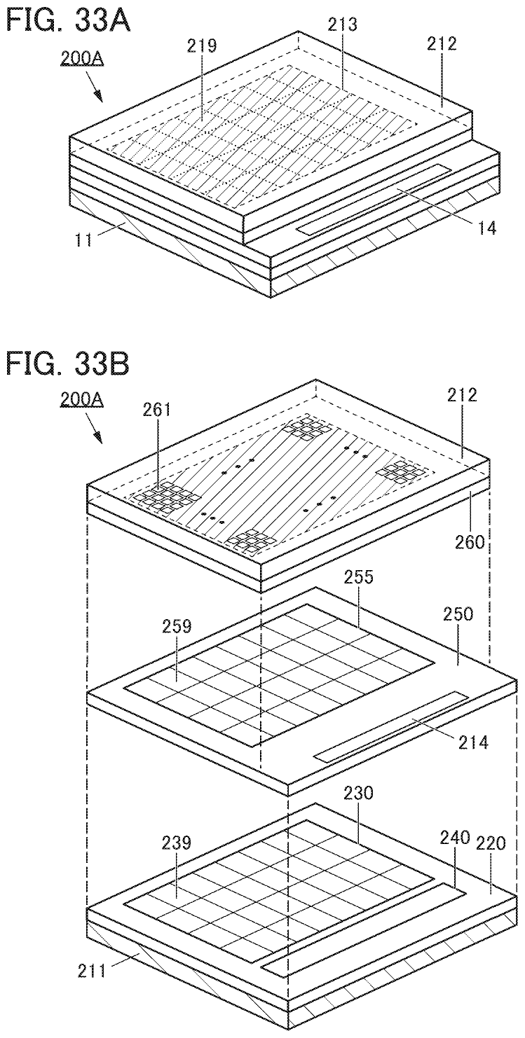

FIG. 33A and FIG. 33B are perspective views of a display apparatus 200A, which is a modification example of the display apparatus 200. FIG. 33B is a perspective view illustrating structures of layers included in the display apparatus 200A. In order to avoid repeated description, a description is mainly given to parts that are different from those of the display apparatus 200.

In the display apparatus 200A, the driver circuit 230 and the pixel circuit group 255 including the plurality of pixel circuits 251 overlap with each other. In a region overlapping with the display portion 213 of the display apparatus 200A, the pixel circuit group 255 is divided into a plurality of sections 259, and the driver circuit 230 is divided into a plurality of sections 239. The plurality of sections 239 each include a source driver circuit and a gate driver circuit.

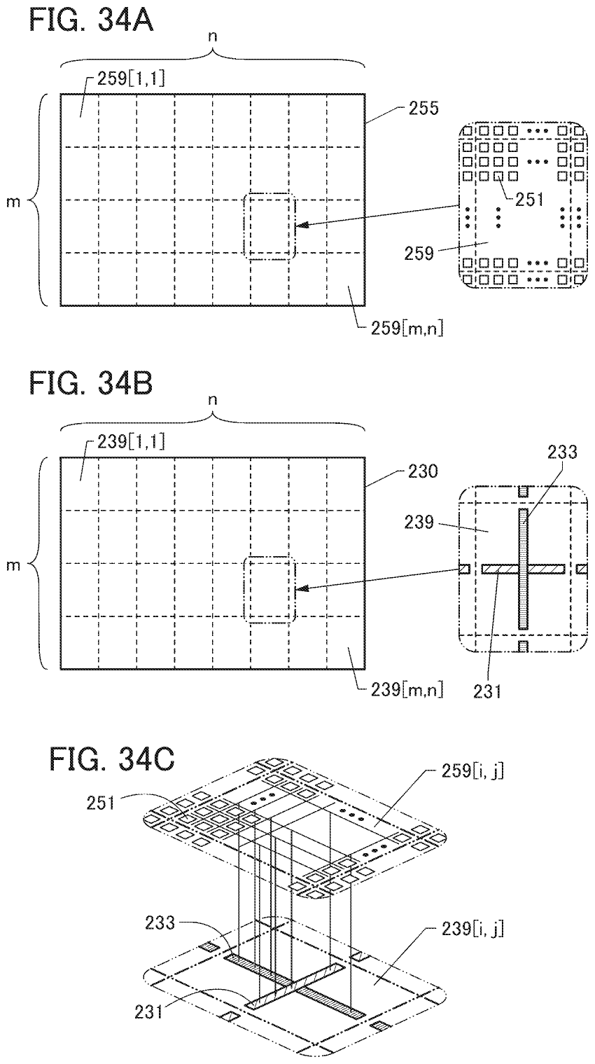

FIG. 34A illustrates a structure example of the pixel circuit group 255 included in the display apparatus 200A. FIG. 34B illustrates a structure example of the driver circuit 230 included in the display apparatus 200A. The sections 259 and the sections 239 are each arranged in a matrix of m rows and n columns (m and n are each an integer greater than or equal to 1). In this specification and the like, the section 259 in the first row and the first column is denoted by a section 259[1,1], and the section 259 in the m-th row and the n-th column is denoted by a section 259[m,n]. Similarly, the section 239 in the first row and the first column is denoted by a section 239[1,1], and the section 239 in the m-th row and the n-th column is denoted by a section 239[m,n]. FIG. 34A and FIG. 34B illustrate a case where m is 4 and n is 8. That is, the pixel circuit group 255 and the driver circuit 230 are each divided into 32 sections.

The plurality of sections 259 each include a plurality of pixel circuits 251, a plurality of wirings SL, and a plurality of wirings GL. In each of the sections 259, one of the plurality of pixel circuits 251 is electrically connected to at least one of the plurality of wirings SL and at least one of the plurality of wirings GL.

One of the sections 259 and one of the sections 239 are provided to overlap with each other (see FIG. 34C). For example, the section 259[i,j] (i is an integer greater than or equal to 1 and less than or equal to m. j is an integer greater than or equal to 1 and less than or equal to n) and the section 239[i,j] are provided to overlap with each other. The source driver circuit 231 included in the section 239[i,j] is electrically connected to the wiring SL included in the section 259[i,j]. The gate driver circuit 233 included in the section 239[i,j] is electrically connected to the wiring GL included in the section 259[i,j]. The gate driver circuit 233 included in the section 239[i,j] has a function of controlling the plurality of pixel circuits 251 included in the section 259[i,j].

When the section 259[i,j] and the section 239[i,j] are provided to overlap with each other, a connection distance (wiring length) between the pixel circuit 251 included in the section 259[i,j] and each of the source driver circuit 231 and the gate driver circuit 233 included in the section 239[i,j] can be made extremely short. As a result, the wiring resistance and the parasitic capacitance are reduced, and thus time taken for charging and discharging can be reduced and high-speed driving can be achieved. Furthermore, the power consumption can be reduced. Moreover, the size and weight of the display apparatus can be reduced.

In addition, the display apparatus 200A includes the source driver circuit 231 and the gate driver circuit 233 in each of the sections 239. Thus, the display portion 213 can be divided into the sections 259 corresponding to the sections 239, and image rewriting can be performed. For example, in the display portion 213, image data rewriting can be performed only in a section with an image change and image data can be retained in a section with no change; therefore, power consumption can be reduced.

In this embodiment and the like, one section of the display portion 213 divided into the sections 59 is referred to as a sub-display portion 219. In the display apparatus 200A described with reference to FIG. 33 and FIG. 34, the display portion 213 is divided into 32 sub-display portions 219 (see FIG. 33A). Each of the sub-display portions 219 includes the plurality of pixels 210 illustrated in FIG. 32 and the like. Specifically, one of the sub-display portions 219 includes one of the sections 259 including the plurality of pixel circuits 251, and the plurality of light-emitting devices 261. One section 239 has a function of controlling the plurality of pixels 210 included in one sub-display portion 219.

In the display apparatus 200A, the driving frequency (e.g., frame frequency, frame rate, or refresh rate) at the time of displaying an image can be set freely for each of the sub-display portions 219 by the timing controller 244 included in the functional circuit 240. The functional circuit 240 has a function of controlling operations in the plurality of sections 239 and the plurality of sections 259. In other words, the functional circuit 240 has a function of controlling driving frequency and an operation timing of a plurality of sub-display portions 219 each arranged in a matrix. In addition, the functional circuit 240 has a function of adjusting synchronization between the sub-display portions.

In the display apparatus in the electronic device of one embodiment of the present invention, the pixel circuit and the driving circuit are stacked and the driving frequency is different between the sub-display portions 219 in accordance with the motion of the gaze, whereby power consumption can be reduced.

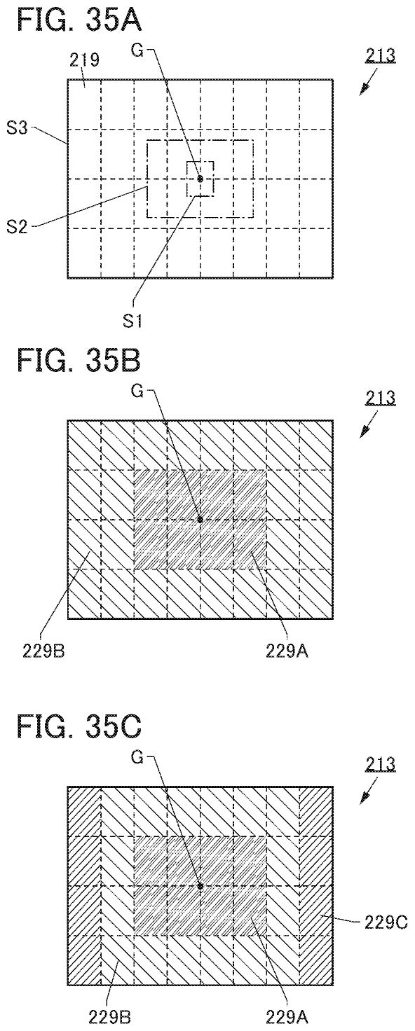

FIG. 35A illustrates the display portion 213 including the sub-display portions 219 in four rows and eight columns. FIG. 35A also illustrates the first region S1 to the third region S3 with the gaze point G as the center. The display apparatus 200A divides the plurality of sub-display portions 219 between a first section 229A overlapping with the first region S1 and the second region S2 and a second section 229B overlapping with the third region S3. In other words, the display apparatus 200A divides the plurality of sections 239 between the first section 229A and the second section 229B. In this case, the first section 229A overlapping with the first region S1 and the second region S2 is the sub-display portion 219 including a region overlapping with the gaze point G, and the second section 229B is the sub-display portion 219 which is positioned outside of the first section 229A and positioned far from the user's gaze point G. (see FIG. 35B).

The operations of the driver circuits (the source driver circuit 231 and the gate driver circuit 233) included in each of the plurality of sections 239 are controlled by the functional circuit 240. For example, the second section 229B is a section overlapping with the third region S3 including the above-described stable gaze visual field, induced visual field, and auxiliary visual field, and is a section where the user is hard to discriminate. Thus, the user perceives a small reduction in practical display quality (hereinafter also referred to as “practical display quality”) even when the number of times of image data rewriting per unit time (hereinafter, also referred to as “image rewriting frequency”) at the time of displaying an image is smaller in the second section 229B than in the first section 229A. That is, a reduction in the practical display quality is small even when the driving frequency of the second section 229B is lower than the driving frequency of the first section 229A.

A decrease in the driving frequency can result in a reduction in power consumption of the display apparatus. On the other hand, a decrease in the driving frequency also reduces the display quality. In particular, display quality in displaying a moving image is decreased. According to one embodiment of the present invention, the driving frequency of the second section 229B is made lower than the driving frequency of the first section 229A; thus, power consumption can be reduced in a section where the visibility by the user is low and the reduction in the practical display quality can be inhibited. According to one embodiment of the present invention, both display quality maintenance and a reduction in power consumption can be achieved.

The driving frequency of the first section 229A can be higher than or equal to 30 Hz and lower than or equal to 500 Hz, preferably higher than or equal to 60 Hz and lower than or equal to 500 Hz. The driving frequency of the second section 229B is preferably lower than or equal to the driving frequency of the first section 229A, further preferably lower than or equal to a half of the driving frequency of the first section 229A, still further preferably lower than or equal to one-fifth of the driving frequency of the first section 229A.

In addition, among the sub-display portions 219 overlapping with the third region S3, the third section 229C is provided outside the second section 229B (see FIG. 35C), and the driving frequency of the sub-display portion 219 included in the third section 229C may be lower than that of the second section 229B. The driving frequency of the third section 229C is preferably lower than or equal to the driving frequency of the second section 229B, further preferably lower than or equal to a half of the driving frequency of the second section 229B, still further preferably lower than or equal to one-fifth of the driving frequency of the second section 229B. A significantly low image rewriting frequency can further reduce power consumption. Alternatively, rewriting of image data may be stopped as necessary. Stopping image data rewriting can further reduce the power consumption.

When such a driving method is employed, a transistor with an extremely low off-state current is suitably used as a transistor included in the pixel circuit 251. For example, an OS transistor is suitably used as the transistor included in the pixel circuit 251. An OS transistor has an extremely low off-state current and thus can achieve long-term retention of image data supplied to the pixel circuit 251. It is particularly suitable to use an OS transistor as the transistor 452A.

In some cases, an image whose brightness, contrast, color tone, or the like is greatly different from that of the previous image is displayed as in the case where an image scene displayed on the display portion 213 is changed, for example. Such a case causes a mismatch of the image change timing between the first section 229A and a section with a lower driving frequency than the first section 229A; this might cause a great difference in the brightness, contrast, color tone, or the like between the sections, leading to the loss of the practical display quality. In the case where an image scene is changed, image rewriting can be temporarily performed in the section other than the first section 229A at the same driving frequency as the first section 229A, and then the driving frequency of the section other than the first section 229A can be decreased.

Furthermore, in the case where the fluctuation amount of the gaze point G is judged to be larger than a certain amount, image rewriting may be performed in the section other than the first section 229A at the same driving frequency as the first section 229A, and the driving frequency of the section other than the first section 229A may be decreased when the fluctuation amount is judged to be within the certain amount. In the case where the fluctuation amount of the gaze point G is judged to be small, the driving frequency of the section other than the first section 229A may be further decreased.

Note that sections set for the display portion 213 are not limited to the following three: the first section 229A, the second section 229B, and the third section 229C. Four or more sections may be set for the display portion 213. When a plurality of sections are set for the display portion 213 and the driving frequencies of the sections gradually are decreased, a reduction in the practical display quality can be smaller.

An image to be displayed on the first section 229A may be subjected to the above-described up-conversion processing. When an image subjected to the up-conversion processing is displayed on the first section 229A, the display quality can be increased. The up-conversion processing may be performed on an image to be displayed on the section other than the first section 229A. When an image subjected to the up-conversion processing is displayed on the section other than the first section 229A, a reduction in the practical display quality that occurs in the case where the driving frequency of the section other than the first section 229A is decreased can be smaller.

Note that the up-conversion processing of an image to be displayed on the first section 229A may be performed using an algorithm with high accuracy, and the up-conversion processing of an image to be displayed on the section other than the first section 229A may be performed using an algorithm with low accuracy. A reduction in the practical display quality that occurs in the case where the driving frequency of the section other than the first section 229A is decreased can be smaller also in such a case.

When image data rewriting for the sub-display portions 219 is performed concurrently in all of the sub-display portions 219, high-speed rewriting can be achieved. In other words, when image data rewriting performed in each of the sections 239 is performed concurrently in all of the sections 239, high-speed rewriting is achieved.

In general, while pixels in one row are selected by a gate driver circuit, a source driver circuit writes image data to all of the pixels in one row concurrently in line sequential driving. In the case where the display portion 213 is not divided into the sub-display portions 219 and the definition is 4000×2000, for example, image data needs to be written to 4000 pixels by the source driver circuit while the pixels in one row are selected by the gate driver circuit. In the case where the frame frequency is 120 Hz, one frame period is approximately 8.3 msec. Accordingly, the gate driver circuit needs to select 2000 rows in approximately 8.3 msec, and a period during which one gate line is selected, i.e., an image data writing period per pixel, is approximately 4.17 usec. That is, it becomes more difficult to ensure sufficient time for rewriting image data as the definition or frame frequency of the display portion increases.

The display portion 213 of the display apparatus 200A described as an example in this embodiment is divided into four parts in the row direction. Thus, the image data writing period per pixel in one sub-display portion 219 can be four times as long as that of the case where the display portion 213 is not divided. One embodiment of the present invention can easily ensure the time for rewriting image data even at a frame frequency of 240 Hz or 360 Hz, and thus can achieve a display apparatus with high display quality.

Since the display portion 213 of the display apparatus 200A described as an example in this embodiment is divided into four parts in the row direction, the length of the wiring SL electrically connecting the source driver circuit and the pixel circuit becomes one-fourth. Accordingly, each of the resistance and parasitic capacitance of the wiring SL becomes one-fourth, whereby the time required for writing (rewriting) image data can be shortened.

In addition, the display portion 213 of the display apparatus 200A described as an example in this embodiment is divided into eight parts in the column direction; thus, the length of the wiring GL electrically connecting the gate driver circuit and the pixel circuit becomes one-eighth. Accordingly, each of the resistance and parasitic capacitance of the wiring GL becomes one-eighth, whereby degradation and delay of a signal can be inhibited and the time for rewriting image data can be easily achieved.

Since the display apparatus 200A of one embodiment of the present invention enables sufficient time for writing image data to be achieved easily, display image rewriting can be performed at high speed. Thus, the display apparatus with high display quality can be achieved. In particular, a display apparatus that excels in displaying a moving image can be achieved.

At least part of the structure examples, the drawings corresponding thereto, and the like described in this embodiment as an example can be combined with the other structure examples, the other drawings, and the like as appropriate.

### Embodiment 6

In this embodiment, a structure example of a display module that can be used for a display of the electronic device of one embodiment of the present invention will be described.

The display apparatus of this embodiment can be a high-resolution display panel. For example, the display apparatus of one embodiment of the present invention can be used for display portions of information terminals (wearable devices) such as watch-type and bracelet-type information terminals and display portions of wearable devices capable of being worn on a head, such as a VR device like a head-mounted display and a glasses-type AR device.

### [Display Module]

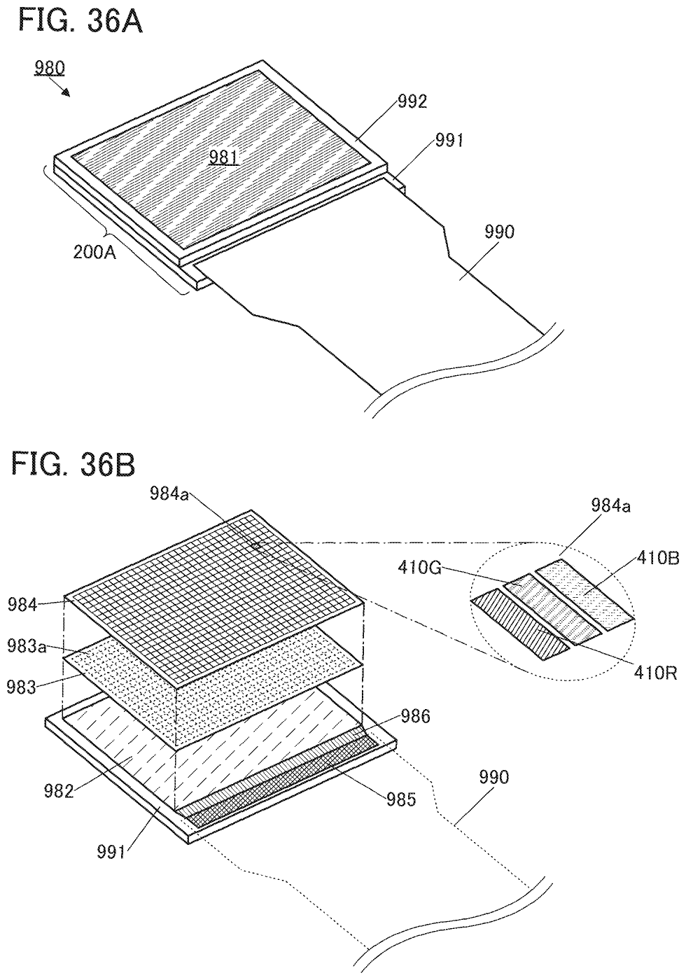

FIG. 36A illustrates a perspective view of a display module 980. The display module 980 includes the display apparatus 200A and an FPC 990. Note that the display panel included in the display module 980 is not limited to the display apparatus 200A and may be any of a display apparatus 200B to a display apparatus 200F described later.

The display module 980 includes a substrate 991 and a substrate 992. The display module 980 includes a display portion 981. The display portion 981 is a region where an image is displayed.

FIG. 36B shows a perspective view schematically illustrating a structure on the substrate 991 side. Over the substrate 991, a circuit portion 982, a pixel circuit portion 983 over the circuit portion 982, and a pixel portion 984 over the pixel circuit portion 983 are stacked. A terminal portion 985 to be connected to the FPC 990 is provided in a portion over the substrate 991 that does not overlap with the pixel portion 984. The terminal portion 985 and the circuit portion 982 are electrically connected to each other through a wiring portion 986 formed of a plurality of wirings.

The pixel portion 984 includes a plurality of pixels 984a arranged periodically. An enlarged view of one pixel 984a is illustrated on the right side of FIG. 36B. The pixel 984a includes a light-emitting device 410R that emits red light, a light-emitting device 410G that emits green light, and a light-emitting device 410B that emits blue light.

The pixel circuit portion 983 includes a plurality of pixel circuits 983a arranged periodically. One pixel circuit 983a is a circuit that controls light emission of three light-emitting devices included in one pixel 984a. One pixel circuit 983a may be provided with three circuits each of which controls light emission of one light-emitting device. For example, the pixel circuit 983a can include at least one selection transistor, one current control transistor (driving transistor), and a capacitor for one light-emitting device. In this case, a gate signal is input to a gate of the selection transistor, and a source signal is input to a source of the selection transistor. With such a structure, an active-matrix display panel is achieved.

The circuit portion 982 includes a circuit for driving the pixel circuits 983a in the pixel circuit portion 983. For example, the circuit portion 982 preferably includes one or both of a gate line driver circuit and a source line driver circuit. The circuit portion 982 may also include at least one of an arithmetic circuit, a memory circuit, a power supply circuit, and the like. A transistor included in the circuit portion 982 may constitute part of the pixel circuit 983a. That is, the pixel circuit 983a may be constituted by a transistor included in the pixel circuit portion 983 and a transistor included in the circuit portion 982.

The FPC 990 functions as a wiring for supplying a video signal, a power supply potential, or the like to the circuit portion 982 from the outside. An IC may be mounted on the FPC 990.

The display module 980 can have a structure in which one or both of the pixel circuit portion 983 and the circuit portion 982 are stacked below the pixel portion 984; thus, the aperture ratio (the effective display area ratio) of the display portion 981 can be significantly high. For example, the aperture ratio of the display portion 981 can be greater than or equal to 40% and less than 100%, preferably greater than or equal to 50% and less than or equal to 95%, further preferably greater than or equal to 60% and less than or equal to 95%. Furthermore, the pixels 984a can be arranged extremely densely and thus the display portion 981 can have extremely high resolution. For example, the pixels 984a are preferably arranged in the display portion 981 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 980 has an extremely high resolution, and thus can be suitably used for a VR device such as a head-mounted display or a glasses-type AR device. For example, even with a structure in which the display portion of the display module 980 is seen through a lens, pixels of the extremely-high-resolution the display portion 981 included in the display module 980 are prevented from being perceived when the display portion is enlarged by the lens, so that display providing a high sense of immersion can be performed. Without being limited thereto, the display module 980 can be suitably used for electronic apparatuses including a relatively small display portion. For example, the display module 980 can be suitably used for a display portion of a wearable electronic apparatus, such as a wrist watch.

### [Display Apparatus 200A]

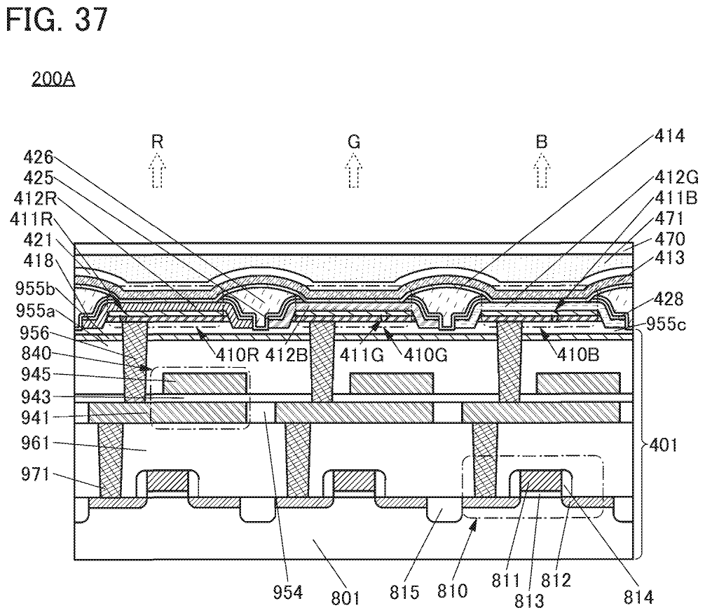

The display apparatus 200A illustrated in FIG. 37A includes a substrate 801, the light-emitting devices 410R, 410G, and 410B, a capacitor 840, and a transistor 810.

The substrate 801 corresponds to the substrate 991 in FIG. 36A and FIG. 36B.

The transistor 810 is a transistor including a channel formation region in the substrate 801. As the substrate 801, a semiconductor substrate such as a single crystal silicon substrate can be used, for example. The transistor 810 includes part of the substrate 801, a conductive layer 811, low-resistance regions 812, an insulating layer 813, and an insulating layer 814. The conductive layer 811 functions as a gate electrode. The insulating layer 813 is positioned between the substrate 801 and the conductive layer 811 and functions as a gate insulating layer. The low-resistance regions 812 are regions where the substrate 801 is doped with an impurity, and functions as one of a source and a drain. The insulating layer 814 is provided to cover the side surface of the conductive layer 811 and functions as an insulating layer.

An element isolation layer 815 is provided between two adjacent transistors 810 to be embedded in the substrate 801.

An insulating layer 961 is provided to cover the transistor 810, and the capacitor 840 is provided over the insulating layer 961.

The capacitor 840 includes a conductive layer 941, a conductive layer 945, and an insulating layer 943 positioned between these conductive layers. The conductive layer 941 functions as one electrode of the capacitor 840, the conductive layer 945 functions as the other electrode of the capacitor 840, and the insulating layer 943 functions as a dielectric of the capacitor 840.

The conductive layer 941 is provided over the insulating layer 961 and is embedded in an insulating layer 954. The conductive layer 941 is electrically connected to one of a source and a drain of the transistor 810 through a plug 971 embedded in the insulating layer 961. The insulating layer 943 is provided to cover the conductive layer 941. The conductive layer 945 is provided in a region overlapping with the conductive layer 941 with the insulating layer 943 therebetween.

An insulating layer 955a is provided to cover the capacitor 840, an insulating layer 955b is provided over the insulating layer 955a, and an insulating layer 955c is provided over the insulating layer 955b.

An inorganic insulating film can be suitably used as each of the insulating layer 955a, the insulating layer 955b, and the insulating layer 955c. For example, it is preferable that a silicon oxide film be used as each of the insulating layer 955a and the insulating layer 955c and that a silicon nitride film be used as the insulating layer 955b. This enables the insulating layer 955b to function as an etching protective film. Although this embodiment shows an example where the insulating layer 955c is partly etched and a depressed portion is formed, a depressed portion is not necessarily provided in the insulating layer 955c.

The light-emitting device 410R, the light-emitting device 410G, and the light-emitting device 410B are provided over the insulating layer 955c.

Since the light-emitting devices for different emission colors are separately formed in the display apparatus 200A, the difference between the chromaticity at low luminance emission and that at high luminance emission is small. Furthermore, since the organic layer 412R, 412G, and 412B are separated from each other, crosstalk generated between adjacent subpixels can be suppressed while the display panel has high resolution. Accordingly, the display panel can have high resolution and high display quality.

In regions between adjacent light-emitting devices, an insulating layer 425, a resin layer 426, and a layer 428 are provided.

A pixel electrode 411R, a pixel electrode 411G, and a pixel electrode 411B of the light-emitting device are each electrically connected to one of the source and the drain of the transistor 810 through a plug 956 embedded in the insulating layer 955a, the insulating layer 955b, and the insulating layer 955c, the conductive layer 941 embedded in the insulating layer 954, and the plug 971 embedded in the insulating layer 961. The top surface of the insulating layer 955c and the top surface of the plug 956 are level or substantially level with each other. A variety of conductive materials can be used for the plugs.

A protective layer 421 is provided over the light-emitting devices 410R, 410G, and 410B. A substrate 470 is bonded to the protective layer 421 with an adhesive layer 471.

An insulating layer covering the end portion of the top surface of the pixel electrodes 411 is not provided between two adjacent pixel electrodes 411. Thus, the distance between adjacent light-emitting devices can be extremely shortened. Accordingly, the display apparatus can have a high resolution or a high definition.

### [Display Apparatus 200B]

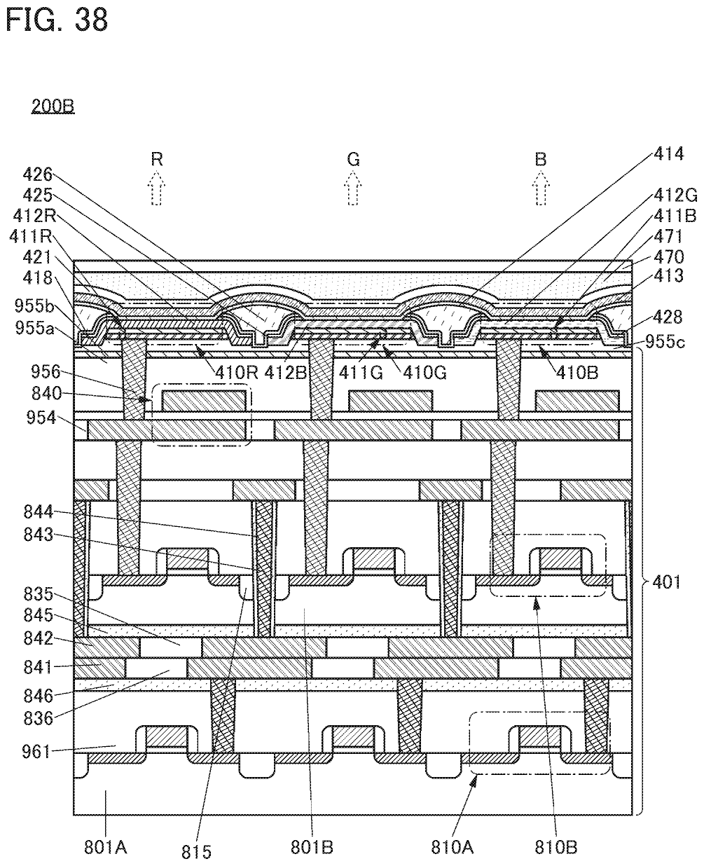

The display apparatus 200B illustrated in FIG. 38 has a structure in which a transistor 810A and a transistor 810B in each of which a channel is formed in a semiconductor substrate are stacked. Note that in the description of the display panel below, portions similar to those of the above-mentioned display panel are not described in some cases.

In the display apparatus 200B, a substrate 801B provided with the transistor 810B, the capacitor 840, and the light-emitting devices is bonded to a substrate 801A provided with the transistor 810A.

Here, an insulating layer 845 is provided on the bottom surface of the substrate 801B and an insulating layer 846 is provided over the insulating layer 961 provided over the substrate 801A. The insulating layers 845 and 846 are insulating layers functioning as protective layers and can inhibit diffusion of impurities into the substrate 801B and the substrate 801A. As the insulating layers 845 and 846, an inorganic insulating film that can be used as the protective layer 421 or an insulating layer 832 can be used.

The substrate 801B is provided with a plug 843 that penetrates the substrate 801B and the insulating layer 845. Here, an insulating layer 844 functioning as a protective layer is preferably provided to cover the side surface of the plug 843.

The substrate 801B is provided with a conductive layer 842 under the insulating layer 845. The conductive layer 842 is embedded in an insulating layer 835 and the bottom surfaces of the conductive layer 842 and the insulating layer 835 are planarized. The conductive layer 842 is electrically connected to the plug 843.

Meanwhile, a conductive layer 841 is provided over the insulating layer 846 over the substrate 801A. The conductive layer 841 is embedded in an insulating layer 836 and the top surfaces of the conductive layer 841 and the insulating layer 836 are planarized.

The conductive layer 841 and the conductive layer 842 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 841 and the conductive layer 842. In that case, it is possible to employ Cu—Cu (copper-to-copper) direct bonding (a technique for achieving electrical continuity by connecting Cu (copper) pads).

### [Display Apparatus 200C]

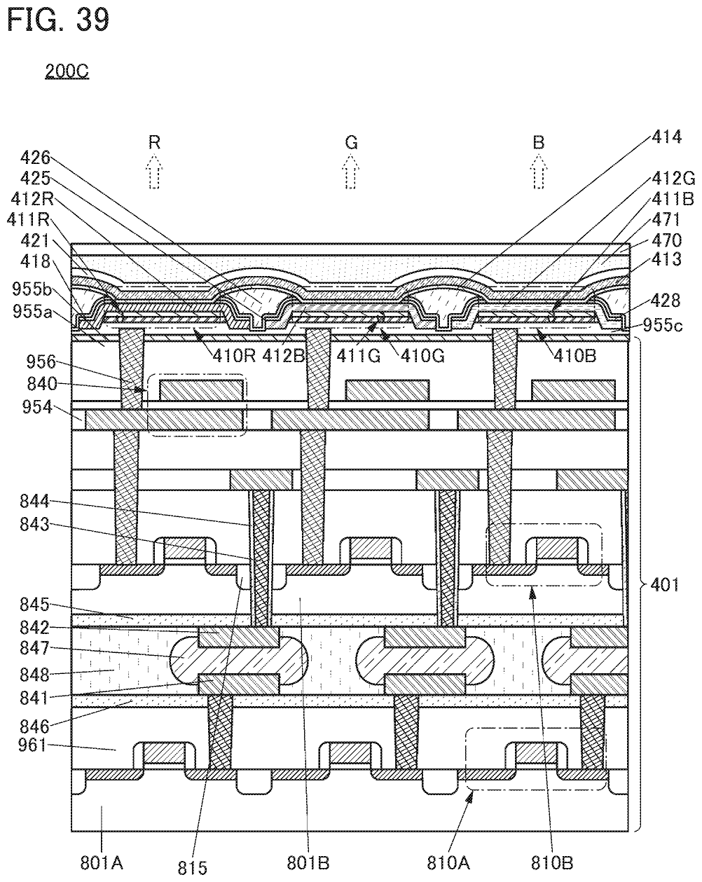

The display apparatus 200C illustrated in FIG. 39 has a structure in which the conductive layer 841 and the conductive layer 842 are bonded to each other through a bump 847.

As illustrated in FIG. 39, providing the bump 847 between the conductive layer 841 and the conductive layer 842 enables the conductive layer 841 and the conductive layer 842 to be electrically connected to each other. The bump 847 can be formed using a conductive material containing gold (Au), nickel (Ni), indium (In), tin (Sn), or the like, for example. For another example, solder may be used for the bump 847. An adhesive layer 848 may be provided between the insulating layer 845 and the insulating layer 846. In the case where the bump 847 is provided, the insulating layer 835 and the insulating layer 836 may be omitted.

### [Display Apparatus 200D]

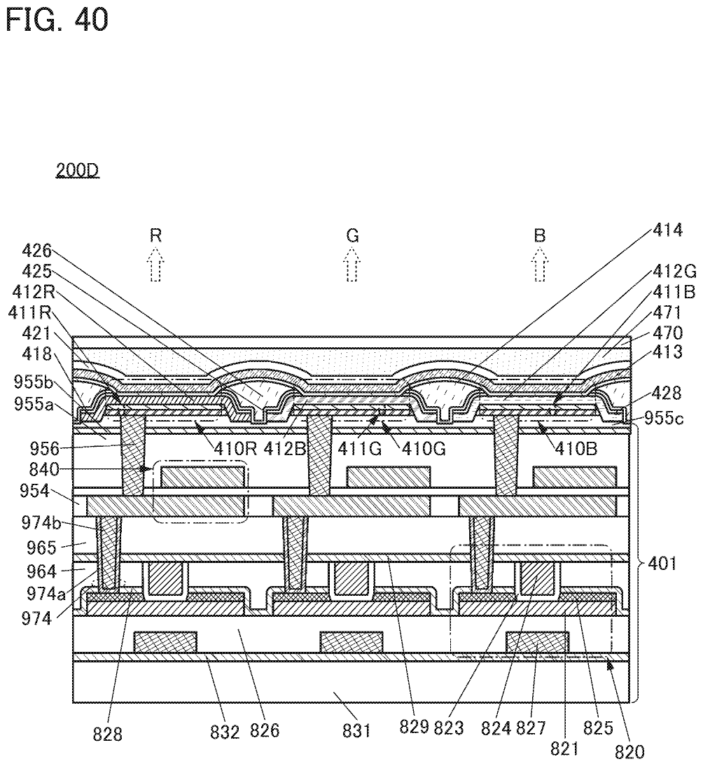

The display apparatus 200D illustrated in FIG. 40 is different from the display apparatus 200A mainly in a structure of a transistor.

A transistor 820 is a transistor (OS transistor) that includes a metal oxide (also referred to as an oxide semiconductor) in its semiconductor layer where a channel is formed.

The transistor 820 includes a semiconductor layer 821, an insulating layer 823, a conductive layer 824, a pair of conductive layers 825, an insulating layer 826, and a conductive layer 827.

A substrate 831 corresponds to the substrate 991 in FIG. 36A and FIG. 36B.

The insulating layer 832 is provided over the substrate 831. The insulating layer 832 functions as a barrier layer that prevents diffusion of impurities such as water and hydrogen from the substrate 831 into the transistor 820 and release of oxygen from the semiconductor layer 821 to the insulating layer 832 side. As the insulating layer 832, for example, a film in which hydrogen or oxygen is less likely to diffuse than in a silicon oxide film, such as an aluminum oxide film, a hafnium oxide film, or a silicon nitride film, can be used.

The conductive layer 827 is provided over the insulating layer 832, and the insulating layer 826 is provided to cover the conductive layer 827. The conductive layer 827 functions as a first gate electrode of the transistor 820, and part of the insulating layer 826 functions as a first gate insulating layer. An oxide insulating film such as a silicon oxide film is preferably used as at least part of the insulating layer 826 that is in contact with the semiconductor layer 821. The top surface of the insulating layer 826 is preferably planarized.

The semiconductor layer 821 is provided over the insulating layer 826. The semiconductor layer 821 preferably includes a metal oxide film having semiconductor characteristics (also referred to as an oxide semiconductor). The pair of the conductive layers 825 is provided over and in contact with the semiconductor layer 821 and functions as a source electrode and a drain electrode.

An insulating layer 828 is provided to cover the top surfaces and the side surfaces of the pair of the conductive layers 825, the side surface of the semiconductor layer 821, and the like, and an insulating layer 964 is provided over the insulating layer 828. The insulating layer 828 functions as a barrier layer that prevents diffusion of impurities such as water and hydrogen from the insulating layer 964 and the like into the semiconductor layer 821 and release of oxygen from the semiconductor layer 821. As the insulating layer 828, an insulating film similar to the above-described insulating layer 832 can be used.

An opening reaching the semiconductor layer 821 is provided in the insulating layer 828 and the insulating layer 964. The insulating layer 823, which is in contact with the top surface of the semiconductor layer 821, and the conductive layer 824 are embedded in the opening. The conductive layer 824 functions as a second gate electrode, and the insulating layer 823 functions as a second gate insulating layer.

The top surface of the conductive layer 824, the top surface of the insulating layer 823, and the top surface of the insulating layer 964 are planarized so as to be level or substantially level with each other, and an insulating layer 829 and an insulating layer 965 are provided to cover these layers.

The insulating layer 964 and the insulating layer 965 function as interlayer insulating layers. The insulating layer 829 functions as a barrier layer that prevents diffusion of impurities such as water and hydrogen from the insulating layer 965 or the like into the transistor 820. For the insulating layer 829, an insulating film similar to the insulating layer 828 and the insulating layer 832 can be used.

A plug 974 electrically connected to one of the pair of the conductive layers 825 is provided to be embedded in the insulating layer 965, the insulating layer 829, and the insulating layer 964. Here, the plug 974 preferably includes a conductive layer 974a covering the side surface of an opening formed in the insulating layer 965, the insulating layer 829, the insulating layer 964, and the insulating layer 828 and part of the top surface of the conductive layer 825, and a conductive layer 974b in contact with the top surface of the conductive layer 974a. For the conductive layer 974a, a conductive material that does not easily allow diffusion of hydrogen and oxygen is preferably used.

### [Display Apparatus 200E]

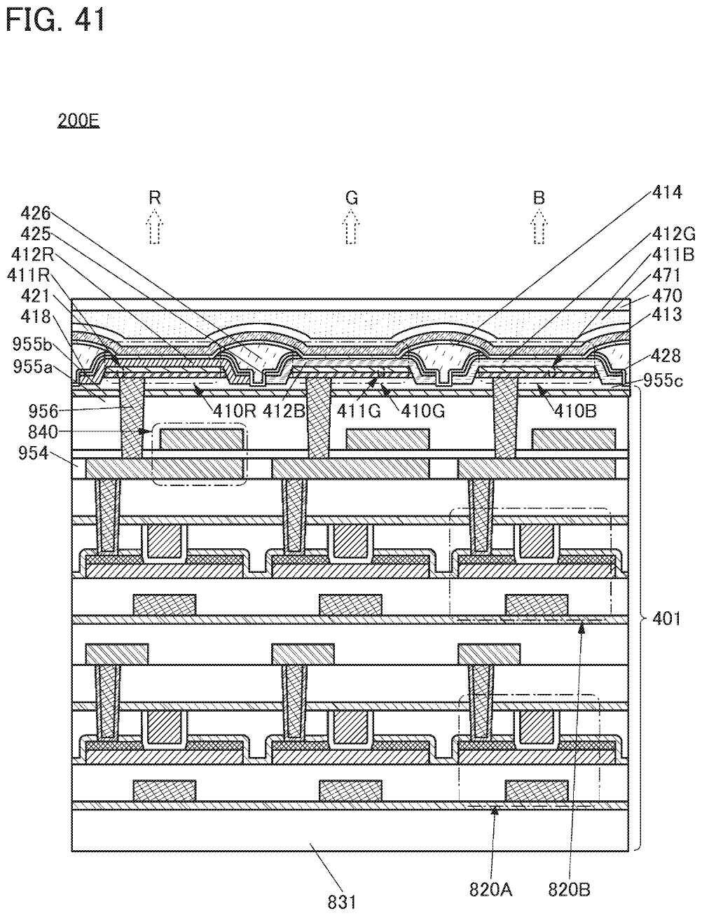

The display apparatus 200E illustrated in FIG. 41 has a structure in which a transistor 820A and a transistor 820B each including an oxide semiconductor in a semiconductor where a channel is formed are stacked.

The description of the display apparatus 200D can be referred to for the transistor 820A, the transistor 820B, and the components around them.

Although the structure in which two transistors including an oxide semiconductor are stacked is described, the present invention is not limited thereto. For example, three or more transistors may be stacked.

### [Display Apparatus 200F]

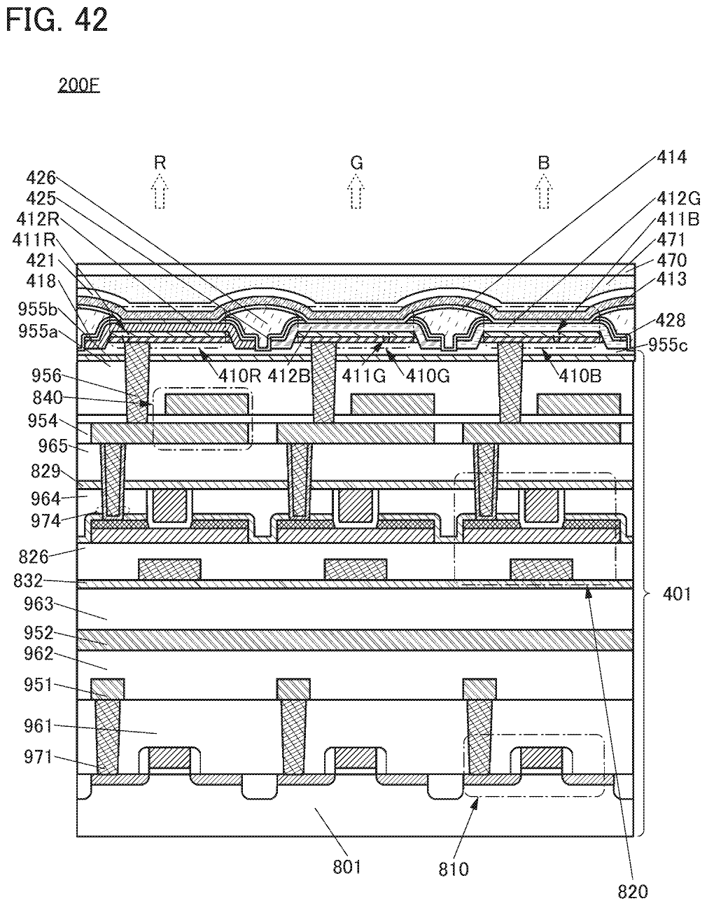

The display apparatus 200F illustrated in FIG. 42 has a structure in which the transistor 810 whose channel is formed in the substrate 801 and the transistor 820 containing a metal oxide in the semiconductor layer where the channel is formed are stacked.

The insulating layer 961 is provided to cover the transistor 810, and a conductive layer 951 is provided over the insulating layer 961. An insulating layer 962 is provided to cover the conductive layer 951, and a conductive layer 952 is provided over the insulating layer 962. The conductive layer 951 and the conductive layer 952 each function as a wiring. An insulating layer 963 and the insulating layer 832 are provided to cover the conductive layer 952, and the transistor 820 is provided over the insulating layer 832. The insulating layer 965 is provided to cover the transistor 820, and the capacitor 840 is provided over the insulating layer 965. The capacitor 840 and the transistor 820 are electrically connected to each other through the plug 974.

The transistor 820 can be used as a transistor included in the pixel circuit. The transistor 810 can be used as a transistor included in the pixel circuit or a transistor included in a driver circuit for driving the pixel circuit (a gate line driver circuit or a source line driver circuit). The transistor 810 and the transistor 820 can also be used as transistors included in a variety of circuits such as an arithmetic circuit and a memory circuit.

With such a structure, not only the pixel circuit but also the driver circuit and the like can be formed directly under the light-emitting devices; thus, the display panel can be downsized as compared with the case where a driver circuit is provided around a display region.

### [Display Apparatus 200G]

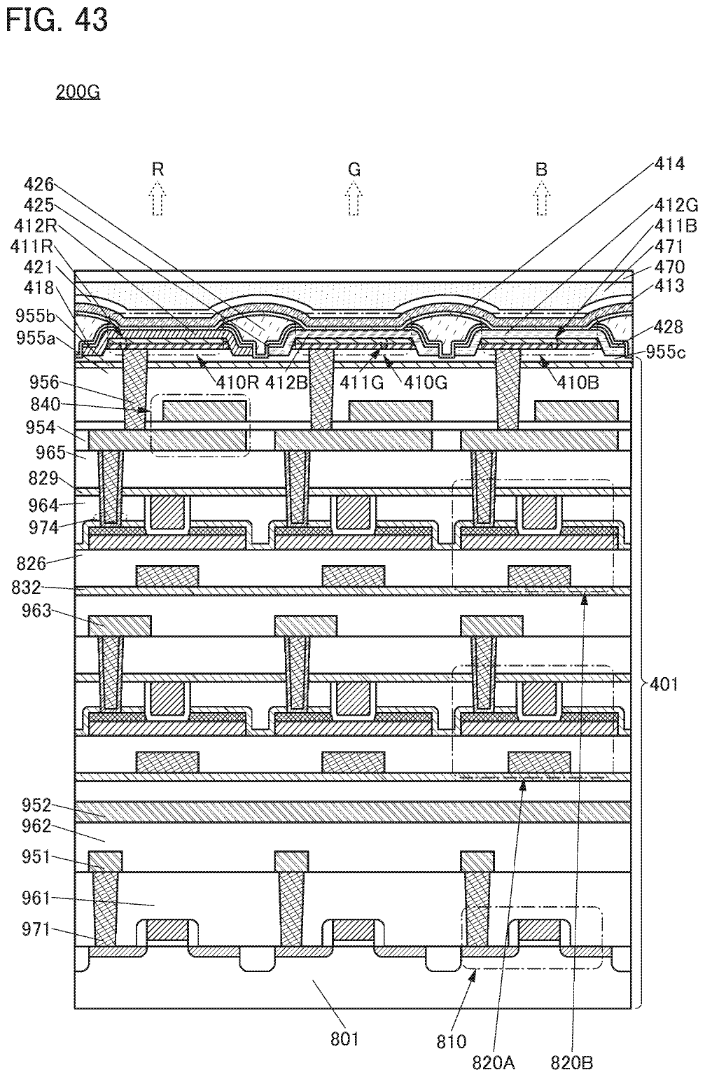

A display apparatus 200G illustrated in FIG. 43 has a structure in which the transistor 820A containing a metal oxide in a semiconductor layer where a channel is formed and the transistor 820B containing a metal oxide in a semiconductor layer where a channel is formed are stacked. This structure enables the use of transistors that differ in the composition of the constituent elements in the metal oxide in the semiconductor layer. Thus, the display apparatus can be formed using OS transistors with different transistor characteristics. For example, the transistor 820A in the upper layer is used as a transistor of a pixel circuit for driving the light-emitting device, and the transistor 820B in the lower layer can be used as a transistor of a driver circuit.

With such a structure, the circuits provided directly under the light-emitting devices can be arranged with higher density; thus, the display panel can be downsized as compared with the case where a driver circuit is provided around a display region.

At least part of this embodiment can be implemented in combination with the other embodiments described in this specification as appropriate.

### Embodiment 7

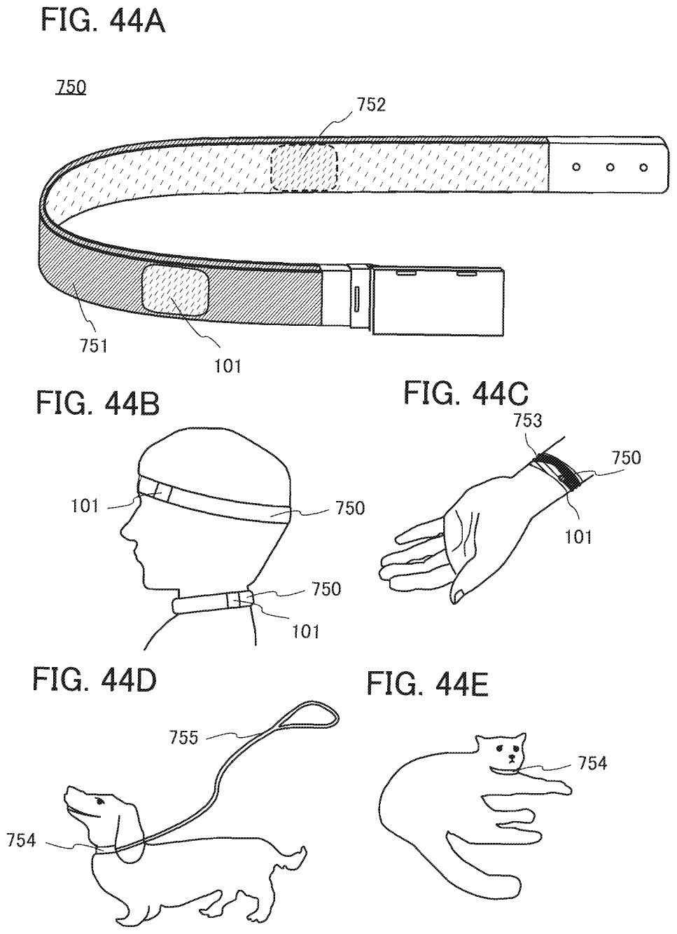

In this embodiment, examples of electronic devices including the above-described semiconductor device will be described with reference to FIG. 44.

Examples of electronic devices including the semiconductor device of one embodiment of the present invention include display apparatuses of televisions, monitors, and the like; lighting devices; desktop or laptop personal computers; word processors; image reproduction devices that reproduce still images and moving images stored in recording media such as DVD (Digital Versatile Disc); portable CD players; radios; tape recorders; headphone stereos; stereos; table clocks; wall clocks; cordless phone handsets; transceivers; mobile phones; car phones; portable game machines; tablet terminals; large-sized game machines such as pachinko machines; calculators; portable information terminals; electronic notebooks; e-book readers; electronic translators; audio input devices; video cameras; digital still cameras; electric shavers; high-frequency heating appliances such as microwave ovens; electric rice cookers; electric washing machines; electric vacuum cleaners; water heaters; electric fans; hair dryers; air-conditioning systems such as air conditioners, humidifiers, and dehumidifiers; dishwashers; dish dryers; clothes dryers; futon dryers; electric refrigerators; electric freezers; electric refrigerator-freezers; freezers for preserving DNA; flashlights; tools such as chain saws; smoke detectors; and medical equipment such as dialyzers. Other examples include industrial equipment such as guide lights, traffic lights, conveyor belts, elevators, escalators, industrial robots, power storage systems, and power storage devices for leveling the amount of power supply and smart grid.

In addition, moving objects and the like driven by electric motors using electric power from the power storage devices are also included in the category of electronic devices. Examples of the moving objects include electric vehicles (EVs), hybrid electric vehicles (HEVs) that include both an internal-combustion engine and a motor, plug-in hybrid electric vehicles (PHEVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic devices may include a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), for example.

The electronic device can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication mean, and a function of reading out a program or data stored in a recording medium.

FIG. 44A illustrates an example of a band-type information terminal. An information terminal 750 includes a housing 751, the semiconductor device 101, a sensor 752, and the like. The information terminal 750 may include a secondary battery, a display apparatus, and the like inside. The semiconductor device of one embodiment of the present invention is used for the information terminal 750, whereby the information terminal 750 can function as a shock-resistant IoT device that is sufficiently reduced in size and power consumption.

FIG. 44B is a diagram illustrating an example of a usage mode of the information terminal 750 illustrated in FIG. 44A. The information terminal 750 can be used while being wound around a user's head, neck, or the like. For example, a structure can be employed in which a sensor (not illustrated) is provided inside the band-type information terminal 750 and information obtained by the sensor is processed with a semiconductor device. With this structure, convenience of a shock-resistant IoT device that is sufficiently reduced in size and power consumption can be improved.

FIG. 44C is a diagram illustrating another example of a usage mode of the information terminal 750 illustrated in FIG. 44A. The information terminal 750 can be used while being wound around a user's arm portion or the like. For example, a structure can be employed in which a sensor (not illustrated) is provided inside the band-type information terminal 750, information obtained from the sensor is processed with a semiconductor device, and obtained data is transmitted and received to and from an external communication device through an antenna 753 or the like provided in the band-type information terminal 750. With this structure, convenience of a shock-resistant IoT device that is sufficiently reduced in size and power consumption can be improved.

The usage mode of the electronic device of one embodiment of the present invention described with reference to FIG. 44B and FIG. 44C may employ a structure in which the electronic device is attached to an animal such as a dog or a cat may be employed. For example, in FIG. 44D and FIG. 44E, a dog and a cat to which the information terminal 750 is attached are illustrated. Like the information terminal 750 described with reference to FIG. 44B and FIG. 44C, collars 754 and a lead 755 illustrated in FIG. 44D and FIG. 44E include a sensor, the semiconductor device 101, and the like. With this structure, convenience of an IoT device that is highly resistant to impact and is excellent in reduction in size and power consumption can be improved. The structures, configurations, methods, and the like described in this embodiment can be used in combination as appropriate with the structures, configurations, methods, and the like described in the other embodiments.

### Supplementary Notes on Description in this Specification and the Like

The following are notes on the description of the foregoing embodiments and the structures in the embodiments.

One embodiment of the present invention can be constituted by appropriately combining the structure described in an embodiment with any of the structures described in the other embodiments. In addition, in the case where a plurality of structure examples are described in one embodiment, some of the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, the blocks in the block diagrams are not limited by the components described in the specification, and the description can be changed appropriately depending on the situation.

Furthermore, in the drawings, the size, the layer thickness, or the region is shown with given magnitude for description convenience. Therefore, they are not limited to the illustrated scale. Note that the drawings are schematically shown for clarity, and embodiments of the present invention are not limited to shapes, values, or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the terms “electrode” or “wiring” do not functionally limit these components. For example, an “electrode” is used as part of a “wiring” in some cases, and vice versa. Furthermore, for example, the term “electrode” or “wiring” also includes the case where a plurality of “electrodes” or “wirings” are formed in an integrated manner.

In this specification and the like, voltage and potential can be replaced with each other as appropriate. The term voltage refers to a potential difference from a reference potential, and when the reference potential is a ground potential, for example, voltage can be replaced with potential. The ground potential does not necessarily mean 0 V. Potentials are relative values, and a potential supplied to a wiring or the like is sometimes changed depending on the reference potential.

In this specification and the like, the terms “film” and “layer” can be interchanged with each other depending on the case or circumstances. For example, the term “conductive layer” can be changed into the term “conductive film” in some cases. Also, for example, the term “insulating film” can be changed into the term “insulating layer” in some cases.

In this specification and the like, a switch is in a conduction state (on state) or in a non-conduction state (off state) to determine whether current flows therethrough or not. Alternatively, a switch has a function of selecting and changing a current path.

In this specification and the like, the channel length refers to, for example, the distance between a source and a drain in a region where a semiconductor (or a portion where current flows in a semiconductor when a transistor is on) and a gate overlap with each other or a region where a channel is formed in a top view of the transistor.

In this specification and the like, the channel width refers to, for example, the length of a portion where a source and a drain face each other in a region where a semiconductor (or a portion where current flows in a semiconductor when a transistor is on) and a gate electrode overlap with each other or a region where a channel is formed.

In this specification and the like, the expression “A and B are connected” means the case where A and B are electrically connected to each other as well as the case where A and B are directly connected to each other. Here, the expression “A and B are electrically connected” means the case where electric signals can be transmitted and received between A and B when an object having any electric action exists between A and B.

### REFERENCE NUMERALS

10M: backup circuit, 10: CPU, 11: CPU core, 12: L1 cache memory device, 13: L2 cache memory device, 14: bus interface portion, 20M: data retention circuit, 20: accelerator, 21: memory circuit, 22: arithmetic circuit, 23: control circuit, 30M: memory cell, 30: memory device, 31: memory cell array, 32: peripheral circuit, 40A: bus, 40B: bus, 41: DMAC, 42: PMU, 43: memory controller, 44: controller, 45: USB interface circuit, 46: display interface circuit, 50: bridge circuit, 51: interrupt control circuit, 52: interface circuit, 53: battery control circuit, 54: DAC interface circuit, 60: power supply circuit, 100: electronic device, 101: semiconductor device, 102: display, 103: main memory, 104: battery, 105: sensor, 111: housing, 112: operation portion, 113: band

1. An electronic device comprising:
a semiconductor device,
wherein the semiconductor device comprises a CPU, an accelerator, and a memory device,
wherein the CPU comprises a scan flip-flop circuit and a backup circuit electrically connected to the scan flip-flop circuit,
wherein the backup circuit comprises a first transistor,
wherein the accelerator comprises an arithmetic circuit and a data retention circuit electrically connected to the arithmetic circuit,
wherein the data retention circuit comprises a second transistor,
wherein the memory device comprises a memory cell comprising a third transistor, and
wherein the first transistor to the third transistor each comprise a semiconductor layer comprising a metal oxide in a channel formation region.

2. An electronic device comprising:
a semiconductor device,
wherein the semiconductor device comprises a CPU, an accelerator, and a memory device,
wherein the CPU comprises a scan flip-flop circuit and a backup circuit electrically connected to the scan flip-flop circuit,
wherein the backup circuit comprises a first transistor,
wherein a layer where the backup circuit is provided is stacked with a layer where the scan flip-flop circuit is provided,
wherein the accelerator comprises an arithmetic circuit and a data retention circuit electrically connected to the arithmetic circuit,
wherein the data retention circuit comprises a second transistor,
wherein a layer where the data retention circuit is provided is stacked with a layer where the arithmetic circuit is provided,
wherein the memory device comprises a memory cell comprising a third transistor, and
wherein the first transistor to the third transistor each comprise a semiconductor layer comprising a metal oxide in a channel formation region.

3. The electronic device according to claim 1,
wherein the backup circuit is configured to retain, when the CPU does not operate, data retained in the scan flip-flop circuit in a state where supply of power supply voltage is stopped.

4. The electronic device according to claim 1,
wherein the data retention circuit is configured to retain, when the accelerator does not operate, data retained in the data retention circuit in a state where supply of power supply voltage is stopped.

5. The electronic device according to claim 1,
wherein the scan flip-flop circuit and the arithmetic circuit each comprise a transistor comprising a semiconductor layer comprising silicon in a channel formation region.

6. The electronic device according to claim 1,
wherein the memory device comprises a peripheral circuit controlling the memory cell, and
wherein a layer where the peripheral circuit is provided is stacked with a layer where the memory cell is provided.

7. The electronic device according to claim 1,
wherein the arithmetic circuit is a circuit that performs a product-sum operation.

8. The electronic device according to claim 1,
wherein the metal oxide comprises In, Ga, and Zn.

9. A display system comprising:
a first electronic device; and
a second electronic device,
wherein the first electronic device comprises a first display portion, a first wireless communication means, and a first sensor,
wherein the second electronic device comprises a second display portion, a second wireless communication means, and a second sensor,
wherein, when the first wireless communication means and the second wireless communication means are linked to each other, the first electronic device and the second electronic device are connected to each other, and
wherein the display system is configured to display any one or more of augmented reality, virtual reality, substitutional reality, and mixed reality on the second display portion based on any one or more pieces of information input to the first sensor and the second sensor, and to operate an image on the second display portion based on the information input to the first sensor.

10. The display system according to claim 9,
wherein the first electronic device is an electronic device comprising:
a semiconductor device,
wherein the semiconductor device comprises a CPU, an accelerator, and a memory device,
wherein the CPU comprises a scan flip-flop circuit and a backup circuit electrically connected to the scan flip-flop circuit,
wherein the backup circuit comprises a first transistor,
wherein the accelerator comprises an arithmetic circuit and a data retention circuit electrically connected to the arithmetic circuit,
wherein the data retention circuit comprises a second transistor,
wherein the memory device comprises a memory cell comprising a third transistor, and
wherein the first transistor to the third transistor each comprise a semiconductor layer comprising a metal oxide in a channel formation region.

11. The electronic device according to claim 2,
wherein the backup circuit is configured to retain, when the CPU does not operate, data retained in the scan flip-flop circuit in a state where supply of power supply voltage is stopped.

12. The electronic device according to claim 2,
wherein the data retention circuit is configured to retain, when the accelerator does not operate, data retained in the data retention circuit in a state where supply of power supply voltage is stopped.

13. The electronic device according to claim 2,
wherein the scan flip-flop circuit and the arithmetic circuit each comprise a transistor comprising a semiconductor layer comprising silicon in a channel formation region.

14. The electronic device according to claim 2,
wherein the memory device comprises a peripheral circuit controlling the memory cell, and
wherein a layer where the peripheral circuit is provided is stacked with a layer where the memory cell is provided.

15. The electronic device according to claim 2,
wherein the arithmetic circuit is a circuit that performs a product-sum operation.

16. The electronic device according to claim 2,
wherein the metal oxide comprises In, Ga, and Zn.
